(19) United States
(12) Patent Application Publication
(10) Pub. No.: US 2019/0375896 A1
(43) Pub. Date: Dec. 12, 2019

(54) SILSESQUIOXANE DERIVATIVE HAVING RADICAL POLYMERIZABLE FUNCTIONAL GROUP, COMPOSITION THEREOF, AND CURED FILM HAVING LOW CURE SHRINKAGE

(71) Applicants: JNC CORPORATION, Tokyo (JP); JNC PETROCHEMICAL CORPORATION, Tokyo (JP)

(72) Inventors: Kazuya SUWA, Chiba (JP); Hironori IKENO, Chiba (JP); Tomoyuki OOBA, Chiba (JP)

(21) Appl. No.: 16/476,798

(22) PCT Filed: Jan. 9, 2018
(86) PCT No.: PCT/JP2018/000194

§ 371 Date: Jul. 9, 2019

(30) Foreign Application Priority Data
Jan. 10, 2017 (JP) 2017-002202

(51) Int. Cl. C08G 77/20; C08G 77/04; C08G 77/26; C09D 183/08; C09D 183/06; C09D 135/02; C09D 4/06; H05K 1/03

(52) U.S. Cl. CPC C08G 77/20; C08G 77/045; C08G 77/26; H05K 1/0346; C09D 183/06; C09D 135/02; C09D 4/06; C09D 183/08

(57) ABSTRACT

Provided is a new compound which can provide a cured film obtained from a resin composition with low cure shrinkage while suppressing reduction of hardness (scratch resistance) thereof. A silsesquioxane derivative having a radically polymerizable functional group, which is represented by formula (1), (2) or (3). In the formulas (1) to (3), R¹ is a group independently selected from alkyl having 1 to 45 carbons, cycloalkyl having 4 to 8 carbons, aryl having 6 to 14 carbons and arylalkyl having 7 to 24 carbons, R² and R³ are a group independently selected from alkyl having 1 to 10 carbons, cyclopentyl, cyclohexyl and phenyl, and X is independently hydrogen or a monovalent organic group, in which at least one of X is a radically polymerizable functional group represented by formula (4).

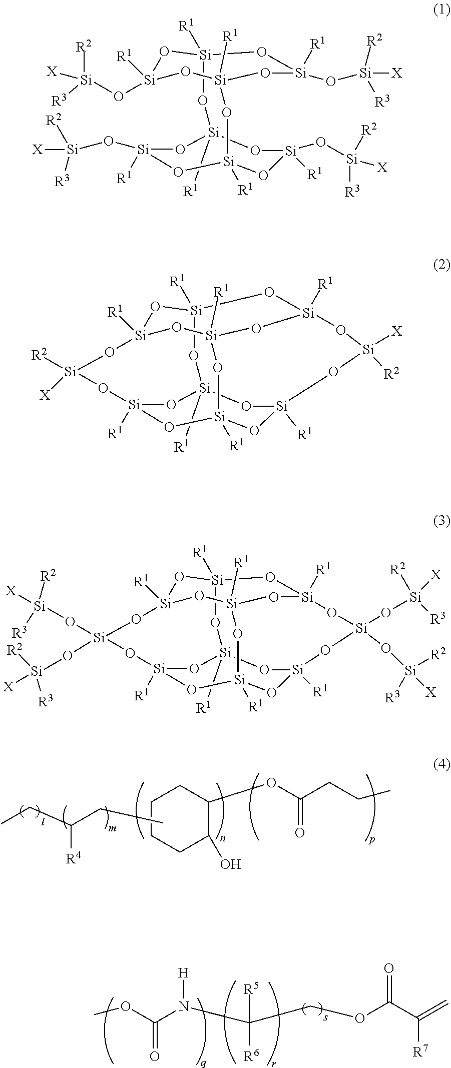

### TECHNICAL FIELD

The invention relates to a silsesquioxane derivative having a radically polymerizable functional group, a composition thereof, and a cured film having low cure shrinkage.

### BACKGROUND ART

Silsesquioxane is a generic term of polysiloxane represented by [(R—SiO_{1.5})n] (R is an arbitrary substituent). Silsesquioxane is a polysiloxane having a specific structure, and is a compound to be interested. The structure of silsesquioxane is generally classified into a random-type structure, a rudder-type structure and a cage-type structure, based on a Si—O—Si skeleton thereof.

For example, a proposal has been made on a new silsesquioxane derivative of an imperfect condensation type in which Na is bonded to the cage-type silsesquioxane having 8 atoms of Si, as a cage-type silsesquioxane derivative that can be usefully used as an electronic material, an optical material, an electro-optic material, a catalyst support, a polymer raw material or the like, and a method of easily preparing the derivative (Patent literature No. 1).

Moreover, an attempt has been made on introducing various functional groups into silsesquioxane, and a report has also been made on silsesquioxane into which a group containing fluorine is introduced, for example (Patent literature No. 2).

For example, a report has also been made on a silsesquioxane compound having a polymerizable functional group obtained by introducing an organic group having a secondary hydroxyl group and one (meth)acryloyloxy group as an organic group directly bonded to a silicon atom to the silsesquioxane compound (Patent literature No. 3).

### CITATION LIST

### Patent Literature

Patent literature No. 1: WO 2003/024870 A.

Patent literature No. 2: JP 2004-123698 A.

Patent literature No. 3: WO 2010/024119 A.

### SUMMARY OF INVENTION

### Technical Problem

Upon curing a resin by heat or ultraviolet light, shrinkage by curing is caused, and a problem such as deterioration of a surface shape, peeling from a base material caused by stress and warpage of the base material occurs.

An acrylic resin is excellent in optical properties, mechanical physical properties, water resistance, weather resistance and electric insulation, and also easy in molding processing, and therefore is used in wide fields such as a building material, a material for electrical equipment, a material for automobile, a paint, an adhesive and a pressure sensitive adhesive. However, the acrylic resin is more significant in shrinkage upon being cured by heat or ultraviolet light as compared with an epoxy resin.

The present inventors have attempted to increase an acryl equivalent to reduce a crosslinking density for suppressing cure shrinkage of the acrylic resin. The present inventors have studied on use of a monomer or an oligomer in which a molecular weight is large and an amount of an acrylic group is small, and use of a filler such as nanosilica, as a method for reducing the crosslinking density. As a result, the present inventors have found that a cured film excellent in scratch resistance can be obtained by using the monomer or the oligomer in which the amount of the acrylic group is small, but an effect of suppressing the cure shrinkage is small and resistance to moist heat is deteriorated in several cases. Moreover, the present inventors have found that the cured film excellent in hardness (scratch resistance) and resistance to moist heat can be obtained by adding the filler such as nanosilica, but a sufficient effect of suppressing the cure shrinkage is hard to be obtained.

Accordingly, an object of the invention is to provide a new compound that can provide the cured film low cure shrinkage while suppressing reduction of hardness (scratch resistance) of the cured film obtained from a resin composition. Moreover, a further object of the invention is to provide a resin composition from which a cured film having low warpage, and having suppressed cure shrinkage, and suppressed reduction of hardness (scratch resistance) is obtained. Moreover, a further object is provide a cured film having low warpage and having suppressed reduction of hardness (scratch resistance). A further object is to provide a laminate having low warpage and high resistance to moist heat.

### Solution to Problem

The present inventors have diligently continued to conduct a study. As a result, the present inventors have succeeded in synthesis of a new double-decker type silsesquioxane compound having a radically polymerizable functional group.

Further, the present inventors have found that a cured film having suppressed cure shrinkage upon being cured and having reduced suppression of hardness (scratch resistance) can also be obtained by combining the new double-decker type silsesquioxane compound and an acrylic resin. Moreover, the present inventors have found that a laminate having low warpage and high resistance to moist heat can be obtained.

An embodiment of the invention includes structure described below.

[1] A silsesquioxane derivative having a radically polymerizable functional group, represented by formula (1), (2) or (3):

wherein, in formulas (1) to (3),

R¹ is a group independently selected from alkyl having 1 to 45 carbons, cycloalkyl having 4 to 8 carbons, aryl having 6 to 14 carbons and arylalkyl having 7 to 24 carbons; in the alkyl having 1 to 45 carbons, at least one hydrogen may be replaced by fluorine, and at least one non-adjacent —CH₂— may be replaced by —O— or —CH═CH—; and in a benzene ring in the aryl and the arylalkyl, at least one hydrogen may be replaced by halogen or alkyl having 1 to 10 carbons, and in the alkyl having 1 to 10 carbons, at least one hydrogen may be replaced by fluorine, and at least one non-adjacent —CH₂— may be replaced by —O— or —CH═CH—; and the number of carbons of alkylene in the arylalkyl is 1 to 10, and at least one non-adjacent —CH₂— may be replaced by —O—;
R² and R³ are a group independently selected from alkyl having 1 to 10 carbons, cyclopentyl, cyclohexyl and phenyl,
X is independently hydrogen or a monovalent organic group, in which at least one of X is a radically polymerizable functional group represented by formula (4); and
   in formula (4), 1 is an integer from 0 to 10, m is an integer from 0 to 10, n is 0 or 1, p is an integer from 0 to 10, q is 0 or 1, r is 0 or 1, s is an integer from 0 to 10, R⁴ is a hydroxyl group, R⁵ is hydrogen or methyl, R⁶ is an organic group having 4 to 6 carbons, and having an acryloyl group or a methacryloyl group, and R⁷ is hydrogen or methyl; and arbitrary —CH₂— may be replaced by —O—, in which a case where two oxygens are bonded with each other (—O—O—) is excluded, in X of the silsesquioxane derivative represented by formula (1), when all of m, n, p, q and r are 0, and R⁷ is methyl, a sum: 1+s is an integer from 4 or more; and in X of the silsesquioxane derivative represented by formula (2), when all of m, n, p, q and r are 0, a sum: 1+s is an integer from 4 or more:

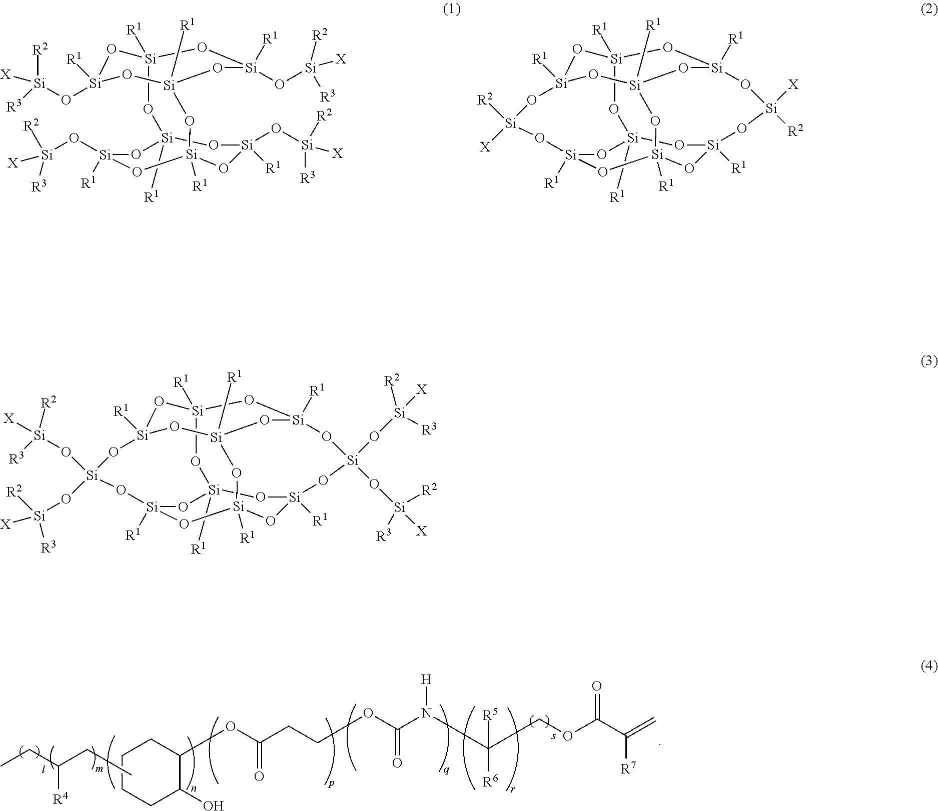

[2] The silsesquioxane derivative having the radically polymerizable functional group according to [1], wherein, in the formula (1), (2) or (3), all of R² and R³ are alkyl having 1 to 6 carbons.

[3] The silsesquioxane derivative having the radically polymerizable functional group according to [2], wherein, in the formula (1), (2) or (3), all of R² and R³ are a methyl group or an ethyl group.

[4] The silsesquioxane derivative having the radically polymerizable functional group according to any one of [1] to [3], wherein, in the formula (1), (2) or (3), all of X contain a polymerizable functional group.

[5] The silsesquioxane derivative having the radically polymerizable functional group according to any one of [1] to [4], wherein, in the formula (1), (2) or (3), at least one of X is (meth)acrylate, urethane (meth)acrylate or epoxy (meth)acrylate.

[6] The silsesquioxane derivative having the radically polymerizable functional group according to any one of [1] to [4], wherein, in the formula (1), X is one kind selected from the group of polymerizable functional groups represented by (a-1) to (a-4), (b-1) to (b-5), (c-1), (c-2), (d-1) and (d-2),

in the formula (2), X is one kind selected from the group of polymerizable functional groups represented by (a-1) to (a-3), (b-1) to (b-5), (c-1), (c-2), (d-1) and (d-2), and
in the formula (3), X is one kind selected from the group of polymerizable functional groups represented by (a-1) to (a-5), (b-1) to (b-5), (c-1), (c-2), (d-1) and (d-2);

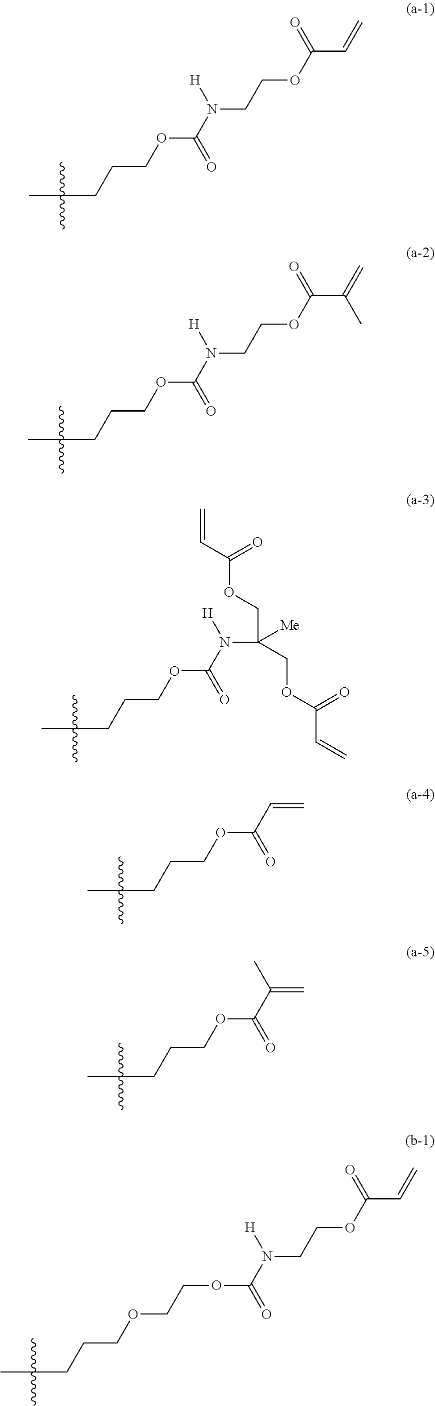

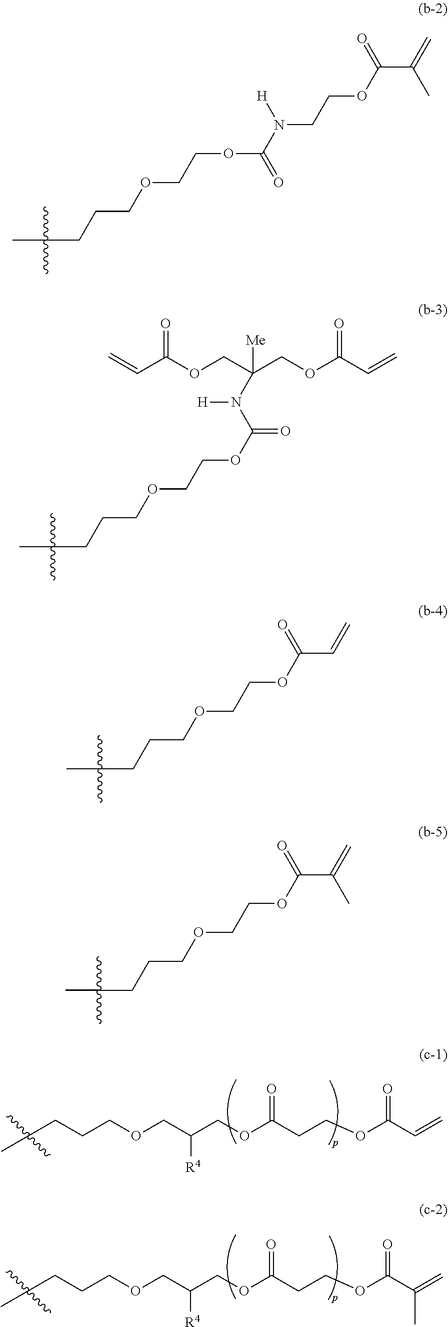

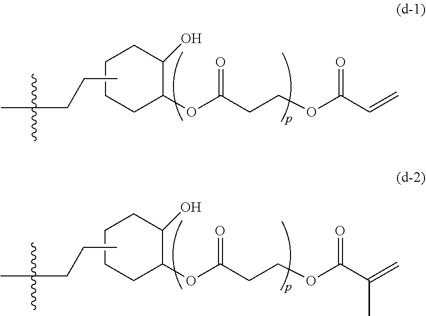

wherein, R⁴ is a hydroxyl group, and p is an integer from 0 to 10.

[7] A resin composition, containing acrylic resin (A) and at least one kind selected from silsesquioxane derivatives (B) represented by formula (1), (2) or (3):

wherein, in the silsesquioxane derivative represented by formula (1), (2) or (3),

R¹ is a group independently selected from alkyl having 1 to 45 carbons, cycloalkyl having 4 to 8 carbons, aryl having 6 to 14 carbons and arylalkyl having 7 to 24 carbons; and in the alkyl having 1 to 45 carbons, at least one hydrogen may be replaced by fluorine, and at least one non-adjacent-CH₂— may be replaced by —O— or —CH═CH—; and in a benzene ring in the aryl and the arylalkyl, at least one hydrogen may be replaced by halogen or alkyl having 1 to 10 carbons, and in the alkyl having 1 to 10 carbons, at least one hydrogen may be replaced by fluorine, and at least one non-adjacent —CH₂— may be replaced by —O— or —CH═CH—; and the number of carbons of alkylene in the arylalkyl is 1 to 10, and at least one non-adjacent-CH₂— may be replaced by —O—,

R² and R³ are a group independently selected from alkyl having 1 to 10 carbons, cyclopentyl, cyclohexyl and phenyl,

X is independently hydrogen or a monovalent organic group, in which at least one of X is a radically polymerizable functional group represented by formula (4); and

in formula (4), 1 is an integer from 0 to 10, m is an integer from 0 to 10, n is 0 or 1, p is an integer from 0 to 10, q is 0 or 1, r is 0 or 1, s is an integer from 0 to 10, R⁴ is a hydroxyl group, R⁵ is hydrogen or methyl, R⁶ is an organic group having 4 to 6 carbons, and having an acryloyl group or a methacryloyl group, R⁷ is hydrogen or methyl; arbitrary —CH₂— may be replaced by —O—; in which a case where two oxygens are bonded with each other (—O—O—) is excluded, in which in X of the silsesquioxane derivative represented by formula (1), when all of m, n, p, q and r are 0, and R⁷ is methyl, a sum: 1+s is an integer from 4 or more, and in X of the silsesquioxane derivative represented by formula (2), when all of m, n, p, q and r are 0, a sum: 1+s is an integer from 4 or more:

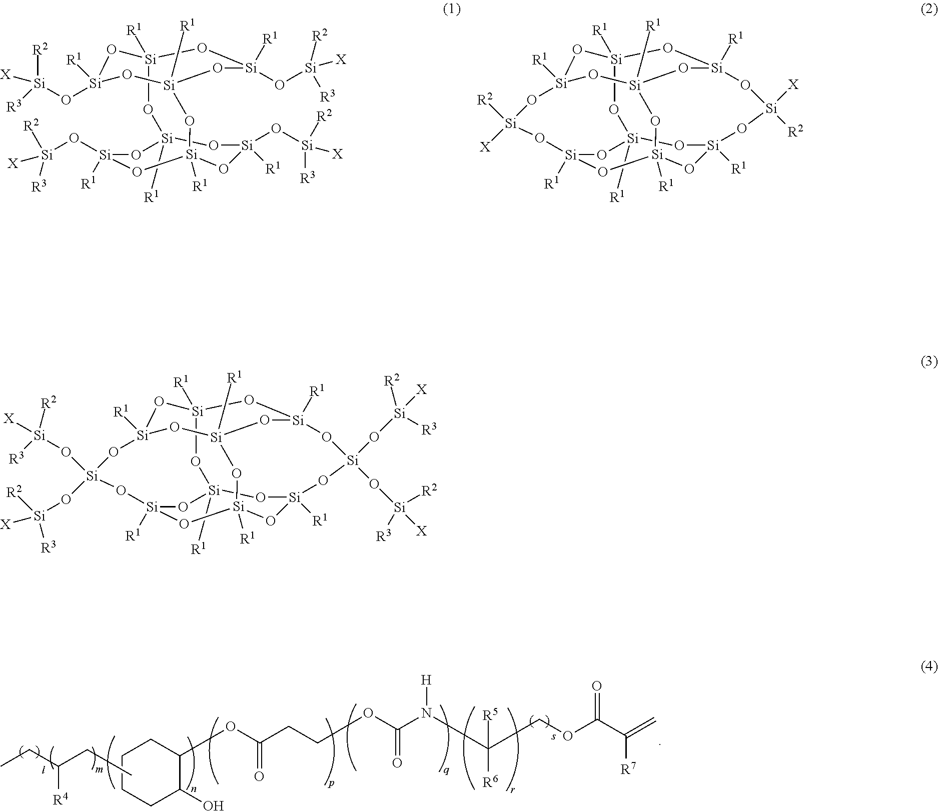

[8] The resin composition according to [7], containing at least one kind of a silsesquioxane derivative, wherein, in the silsesquioxane derivative (B) represented by formula (1), (2) or (3), all of R¹ are phenyl, all of R² and R³ are a methyl group, and X is selected from the group represented by (a-1) to (a-5), (b-1) to (b-5), (c-1), (c-2), (d-1) and (d-2):

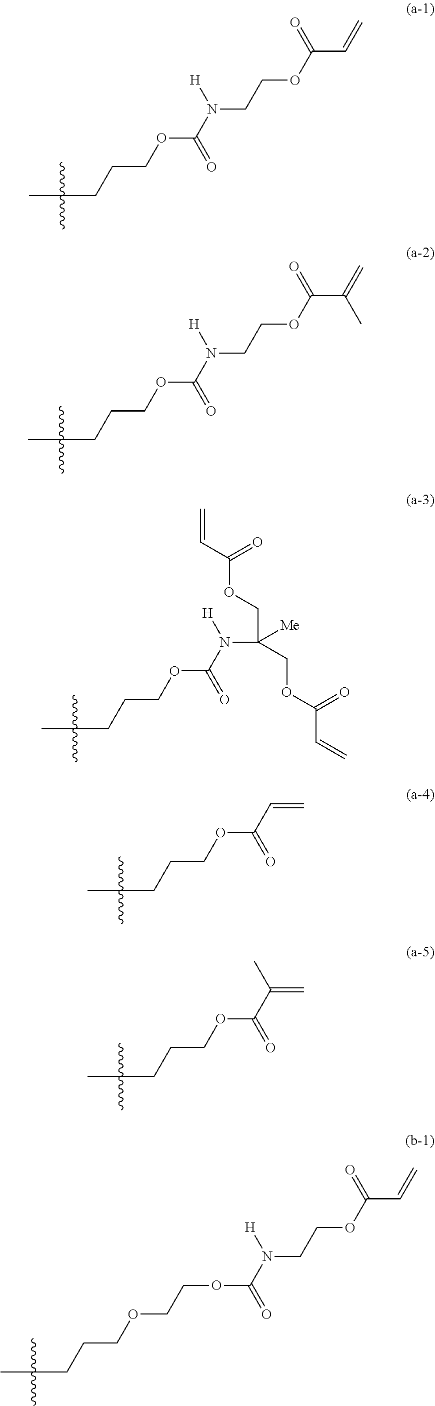

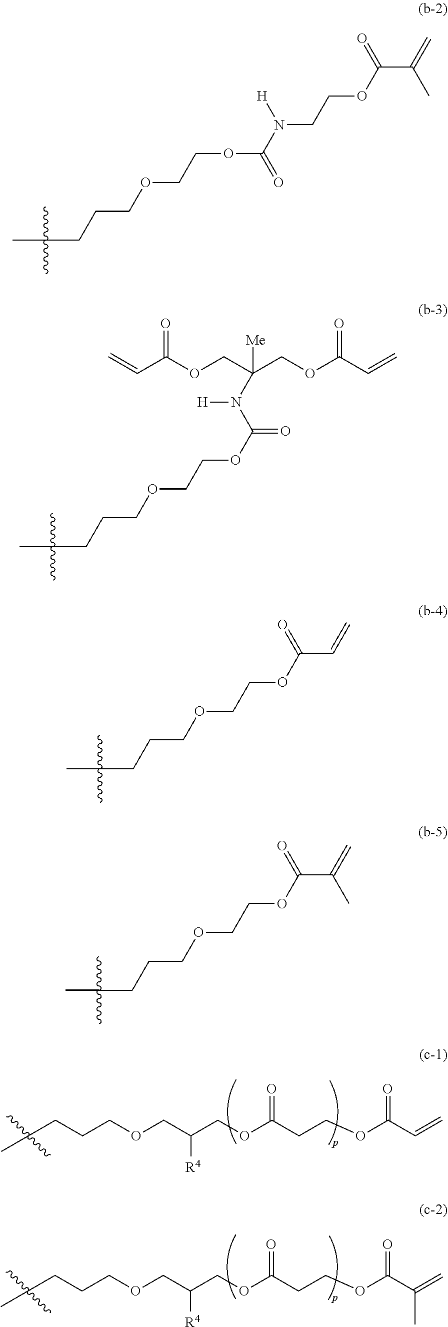

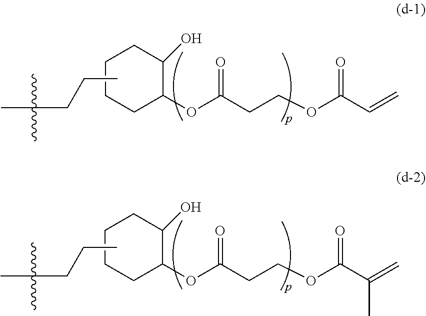

wherein, R⁴ is a hydroxyl group, and p is an integer from 0 to 10.

[9] The resin composition according to [7] or [8], wherein the acrylic resin (A) is a polyfunctional monomer type (meth)acrylic resin.

[10] The resin composition according to any one of [7] to [9], containing acrylic resin(A) by 10% by mass or more and 95% by mass or less in a solid content of the resin composition.

[11] The resin composition according to any one of [7] to [10], wherein a mass ratio of a content of the acrylic resin (A) to a total content of the silsesquioxane derivatives (B) represented by formula (1), (2) or (3) is 10:90 to 95:5.

[12] A cured film, formed by curing the resin composition according to any one of [7] to [11].

[13] A laminate, including:

a base material, and

a cured film formed by curing the resin composition containing at least acrylic resin (A) and at least one kind selected from silsesquioxane derivatives (B) represented by formula (1), (2) or (3) on the base material,

wherein a warpage height of the base material with the cured film on the resin composition is 0 millimeter or more and 4 millimeters or less by evaluation method 1, and adhesion on all kinds of base materials after 120 hours is rated to be 4B or more in adhesion evaluation by evaluation method 2; and
in formula (1), (2) or (3), R¹ is a group independently selected from alkyl having 1 to 45 carbons, cycloalkyl having 4 to 8 carbons, aryl having 6 to 14 carbons and arylalkyl having 7 to 24 carbons; in the alkyl having 1 to 45 carbons, at least one hydrogen may be replaced by fluorine, and at least one non-adjacent —CH₂— may be replaced by —O— or —CH═CH—; and in a benzene ring in the aryl and the arylalkyl, at least one hydrogen may be replaced by halogen or alkyl having 1 to 10 carbons, and in the alkyl having 1 to 10 carbons, at least one hydrogen may be replaced by fluorine, and at least one non-adjacent —CH₂— may be replaced by —O— or —CH═CH—; and the number of carbons of alkylene in the arylalkyl is 1 to 10, and at least one non-adjacent-CH₂— may be replaced by —O—,

R² and R³ are a group independently selected from alkyl having 1 to 10 carbons, cyclopentyl, cyclohexyl and phenyl,

X is independently hydrogen or a monovalent organic group, in which at least one of X is a radically polymerizable functional group represented by formula (4); and

in the formula (4), 1 is an integer from 0 to 10, m is an integer from 0 to 10, n is 0 or 1, p is an integer from 0 to 10, q is 0 or 1, r is 0 or 1, s is an integer from 0 to 10, R⁴ is a hydroxyl group, R⁵ is hydrogen or methyl, R⁶ is an organic group having 4 to 6 carbons, and having an acryloyl group or a methacryloyl group, R⁷ is hydrogen or methyl; and arbitrary —CH₂— may be replaced by —O—; in which a case where two oxygens are bonded with each other (—O—O—) is excluded, and in X of the silsesquioxane derivative represented by formula (1), when all of m, n, p, q and r are 0, and R⁷ is methyl, a sum: 1+s is an integer from 4 or more; and in X of the silsesquioxane derivative represented by formula (2), when all of m, n, p, q and r are 0, a sum: 1+s is an integer from 4 or more:

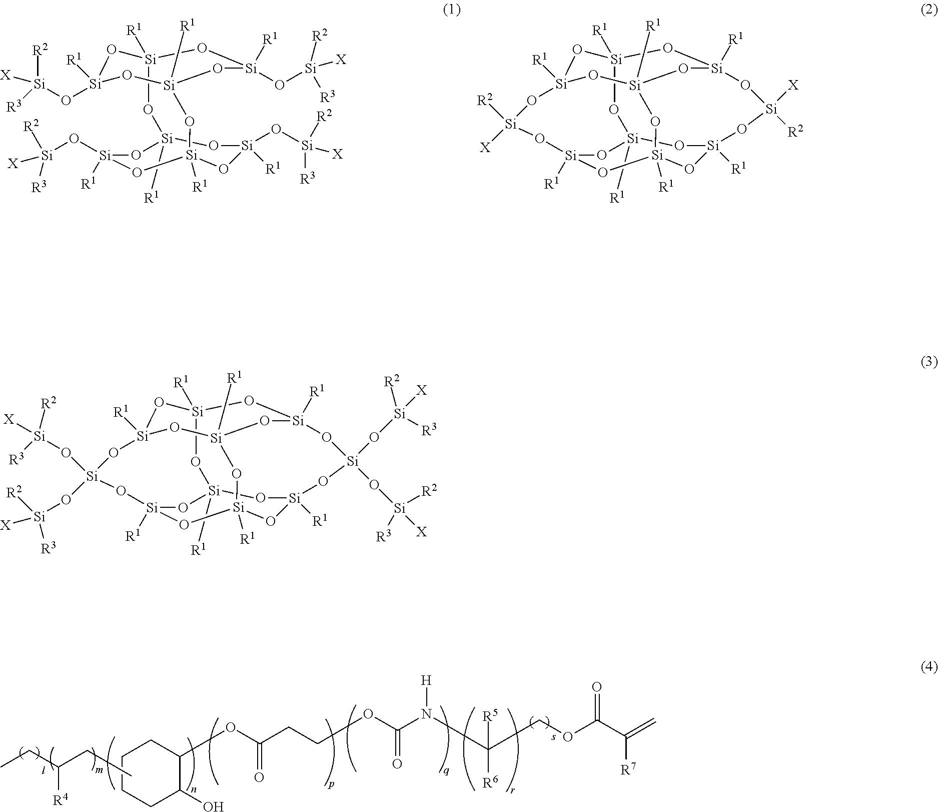

### Evaluation Method 1

a cured film each having a thickness of 2.5 to 6 micrometers and composed of the resin composition is formed on a 50 micrometer-thick polyethylene terephthalate (PET) film base material on which an easy-adhesive layer may be formed;

the resulting PET with the cured film is cut into a lattice of 15 cm×15 cm, and the resulting square is allowed to stand with the cured film upward under an atmosphere of 25° C. and 50% RH for 24 hours or more, and then each height of the cured film lifted on four corners on a horizontal table is measured, and a mean value of the total of heights is taken as a measured value (unit: mm); and

a case of curling downward (U shape) is taken as a positive value, and a case of curling upward (inverted U shape) is taken as a negative value;

### Evaluation Method 2

a cured film each having a thickness of 2.5 to 6 micrometers and composed of the resin composition is formed on a 50 micrometer-thick polyethylene terephthalate (PET) film base material on which an easy-adhesive layer may be formed;

on the resulting PET with the cured film, in accordance with ASTM D3359 (Method B),

an adhesion test is performed by using a crosscut adhesion method with 25 lattice patterns at a spacing of 1 millimeter; and then the PET with the cured film after performing adhesion test is put into a constant temperature and humidity chamber at 85° C. and 85% RH for 120 hours, and then the resulting material is took out therefrom, and in accordance with ASTM D3359 (Method B),

an adhesion test is performed by using a crosscut adhesion method with 25 lattice patterns at a spacing of 1 millimeter; and evaluation criteria are as described below:

5B: 0% in percent area removed;

4B: less than 5% in percent area removed;

3B: 5% or more and less than 15% in percent area removed;

2B: 15% or more and less than 35% in percent area removed;

1B: 35% or more and less than 65% in percent area removed; and

0B: 65% or more in percent area removed.

[14] An electronic component, including the cured film according to [12] or the laminate according to [13].

### Advantageous Effects of Invention

The invention provides a new silsesquioxane derivative having a polymerizable functional group. Moreover, the invention provides a resin composition from which a cured film having suppressed cure shrinkage, and having suppressed reduction of hardness (scratch resistance) is obtained. Moreover, the invention provides a cured film having low warpage and having reduced reduction of hardness (scratch resistance). Further, the invention provides a laminate having low warpage and high resistance to moist heat.

### DESCRIPTION OF EMBODIMENTS

Hereinafter, the invention will be described in detail by way of embodiments. However, the invention is not limited to the embodiments described explicitly or impliedly in the present specification, and each embodiment described in the present specification can be modified in various manners within the range without departing from the spirit, and can be combined within the practicable range.

### 1. Silsesquioxane Derivative Having Radically Polymerizable Functional Group

One embodiment according to the invention is a silsesquioxane derivative that is represented by formula (1), (2) or (3), and is a double-decker type silsesquioxane compound having a radically polymerizable functional group.

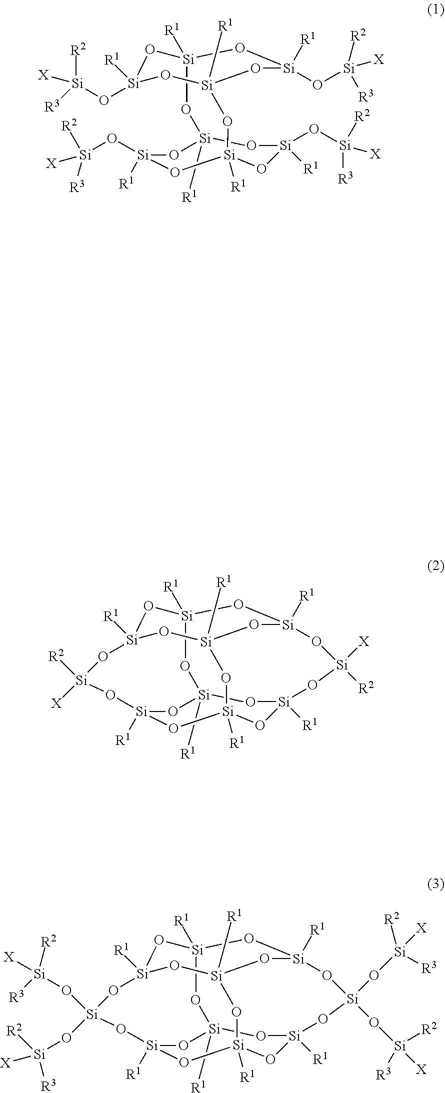

In the silsesquioxane derivative represented by formula (1), (2) or (3) (hereinafter, described merely as “compound of formulas (1) to (3),” or the like in several cases),

R¹ is a group independently selected from alkyl having 1 to 45 carbons, cycloalkyl having 4 to 8 carbons, aryl having 6 to 14 carbons and arylalkyl having 7 to 24 carbons; and in the alkyl having 1 to 45 carbons, at least one hydrogen may be replaced by fluorine, and at least one non-adjacent —CH₂— may be replaced by —O— or —CH═CH—; and in a benzene ring in the aryl and the arylalkyl, at least one hydrogen may be replaced by halogen or alkyl having 1 to 10 carbons, and in the alkyl having 1 to 10 carbons, at least one hydrogen may be replaced by fluorine, and at least one non-adjacent-CH₂— may be replaced by —O— or —CH═CH—; and the number of carbons of alkylene in the arylalkyl is 1 to 10, and at least one non-adjacent —CH₂— may be replaced by —O—,

R² and R³ are a group independently selected from alkyl having 1 to 10 carbons, cyclopentyl, cyclohexyl and phenyl, and

X is independently hydrogen or a monovalent organic group, in which at least one of X has a radically polymerizable functional group.

Specific examples of alkyl having 1 to 45 carbons include methyl, ethyl, propyl, isopropyl, n-butyl, sec-butyl, tert-butyl, pentyl, hexyl and dodecanyl.

Specific examples of cycloalkyl having 4 to 8 carbons include cyclopropyl, cyclobutyl, cyclopentyl and cyclohexyl.

Specific examples of aryl having 6 to 14 carbons include phenyl, 1-naphthyl, 2-naphthyl, indenyl, biphenylyl, anthryl and phenanthryl.

Specific examples of arylalkyl having 7 to 24 carbons include benzyl, phenethyl, diphenylmethyl, triphenylmethyl, 1-naphthyl methyl, 2-naphthyl methyl, 2,2-diphenylethyl, 3-phenylpropyl, 4-phenylbutyl and 5-phenylpentyl.

From viewpoints of suppression of cure shrinkage, solubility with a resin and production, R¹ is preferably alkyl having 1 to 6 carbons, cycloalkyl having 4 to 6 carbons, aryl having 6 to 14 carbons or arylalkyl having 7 to 24 carbons, further preferably alkyl having 1 to 6 carbons or aryl having 6 to 10 carbons, and still further preferably phenyl or cyclohexyl.

From viewpoints of suppression of cure shrinkage and production, R² is preferably alkyl having 1 to 6 carbons or phenyl, further preferably alkyl having 1 to 6 carbons, and still further preferably a methyl group or an ethyl group.

From viewpoints of suppression of cure shrinkage and production, R³ is preferably alkyl having 1 to 6 carbons or phenyl, is further preferably alkyl having 1 to 6 carbons, and still further preferably a methyl group or an ethyl group.

From viewpoints of suppression of cure shrinkage and production, all of R² and R³ are preferably identical, all of R² and R³ are further preferably alkyl having 1 to 6 carbons or phenyl, and all of R² and R³ are still further preferably a methyl group or an ethyl group.

The monovalent organic group in X is not particularly limited, and specific examples thereof include alkyl having 1 to 20 carbons, alkenyl having 2 to 20 carbons, alkynyl having 2 to 20 carbons and an organic group having at least one bond selected from the group of a carboxylic acid ester bond, a sulfonic acid ester bond, an amide bond, a phosphonic acid bond, an ether bond, a sulfide bond and an imide bond in an arbitrary site of the organic groups.

The above-described radically polymerizable functional group has a (meth)acryloyloxy group at a terminal, and is represented by formula (4).

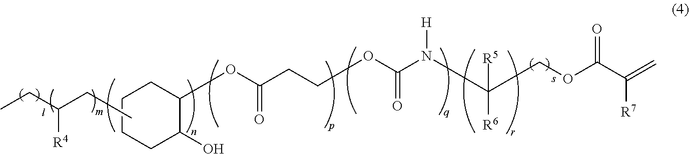

In formula (4), 1 is an integer from 0 to 10, m is an integer from 0 to 10, n is 0 or 1, p is an integer from 0 to 10, q is 0 or 1, r is 0 or 1, s is an integer from 0 to 10, R⁴ is a hydroxyl group, R⁵ is hydrogen or methyl, R⁶ is an organic group having 4 to 6 carbons, and having an acryloyl group or a methacryloyl group, and R⁷ is hydrogen or methyl, in which in X of the silsesquioxane derivative represented by formula (1), when all of m, n, p, q and r are 0, and R⁷ is methyl, a sum: 1+s is an integer from 4 or more.

Moreover, in X of the silsesquioxane derivative represented by formula (2), when all of m, n, p, q and r are 0, a sum: 1+s is an integer from 4 or more.

Moreover, in formula (4), arbitrary methylene (—CH₂—) may be replaced by oxygen (—O—). More specifically, the expression means that arbitrary “—CH₂—” may be replaced by “—O—.” However, a case where two oxygen are bonded with each other (—O—O—) is excluded. Thus, a radically polymerizable functional group may have an ether bond. Moreover, in a preferred radically polymerizable functional group, a case where methylene adjacent to Si is replaced by oxygen is excluded.

In the formulas (1) to (3), at least one of X is preferably (meth)acrylic acid ester, urethane (meth)acrylate or epoxy (meth)acrylate.

In formula (4), from viewpoints of a suppression effect of cure shrinkage and production, when q=1 and m=n=p=r=0, a case where 1 is an integer from 3 to 8, and s is an integer from 1 to 6 is preferred, and a case where 1 is an integer from 3 to 6, and s is 1 or 2 is further preferred. In the above cases, an embodiment in which at least one methylene is replaced by oxygen is also preferred.

In formula (4), from viewpoints of the suppression effect of cure shrinkage and production, when q=1, r=1, and m=n=p=0, a case where 1 is an integer from 3 to 10, and s is an integer from 1 to 6 is preferred, and a case where 1 is an integer from 3 to 7 and s is an integer from 1 to 3 is further preferred. In the above cases, an embodiment in which at least one methylene is replaced by oxygen is also preferred.

In formula (4), from viewpoints of the suppression effect of cure shrinkage and production, when m=n=p=q=r=s=0, a case where 1 is an integer from 4 to 10, and at least one methylene is replaced by oxygen is preferred, and a case where 1 is an integer from 4 to 8, and at least one methylene is replaced by oxygen is preferred, a case where 1 is an integer from 4 to 6, and at least one methylene is replaced by oxygen is preferred, and a case where 1 is an integer from 4 to 6, and one methylene is replaced by oxygen is further preferred.

In formula (4), from viewpoints of the suppression effect of cure shrinkage and production, when m and p each is 1 or more, and n=q=r=0, a case where 1 is an integer from 3 to 7, m is an integer from 1 to 5, p is an integer from 0 to 10, and s is an integer from 0 to 3 is preferred, and a case where 1 is an integer from 3 to 6, m is an integer from 1 to 3, p is an integer from 0 to 10 and s is an integer from 0 to 2 is further preferred. In the above cases, an embodiment in which at least one methylene is replaced by oxygen is also preferred.

In formula (4), from viewpoints of the suppression effect of cure shrinkage and production, when n and p each is 1 or more, and m=q=r=0, a case where 1 is an integer from 2 to 7, n is an integer from 1 to 5, p is an integer from 0 to 10, and s is an integer from 0 to 3 is preferred, and a case where 1 is an integer from 2 to 6, n is an integer from 1 to 3, p is an integer from 0 to 10, and s is an integer from 0 to 2 is further preferred.

In the formula (1), X is particularly preferably one kind selected from the group of polymerizable functional groups represented by (a-1) to (a-4), (b-1) to (b-5), (c-1), (c-2), (d-1) and (d-2).

In the formula (2), X is particularly preferably one kind selected from the group of polymerizable functional groups represented by (a-1) to (a-3), (b-1) to (b-5), (c-1), (c-2), (d-1) and (d-2).

In the formula (3), X is particularly preferably one kind selected from the group of polymerizable functional groups represented by (a-1) to (a-5), (b-1) to (b-5), (c-1), (c-2), (d-1) and (d-2).

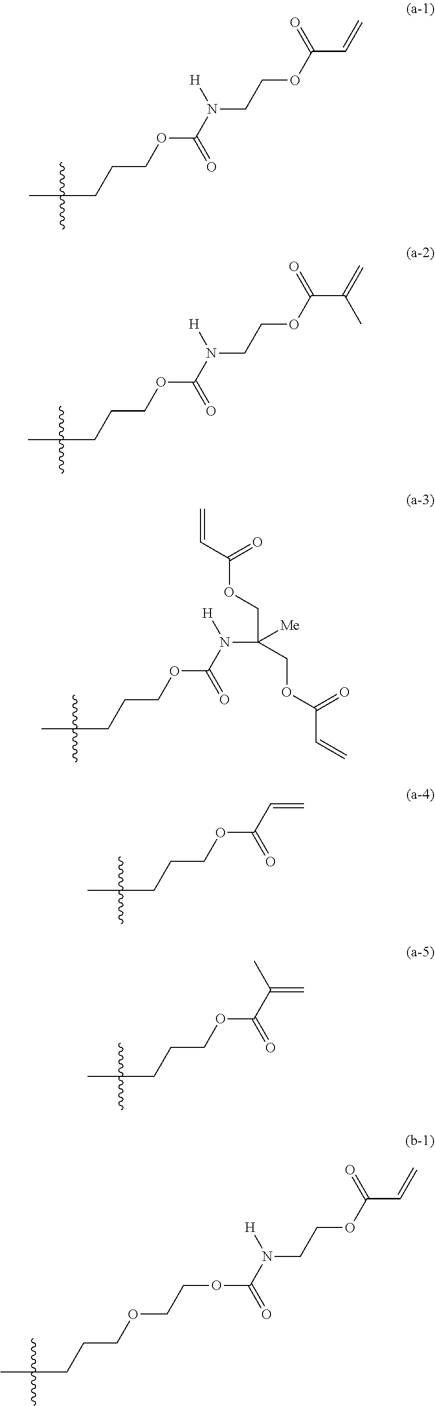

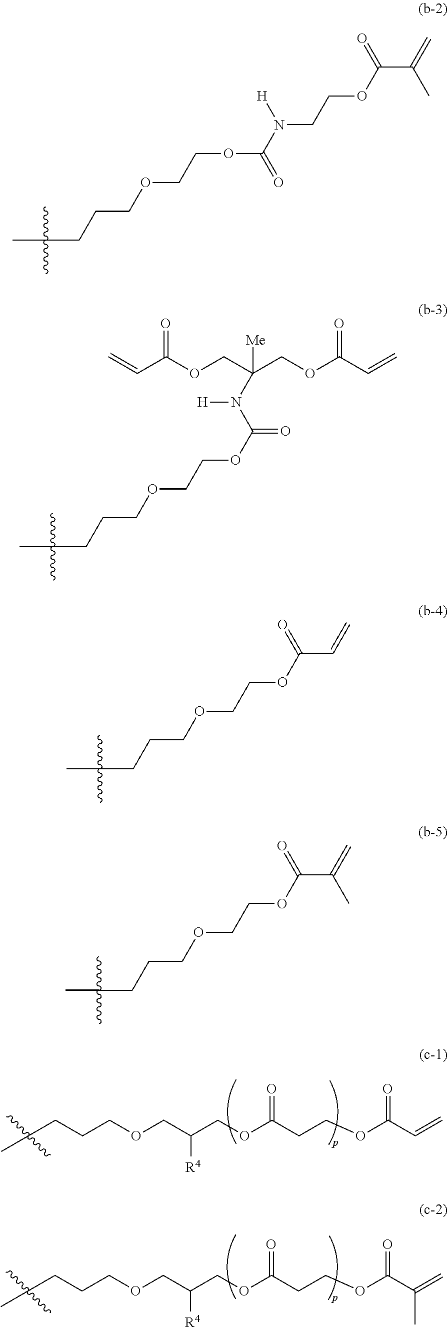

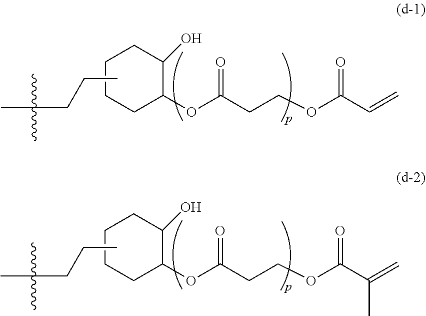

R⁴ is a hydroxyl group, and p is an integer from 0 to 10.

In the formulas (1) to (3), two or more of X preferably contain a polymerizable functional group represented by formula (4), and all of X are preferably the polymerizable functional group represented by formula (4). In one molecule of the compound represented by formula (1) or (3) according to the invention, the number of the (meth)acryloyloxy groups is preferably 1 or more, further preferably 2 or more, and still further preferably 4 or more, and preferably 8 or less. In one molecule of a compound represented by formula (2) according to the invention, the number of the (meth)acryloyloxy groups is preferably 1 or more, further preferably 2 or more, and preferably 4 or less. The number of the (meth)acryloyloxy groups is adjusted within the range described above, whereby, while reduction of hardness (scratch resistance) of a cured film obtained by adding the compound to an acrylic resin, low warpage can be realized.

As the compound represented by formula (1), a compound in which all of R¹ are phenyl, all of R² and R³ are methyl, and X is one kind selected from the group of compounds represented by (a-1) to (a-4), (b-1) to (b-5), (c-1), (c-2), (d-1) and (d-2) is particularly preferred.

As the compound represented by formula (2), a compound in which all of R¹ are phenyl, all of R² and R³ are methyl, and X is one kind selected from the group of compounds represented by (a-1) to (a-3), (b-1) to (b-5), (c-1), (c-2), (d-1) and (d-2) is particularly preferred.

As a compound represented by formula (3), a compound in which all of R¹ are phenyl, all of R² and R³ are methyl, and X is one kind selected from the group of compounds represented by (a-1) to (a-5), (b-1) to (b-5), (c-1), (c-2), (d-1) and (d-2) is particularly preferred.

As a production method of the compound represented by formula (1), the method described in WO 2004/024741 A or the like can be used as a reference, for example.

A compound to be used as a raw material can be easily produced with good yield by hydrolyzing a silicon compound having three hydrolyzable groups to allow polycondensation in an oxygen-containing organic solvent such as tetrahydrofuran (hereinafter referred to as THF) or an alcohol in the presence of an alkali metal hydroxide. Many of silicon compounds having three hydrolyzable groups are commercially available. A compound that is not commercially available can be synthesized by a known technique (for example, a reaction between a halogenated silane and a Grignard reagent, or the like). Then, in the synthesis of the compound represented by formula (5) (hereinafter, also referred to as compound (5)), when at least two silicon compounds having three hydrolyzable groups are used, compound (5) in which 8 pieces of R are composed of at least two different groups is obtained. For the synthesis of the compound represented by formula (5), the method described in WO 03/024870 A can also be used as a reference.

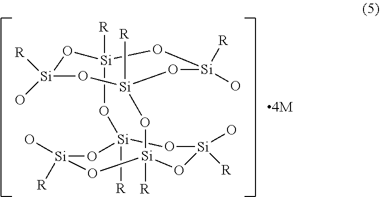

In formula (5), R has a meaning identical with R¹ in formula (1), and M is a monovalent alkali metal atom. Examples of the alkali metal atom include lithium, potassium, sodium and cesium, and sodium is preferred.

One of methods for producing compound (1) from compound (5) include a method in which compound (6) is allowed to react with compound (5) to form compound (7), and then applying a method (i) of introducing a radially polymerizable functional group by preparing a terminal hydroxyl group by allowing a hydrosilylation reaction of a hydroxyl group such as allyl alcohol with a compound having a terminal unsaturated hydrocarbon group, and then allowing a compound having an isocyanate group and the radially polymerizable functional group, acrylic acid chloride or the like to react therewith, a method (ii) of introducing the radially polymerizable functional group by introducing an epoxy group by the hydrosilylation reaction and allowing the reaction between the epoxy and acrylic acid, and a method (iii) of allowing an acrylic compound having a dimethylchlorosilyl group to react with a compound represented by formula (5) or an OH converted from the compound represented by formula (5).

In addition, when compound (7) and a compound having the radially polymerizable functional group and an unsaturated hydrocarbon group are subjected to the hydrosilylation reaction, both of unsaturated bonds on a vinyl side and on a (meth)acryloyl side react, and therefore a large number of by-products are formed. Therefore, as a method for producing a new silsesquioxane derivative, which is one embodiment of the invention, compound (1) is preferably produced by introducing the radially polymerizable functional group by any one of the methods (i) to (iii).

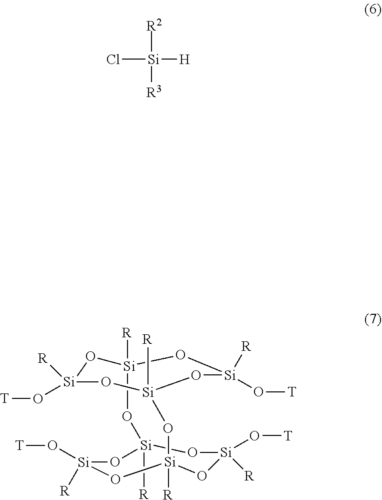

R² and R³ in formula (6) have meanings each identical with the above symbols in formula (1). In formula (7), at least one of T is a group represented below, in which Cl is eliminated from formula (6), and remaining T is hydrogen. Moreover, R in formula (7) has a meaning identical with R¹ in formula (1)

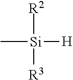

Compound (6) is chlorosilane, and any other halogenated silane can be used in a similar manner. Compound (6) is commercially available. Compound (6) that is not commercially available can be easily obtained by a publicly-known technology, for example, a method of allowing a halogenated silane to react with a Grignard reagent. In consideration of ease of availability, preferred examples of compound (6) include dimethylchlorosilane, diethylchlorosilane, methylethylchlorosilane, methylhexylchlorosilane, diisopropylchlorosilane, ditert-butylchlorosilane, dicyclopentylchlorosilane, dicyclohexylchlorosilane, dinormaloctylchlorosilane, methylphenylchlorosilane and diphenylchlorosilane.

In the reaction between compound (5) and compound (6), an organic solvent is preferably used. More specifically, compound (5) is mixed with the organic solvent, and compound (6) is added dropwise to the mixture. After completion of the reaction, when necessary, compound (6) is removed by distillation, and then water is added thereto to dissolve by-product alkali metal chloride. Then, an organic layer is washed with water, dried over a dehydrating agent, and then the solvent is removed from the organic layer by distillation, whereby compound (7) can be obtained. Moreover, purity of compound (7) can be improved by recrystallization, or extraction of impurities using the organic solvent, when necessary.

The above-described solvent used during the reaction is selected under conditions of causing no inhibition of progress of the reaction, and is not particular limited in other conditions. Examples of a preferred solvent include an aliphatic hydrocarbon (hexane and heptane), an aromatic hydrocarbon (benzene, toluene, and xylene), ether (diethyl ether, THF, and 1,4-dioxane), a halogenated hydrocarbon (methylene chloride, and carbon tetrachloride) and an ester (ethyl acetate). The above solvents may be used alone or in combination of a plurality thereof. A further preferred solvent is an aromatic hydrocarbon and an ether, and a still further preferred solvent is toluene and THF. Then, a solvent in which a content of the impurities (example: water) easily reacting with compound (6) is significantly low is preferred.

A preferred proportion of compound (5) when compound (5) is mixed in the solvent is 0.05 to 50% by weight based on the weight of the solvent. In order to avoid such a high concentration of a by-product salt as inhibiting progress of the reaction, a proportion is preferably 50% by weight or less. In order to avoid such deterioration of volumetric efficiency as adversely affecting cost, a proportion is preferably 0.05% by weight or more, and a further preferred proportion is 1 to 10% by weight. An amount of use of compound (6) is not limited except that a molar ratio is adjusted to 4 or more relative to compound (5), but in consideration of a post-treatment step, use is large excess is not preferable. In addition, a use proportion of compound (6) to compound (5) may be smaller than 4 in a molar ratio when part of T is left in the form of —H. Moreover, when reactivity of compound (6) is low, compound (7) in which part of T is hydrogen is obtained in several cases even if the use proportion is 4 or more in a molar ratio. A reaction temperature may be room temperature, and heating may be made for promoting the reaction, when necessary. Cooling may be made when control of heat generation by the reaction, an unfavorable reaction or the like is required.

The above reaction can be easily promoted by adding a compound having an amino group such as triethylamine or an organic compound having basicity. When triethylamine is used, a preferable addition proportion of triethylamine or the like is 0.005 to 10% by weight, further preferably 0.01 to 3% by weight, based on the weight of the solvent. However, the addition proportion is not particularly limited as long as the reaction can be easily proceeded by adding triethylamine or the like.

An example of a method (i) of introducing the radially polymerizable functional group into compound (7) by preparing a terminal hydroxyl group by allowing the hydrosilylation reaction of a hydroxyl group such as allyl alcohol with a compound having the terminal unsaturated hydrocarbon group, and then allowing a compound having the isocyanate group and the radially polymerizable functional group to react therewith, and an example of a method of introducing a radically polymerizable function group to compound (7) by allowing acrylic acid chloride to react therewith.

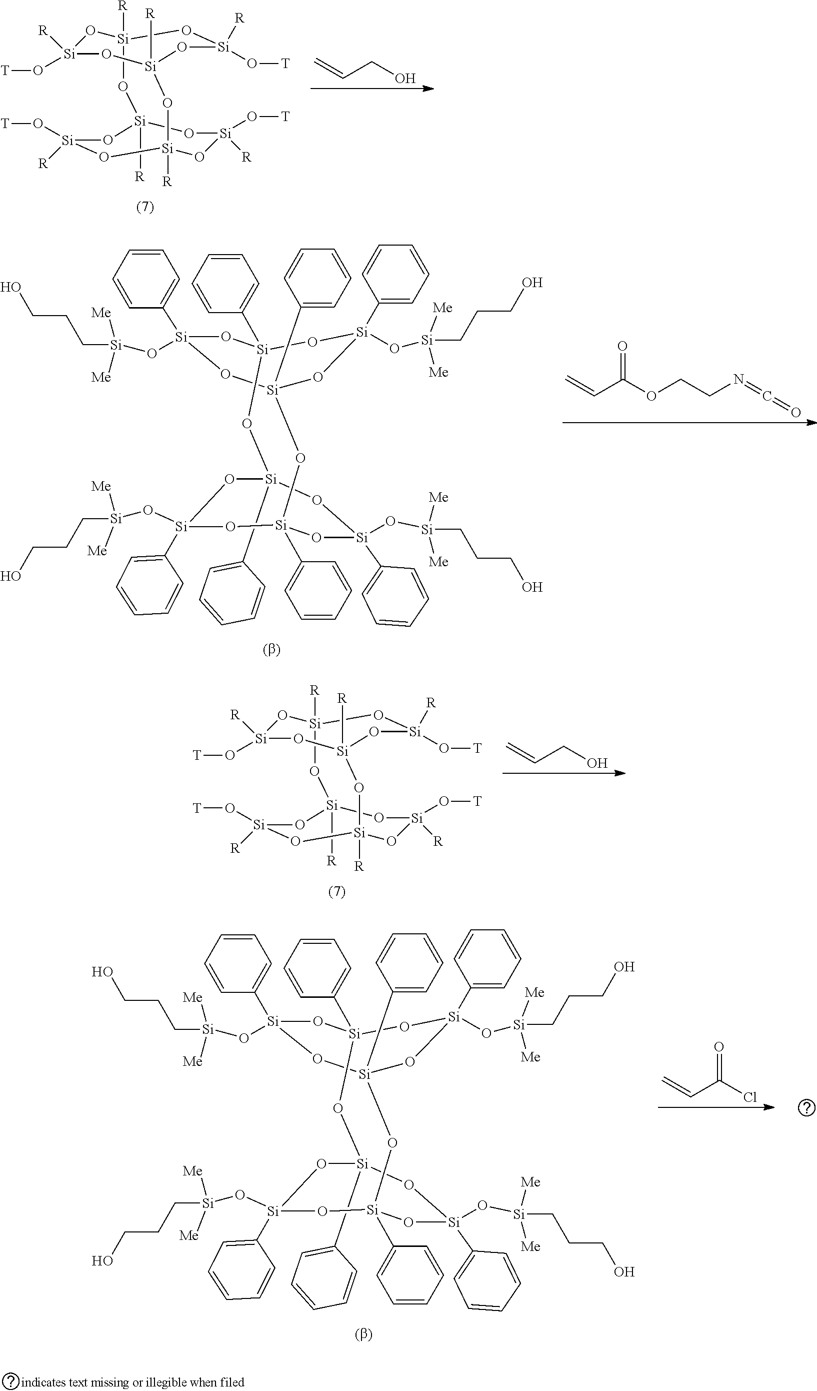

Specific examples of unsaturated alcohol include allyl alcohol, 3-butene-1-ol, 2-methyl-3-butene-1-ol, 4-penten-1-ol, 2-methyl-4-penten-1-ol, 3-methyl-4-penten-1-ol, 3-methyl-4-penten-2-ol, 4-methyl-1-penten-3-ol, 2,2-dimethyl-3-butene-1-ol, 3,3-dimethyl-2-methylene-1-butanol, ethyleneglycolmonoallyl ether, 1-(2-propene-1-yloxy)-1-propanol, 1-(2-propene-1-yloxy)-2-propanol, 2-(3-butene-1-yloxy)-ethanol and 2-[2-(2-propene-1-yloxy)ethoxy]-ethanol.

Specific examples of the compound having the isocyanate group and the radially polymerizable functional group include 2-acryloyloxyethyl isocyanate (Karenz AOI), 2-methacryloyloxyethyl isocyanate (Karenz MOI) and 1,1-(bis-acryloyloxymethyl)ethylisocyanate (Karenz BEI).

Specific examples of acrylic acid chloride include acrylic acid chloride, methacrylic acid chloride, 1-chloro-3-butene-2-one and 1-chloro-3-methyl-3-butene-2-one.

In formula (4), when unit 1 and unit s are introduced or when unit q, unit 1 and unit s are introduced, the above method is preferably used. In addition, in formula (4), each of 1, m, n, p, q, r and s represents the number of repeating units of structure in parentheses ( ) represented by “( )ₗ, ( )ₘ, ( )ₙ,” “( )ₚ,” “( )_{q},” “( )ᵣ“and” ( )ₛ.” Moreover, in formula (4), structures in the parentheses ( ) each represented by “( )ₗ,” “( )ₛ” and “( )_{q}” are referred to as unit l, unit s and unit q, respectively. A same rule applies also to unit m, unit p and unit r described below.

Moreover, when a polymerizable functional group each represented by (a-1) to (a-3) is introduced into the compound represented by formula (1), a method of allowing a compound having the isocyanate group and the radically polymerizable function group to react with a terminal hydroxyl group-containing silsesquioxane derivative is preferably used. As reaction conditions in the above case, a reaction temperature is preferably 40° C. to 120° C., and further preferably 60° C. to 100° C., and a reaction time is preferably 30 minutes to 6 hours, and further preferably 1 hour to 4 hours. The reaction is preferably carried out under air flow for suppressing a polymerization reaction of the radically polymerizable functional group, and dehydrated toluene or the like can be used as the solvent. Moreover, the compound having the isocyanate group and the radially polymerizable functional group is preferably used in a molar ratio of 1:1 to 1:5 to a terminal hydroxyl group-containing silsesquioxane derivative compound synthesized from formula (7).

When a polymerizable functional group each represented by (b-1) to (b-3) is introduced in the compound represented by formula (1), a method of allowing the compound having the isocyanate group and the radically polymerizable function group to react with the terminal hydroxyl group-containing silsesquioxane derivative is preferably used. As reaction conditions in the above case, a reaction temperature is preferably 40° C. to 120° C., and further preferably 60° C. to 100° C., and a reaction time is preferably 30 minutes to 6 hours, and further preferably 1 hour to 4 hours. The reaction is preferably carried out under air flow for suppressing the polymerization reaction of the radically polymerizable functional group, and dehydrated toluene or the like can be used as the solvent. Moreover, the compound having the isocyanate group and the radially polymerizable functional group is preferably used in a molar ratio of 1:1 to 1:5 to the terminal hydroxyl group-containing silsesquioxane derivative compound synthesized from formula (7).

Moreover, when a polymerizable functional group each represented by (a-1) and (a-5) is introduced in the compound represented by formula (1), a method of allowing acrylic acid chloride to react with the terminal hydroxyl group-containing silsesquioxane derivative is preferably used. As reaction conditions in the above case, a reaction temperature is preferably −10° C. to 50° C., and further preferably 0° C. to 30° C., and a reaction time is preferably 1 hour to 24 hours, and further preferably 3 hours to 12 hours. Each reaction is preferably carried out under an inert atmosphere such as a nitrogen atmosphere. Moreover, acrylic acid chloride is preferably used in a molar ratio of 1:1 to 1:5 to the terminal hydroxyl group-containing silsesquioxane derivative compound synthesized from formula (7).

When a polymerizable functional group represented by (b-4) or (b-5) is introduced in the compound represented by formula (1), a method of allowing acrylic acid chloride to react with the terminal hydroxyl group-containing silsesquioxane derivative is preferably used. As reaction conditions in the above case, a reaction temperature is preferably −10° C. to 50° C., and further preferably 0° C. to 30° C., and a reaction time is preferably 1 hour to 24 hours, and further preferably 3 hours to 12 hours. The above reaction is preferably carried out under the inert atmosphere such as the nitrogen atmosphere, and as the solvent, or the like can be used. Moreover, acrylic acid chloride is preferably used in a molar ratio of 1:1 to 1:5 to the terminal hydroxyl group-containing silsesquioxane derivative compound synthesized from formula (7).

Moreover, into compound (7) obtained, (ii): the epoxy group is introduced by allowing the hydrosilylation reaction of the compound having the epoxy group and the unsaturated hydrocarbon group to allow the epoxy to react with acrylic acid, whereby compound (1) can be synthesized.

In formula (4), when unit m, unit p and unit r are introduced, and when unit n, unit p and unit r are introduced, the above method is preferably used.

Examples of the unsaturated hydrocarbon group include alkenyl having 2 to 30 carbons, alkynyl having 2 to 30 carbons, arylalkenyl having 6 to 10 carbons and aryl having 6 to 10 carbons. Specific examples thereof include vinyl, allyl, isopropenyl, 3-butenyl, 2,4-pentadienyl, butadienyl, 5-hexenyl, undecenyl, ethynyl, propynyl, hexynyl, cyclopentenyl, cyclohexenyl, 3-cyclohexenylethyl, 5-bicycloheptenyl, norbornenyl, 4-cyclooctenyl, cyclooctadienyl, styryl, styrylethyl, styryloxy, allyloxypropyl, 1-methoxyvinyl, cyclopentenyloxy, 3-cyclohexenyloxy, acryloyl, acryloyloxy, methacryloyl and methacryloyloxy.

Compound (1) having two identical radically polymerizable functional groups can be obtained by allowing the hydrosilylation reaction between one compound selected from the above compounds having the epoxy group and the unsaturated hydrocarbon group, and compound (7) to allow a reaction between the epoxy and acrylic acid. In order to prepare compound (1) having at least two different functional groups, at least two different compounds each having the epoxy group and the unsaturated hydrocarbon group may be used to react with compound (7). In order to obtain compound (1) in which X being the group having the radically polymerizable functional group, and X being R are mixed, a mixture of the compound having both the epoxy group and the unsaturated hydrocarbon group, and the compound having R having no epoxy group and having the unsaturated hydrocarbon group is allowed to react with compound (7), and then the epoxy and acrylic acid only need to be reacted. On the above occasion, the reaction is carried out as the mixture at once, or the reaction is sequentially carried out one by one.

When the number of functional groups in compound (1) is desired to set to 1 to 3, and if compound (6) in a molar ratio of 1 to 3 is allowed to react with compound (5), compound (7) having a Si—H group and a Si—OH group as the functional group can be obtained. Accordingly, the above method is inconvenient for the purpose of obtaining compounds (1) to (3) each having 1 to 3 functional groups in one kind. In order to achieve the above purpose, a compound represented by formula (6) and a compound in which R is bonded in place of H in formula (6) only needs to be mixed and allowed to react with compound (5). Another method is a method of allowing compound (6) to react with compound (5) in such a manner that no Si—OH group is left. In the above case, compound (7) having 4 Si—H groups is obtained, and therefore a mixture of a compound having the functional group and the unsaturated hydrocarbon group and a compound having no functional group and having only the unsaturated hydrocarbon group only needs to be allowed to react with the compound (7).

The solvent used for the hydrosilylation reaction is selected under conditions of causing no inhibition of progress of the reaction, and is not particularly limited in other conditions. Examples of a preferred solvent are identical with the examples of the solvent used in the reaction between compound (5) and compound (6), and the solvents may be used alone, or in combination of two or more kinds. A further preferred solvent is aromatic hydrocarbons, and above all, toluene is most preferred.

When the compound having the epoxy group and the unsaturated hydrocarbon group is allowed to react with compound (5), a preferred proportion of compound (5) to the solvent is 0.05 to 80% by weight based on the weight of the solvent. A further preferred proportion is 30 to 70% by weight. A use proportion of the compound having the functional group and the unsaturated hydrocarbon group to compound (5) is different depending on a purpose. When all of four Si—H groups are allowed to react therewith, a ratio of the compound to compound (5) used for increasing the yield is preferably is 4 or more in a molar ratio. Even when a mixture of the compound having the epoxy group and the unsaturated hydrocarbon group and the compound having R and the unsaturated hydrocarbon group without having the epoxy group is allowed to react with compound (5), a total use amount thereof is required to be 4 or more in the molar ration in order to leave no Si—H group. Meanwhile, when part of the Si—H group is left, the use proportion in the total of the compound having the unsaturated hydrocarbon group only needs to be smaller than 4 in the molar ratio relative to compound (5). When the number of Si—H groups in compound (5) is less than 4, consideration only needs to be made in a similar manner according to the number of Si—H groups.

The reaction temperature may be room temperature. In order to promote the reaction, heating may be performed, when necessary. Cooling may be performed if cooling is necessary for controlling heat generation by the reaction, an unfavorable reaction or the like. When necessary, the reaction can be further easily progressed by adding a hydrosilylation catalyst. Examples of a preferred hydrosilylation catalyst include a Karstedt catalyst, a Spier catalyst and a Wilkinson catalyst, and the catalysts are generally a well-known catalyst.

The above hydrosilylation catalysts have high reactivity, and therefore addition in a small amount can sufficiently progress the reaction. The catalyst ordinarily only needs to be used in the range in which transition metal contained therein becomes 10-9 to 1 mol % relative to the hydrosilyl group. A preferred amount of addition is 10-7 to 10-3 mol %. An amount of addition of the catalyst to be required for progressing the reaction to terminate the reaction within an acceptable time is an amount in which the transition metal contained therein becomes 10-9 mol % or more relative to the hydrosilyl group. In consideration of keeping production cost low, the amount of addition of the catalyst is required to become an amount of 1 mol % or less of the transition metal contained therein relative to the hydrosilyl group.

When a polymerizable functional group represented by (c-1) or (c-2) is introduced in the compound represented by formula (1), a method of allowing acrylic acid to react with a terminal epoxy group-containing silsesquioxane derivative is preferably used. As reaction conditions in the above case, a reaction temperature is preferably 40° C. to 120° C., and further preferably 60° C. to 120° C., and a reaction time is preferably 3 hours to 12 hours, and further preferably 5 hours to 10 hours. The reaction is preferably carried out under air flow for suppressing the polymerization reaction of the radically polymerizable functional group, and dehydrated toluene or the like can be used as the solvent. Moreover, acrylic acid is preferably used in a molar ratio of 1:1 to 1:7 to the terminal epoxy group-containing silsesquioxane derivative compound synthesized from formula (7).

When the polymerizable functional group represented by (d-1) or (d-2) is introduced in the compound represented by formula (1), a method of allowing acrylic acid to react with the terminal epoxy group-containing silsesquioxane derivative is preferably used. As reaction conditions in this case, a reaction temperature is preferably 40° C. to 120° C., and further preferably 60° C. to 120° C., and a reaction time is preferably 3 hours to 12 hours, and further preferably 5 hours to 10 hours. The reaction is preferably carried out under air flow for suppressing the polymerization reaction of the radically polymerizable functional group, and dehydrated toluene or the like can be used as the solvent. Moreover, acrylic acid is preferably used in a molar ratio of 1:1 to 1:7 to the terminal epoxy group-containing silsesquioxane derivative compound synthesized from formula (7).

Another method for producing compound (1) using compound (5) is a method in which the compound represented by formula (5) or an OH form of the compound represented by formula (5) is allowed to react with compound (8) (hereinafter, also referred to as compound (8)). The above-described method (iii) in which a compound represented by formula (5) or an OH form of the compound represented by formula (5) is allowed to react with an acrylic compound having a dimethylchlorosilyl group corresponds to the reaction described above. Compound (8) has a commercially available product. The method described above is also effective when compound (8) is available as the commercially available product. Even when compound (8) is not commercially available, compound (8) can be synthesized by a method of allowing halogenated silane to react with a Grignard reagent, or a known technology of allowing the hydrosilylation reaction of halogenated hydrosilane with unsaturated hydrocarbons having a functional group, or the like.

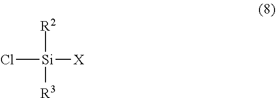

Basically, the above reaction can be carried out in a manner exactly identical with the reaction between compound (5) and compound (6). In order to increase the yield of the reaction, the preferable use amount of compound (8) is also 4 or more in a molar ratio to compound (5). Compound (1) having two identical radically polymerizable functional groups can be obtained by allowing compound (8) to react with compound (5). In order to synthesize compounds (1) having at least two different radically polymerizable functional groups, at least two different compounds (6) only need to be allowed to react with compound (5). In order to obtain compound (1) in which X being a group having the radially polymerizable functional group and X being R are mixed, a mixture of compound (8) and a compound in which X is R in the compound (8) only need to be allowed to react with compound (5). On the above occasion, in consideration of a difference in reactivity of compound (8), the reaction is carried out by using materials as a mixture at once, or the reaction is sequentially carried out one by one. When the reaction is sequentially carried out, the reactivity of the functional group becomes a hindrance in several cases, and on the above occasion, the functional group only needs to be protected in advance by using a protecting group such as trimethylsilyl. When at least two different compounds (8) are used, the total amount to be used is set to 4 or more in a molar ratio to compound (5). When the molar ratio is less than 4 or when the reactivity of compound (8) is low, compound (1) in which part of T is hydrogen is obtained.

Examples of compound (8) include acetoxyethyldimethylchlorosilane, 3-acetoxypropyldimethylchlorosilane, 3-(trimethylsiloxy)propyldimethylchlorosilane, 10-(carbomethyloxy)decyldimethylchlorosilane, chloromethyldimethylchlorosilane, chloromethylmethylchlorosilane, dichloromethyldimethylchlorosilane, bis(chloromethyl)methylchlorosilane, bromomethyldimethylchlorosilane, 3-chloropropyldimethylchlorosilane, 4-chlorobutyldimethylchlorosilane, 11-bromoundecyldimethylchlorosilane, ((chloromethyl)phenylethyl)dimethylchlorosilane, 3-cyanopropyldimethylchlorosilane, 3-cyanopropyldiisopropylchlorosilane, vinyldimethylchlorosilane, allyldimethylsilane, 5-hexenyldimethylchlorosilane, 7-octenyldimethylchlorosilane, 10-undecenyldimethylchlorosilane, vinylphenylmethylchlorosilane, vinyldiphenylchlorosilane, phenylethynyldiisopropylchlorosilane, trivinylchlorosilane, meta-arylphenylpropyldimethylchlorosilane, [2-(3-cyclohexenyl)ethyl]dimethylchlorosilane, 5-norbornene-2-yl(ethyl)dimethylchlorosilane, 3-isocyanatepropyldimethylchlorosilane, 3-methacryloxypropyldimethylchlorosilane, (3,3,3-trifluoropropyl)dimethylchlorosilane, 3,5-bis(trifluoromethyl)phenyldimethylchlorosilane, pentafluorophenyldimethylchlorosilane, pentafluorophenylpropyldimethylchlorosilane, 1H,1H,2H,2H-perfluorodecyldimethylchlorosilane and 1H,1H,2H,2H-perfluorooctyldimethylchlorosilane.

As a method for producing the silsesquioxane derivative represented by formula (2) or (3), the method described in WO 03/024870 A can be used as a reference.

The silsesquioxane derivative represented by formula (2) or (3) can be produced by allowing a compound represented by formula (5) to react with a chlorinated silicon compound containing two or more chlorines in the organic solvent in the presence or absence of a base. As a chlorinated silicon compound containing two or more chlorines, a chlorinated silicon compound such as tetrachlorosilane, a trichlorosilane compound represented by formula (9) or a dichlorosilane compound represented by formula (10) is preferably used.

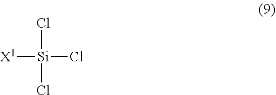

X¹ in formula (9) may be X having the radially polymerizable functional group in formula (1), and is a group independently selected from the group of hydrogen, a group of alkyl having 1 to 45 carbons, a group of substituted or unsubstituted aryl, or a group of substituted or unsubstituted arylalkyl. However, in the alkyl having 1 to 45 carbons, arbitrary hydrogen may be replaced by fluorine, arbitrary —CH₂— may be replaced by —O—, —CH═CH—, cycloalkylene or cycloalkenylene. In alkylene in the substituted or unsubstituted arylalkyl, arbitrary hydrogen may be replaced by fluorine, and arbitrary-CH₂— may be replaced by —O—, —CH═CH— or cycloalkylene.

Examples of compound (9) include acetoxyethyltrichlorosilane, (3-acryloyloxypropyl)trichlorosilane, adamanthylethyltrichlorosilane, allyltrichlorosilane, benzyltrichlorosilane, 5-(bicycloheptenyl)trichlorosilane, 2-(bicycloheptyl)trichlorosilane, 2-bromoethyltrichlorosilane, bromophenyltrichlorosilane, 3-bromopropyltrichlorosilane, p-(t-butyl)phenethyltrichlorosilane, N-butyltrichlorosilane, t-butyltrichlorosilane, 2-(methoxycarbonyl)ethyltrichlorosilane, 1-chloroethyltrichlorosilane, 2-chloroethyltrichlorosilane, 2-(chloromethyl)allyltrichlorosilane, (chloromethyl)phenethyltrichlorosilane, p-(chloromethyl)phenyltrichlorosilane, chloromethyltrichlorosilane, chlorophenytrichlorosilane, 3-chloropropyltrichlorosilane, (3-cyanobutyl)trichlorosilane, 2-cyanoethyltrichlorosilane, 3-cyanopropyltrichlorosilane, (3-cyclohexenyl)ethyltrichlorosilane, 3-cyclohexenyltrichlorosilane, (cyclohexylmethyl)trichlorosilane, cyclohexyltrichlorosilane, (4-cyclooctenyl)trichlorosilane, cyclooctyltrichlorosilane, cyclopentyltrichlorosilane, n-decyltrichlorosilane, 1,2-dibromoethyltrichlorosilane, 1,2-dichloroethyltrichlorosilane, (dichloromethyl)trichlorosilane, dichlorophenyltrichlorosilane, dodecyltrichlorosilane, eicosyltrichlorosilane-docosyltrichlorosilane, ethyltrichlorosilane, (heptadecafluoro-1,1,2,2-tetrahydrodecyl)trichlorosilane, (3-heptafluoroisopropoxy)propyltrichlorosilane, n-heptyltrichlorosilane, hexachlorodisilane, hexachlorodisiloxane, n-hexadecyltrichlorosilane, 5-hexenyltrichlorosilane, hexyltrichlorosilane, isobutyltrichlorosilane, isooctyltrichlorosilane, methacryloyl oxypropyl trichlorosilane, 3-(p-methoxyphenyl)propyltrichlorosilane, methyltrichlorosilane, 3,3,4,4,5,5,6,6,6-nonafluorohexyltrichlorosilane, nonyltrichlorosilane, n-octadecyltrichlorosilane, 7-octenyltrichlorosilane, n-octyltrichlorosilane, pentafluorophenylpropyl trichlorosilane, pentyltrichlorosilane, phenethyltrichlorosilane, 3-phenoxypropyltrichlorosilane, phenyltrichlorosilane, n-propyltrichlorosilane, p-tolyltrichlorosilane, trichloromethyltrichlorosilane, (tridecafluoro-1,1,2,2-tetrahydrooctyl)trichlorosilane, (3,3,3-trifluoropropyl)trichlorosilane and vinyltrichlorosilane.

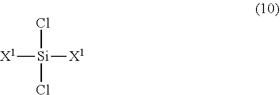

X¹ in formula (10) may be independently X having the radially polymerizable functional group, and is a group independently selected from hydrogen, a group of alkyl having 1 to 45 carbons, a group of substituted or unsubstituted aryl and a group of substituted or unsubstituted arylalkyl. However, in the alkyl having 1 to 45 carbons, arbitrary hydrogen may be replaced by fluorine, and arbitrary —CH₂— may be replaced by —O—, —CH═CH—, cycloalkylene or cycloalkenylene. In alkylene in the substituted or unsubstituted arylalkyl, arbitrary hydrogen may be replaced by fluorine, and arbitrary-CH₂— may be replaced by —O—, —CH═CH— or cycloalkylene.

Examples of compound (10) include acetoxyethylmethyldichlorosilane, acetoxypropylmethyldichlorosilane, (3-acryloyloxypropyl)methyldichlorosilane, allyl(chloropropyl)dichlorosilane, allyl(2-cyclohexenylethyl)-dichlorosilane, allyldichlorosilane, allylhexyldichlorosilane, allylmethyldichlorosilane, allylphenyldichlorosilane, 5-(bicycloheptenyl)methyldichlorosilane, butenylmethyldichlorosilane, t-butyldichlorosilane, N-butylmethyldichlorosilane, t-butylmethyldichlorosilane, t-butylphenyldichlorosilane, 2-(methoxycarbonyl)ethylmethyldichlorosilane, 2-chloroethylmethyldichlorosilane, chloromethylmethyldichlorosilane, ((chloromethyl)phenethyl)methyldichlorosilane, 2-(chloromethyl)propylmethyldichlorosilane, chlorophenylmethyldichlorosilane, 3-chloropropylmethyldichlorosilane, 3-chloropropylphenyldichlorosilane, (3-cyanobutyl)methyldichlorosilane, 2-cyanoethylmethyltrichlorosilane, 3-cyanopropylmethyldichlorosilane, 3-cyanopropylphenyldichlorosilane, (3-cyclohexenylethyl)methyldichlorosilane, cyclohexylmethyldichlorosilane, cyclobutenyldichlorosilane, cyclopropenyldichlorosilane, n-decylmethyldichlorosilane, diaryldichlorosilane, n-butyldichlorosilane, di-t-butyldichlorosilane, 1,1-dichloro-3,3-dimethyl-1,3-disilabutane, 1,3-dichloro-1,3-diphenyl-1,3-dimethyldisiloxane, (dichloromethyl)methyldichlorosilane, 1,3-dichlorotetramethyldisiloxane, 1,3-dichlorotetraphenyldisiloxane, dichlorotetramethyldisilane, dicyclohexyldichlorosilane, dicyclopentyldichlorosilane, diethyldichlorosilane, di-n-hexyl dichlorosilane, diisopropyldichlorosilane, dimesityldichlorosilane, dimethyldichlorosilane, di-n-octyldichlorosilane, diphenyldichlorosilane, di(p-tolyl)dichlorosilane, divinyldichlorosilane, 1,3-divinyl-1,3-dimethyl-1,3-dichlorosilane, ethyldichlorosilane, ethylmethyldichlorosilane, (heptadecafluoro-1,1,2,2-tetrahydrodecyl)methyldichlorosilane, n-heptylmethyldichlorosilane, hexyldichlorosilane, hexylmethyldichlorosilane, isobutylmethyldichlorosilane, isopropylmethyldichlorosilane, methacryloyloxypropylmethyldichlorosilane, 3-(p-methoxyphenyl)propylmethyldichlorosilane, methylpentyldichlorosilane, p-(methylphenethyl)methyldichlorosilane, 2-methyl-2-phenylethyldichlorosilane, 3,3,4,4,5,5,6,6,6-nonafluorohexylmethyldichlorosilane, n-octylmethyldichlorosilane, phenethylmethyldichlorosilane, phenyldichlorosilane, phenylethyldichlorosilane, phenylmethyldichlorosilane, (3-phenylpropyl)methyldichlorosilane, 1-allylmethyldichlorosilane, propylmethyldichlorosilane, p-tolylmethyldichlorosilane, (tridecafluoro-1,1,2,2-tetrahydrooctyl)methyldichlorosilane, (3,3,3-trifluoropropyl)methyldichlorosilane, vinylethyldichlorosilane, vinylmethyldichlorosilane, vinyloctyldichlorosilane, vinylphenyldichlorosilane and methyldichlorosilane.

As a method of introducing a substituent, such a method is preferably used as a method (i) of introducing the radially polymerizable functional group by preparing a terminal hydroxyl group by allowing a hydrosilylation reaction of a hydroxyl group of allyl alcohol or the like with a compound having the terminal unsaturated hydrocarbon group, and then allowing the resulting material to react with the compound having the isocyanate group and the radially polymerizable functional group, acrylic acid chloride or the like, a method (ii) of introducing the group by introducing an epoxy group by a hydrosilylation reaction and by a reaction between the epoxy and acrylic acid, and a method (iii) of converting a chlorosilane terminal silsesquioxane compound obtained by allowing formula (5) to react with formula (9) into an OH form, and allowing an acrylic compound having a dimethylchlorosilyl group to react therewith.

Structure of the compound thus obtained can be performed by nuclear magnetic resonance (NMR) and a matrix-assisted laser desorption/ionization method (MALDI-TOF-MS) described in Examples below. Moreover, a skeleton of silsesquioxane can be analyzed by a 29Si NMR, and presence of the functional group such as the acrylic group can be analyzed by a Fourier transform infrared spectrophotometer (FT-IR).

### 2. Resin Composition

A first embodiment of the invention relates to an acrylic resin composition containing acrylic resin (A) and at least one kind selected from silsesquioxane derivatives (B) represented by formula (1), (2) or (3). Acrylic resin (A) is referred to as component (A), and silsesquioxane derivative (B) represented by formula (1), (2) or (3) is referred to as component (B) in several cases. Any other component of the resin composition is simplified and referred to in a similar manner in several cases.

### Acrylic Resin (A)

Examples of the acrylic resin include a polymer of methyl methacrylate, a copolymer containing a methyl methacrylate component in an amount of 80% by weight or more, a mixture of the polymer or copolymer with another polymers, a polymer of acrylonitrile, a copolymer containing an acrylonitrile component in an amount of 80% or more, and a mixture of the polymer or the copolymer with another polymers.

Specific examples of a monomer to be used for copolymerization include ethyl methacrylate, butyl methacrylate, methyl acrylate, ethyl acrylate, butyl acrylate, 2-hydroxyethyl methacrylate, 2-hydroxyethyl acrylate, methacrylic acid, acrylamide, N-methylolacrylamide, styrene and vinyl acetate.

As the acrylic resin, a (meth)acrylic resin is preferred, and above all, a polyfunctional monomer-type (meth)acrylic resin is preferred.

A weight average molecular weight of the acrylic resin is preferably 100 to 100,000, further preferably 150 to 10,000, and still further preferably 200 to 5,000. If the weight average molecular weight is within the above range, mixing property, solubility and handling become satisfactory.

Moreover, as the acrylic resin, a commercial item as described below can be used.

Specific examples of the commercial item include trade name: (hereinafter, omitted) 701A (2-hydroxy-3-acryloyloxypropylmethacrylate), A-200 (polyethyleneglycol #200 diacrylate), A-400 (polyethyleneglycol #400 diacrylate), A-600 (polyethyleneglycol #600 diacrylate), A-1000 (polyethyleneglycol #1000 diacrylate), A-B1206PE (propoxylated-ethoxylated bisphenol-A diacrylate), ABE-300 (ethoxylated bisphenol-A diacrylate), A-BPE-10 (ethoxylated bisphenol-A diacrylate), A-BPE-20 (ethoxylated bisphenol-A diacrylate), A-BPE-30 (ethoxylated bisphenol-A diacrylate), A-BPE-4 (ethoxylated bisphenol-A diacrylate), A-BPEF (9,9-bis[4-(2-acryloyloxyethoxy)phenyl] fluorene), A-BPP-3 (propoxylated bisphenol-A diacrylate), A-DCP (tricyclodecanedimethanol diacrylate), A-DOD-N(1,10-decanediol diacrylate), A-HD-N(1,6-hexanediol diacrylate), A-NOD-N (1,9-nonanediol diacrylate), APG-100 (dipropylene glycol diacrylate), APG-200 (tripropylene glycol diacrylate), APG-400 (polypropyleneglycol #400 diacrylate), APG-700 (polypropyleneglycol (#700) diacrylate), A-PTMG-65 (polytetramethyleneglycol #650 diacrylate), A-9300 (ethoxylated isocyanuric acid triacrylate), A-9300-1CL (ε-caprolactone-modified tris-(2-acryloxyethyl)isocyanurate), A-GLY-9E (ethoxylated glyceryl triacrylate), A-GLY-20E ethoxylated glyceryl triacrylate, A-TMM-3 (pentaerythritol triacrylate (triester 37%)), A-TMM-3L (pentaerythritol triacrylate (triester 55%)), A-TMM-3LM-N (pentaerythritol triacrylate (triester 57%)), A-TMPT (trimethylolpropane triacrylate), AD-TMP (ditrimethylolpropanetetraacrylate), ATM-35E (ethoxylated pentaerythritol tetraacrylate), A-TMMT (pentaerythritol tetraacrylate), A-9550 (dipentaerythritol polyacrylate), A-DPH (dipentaerythritol hexaacrylate), U-6LPA (hexafunctional urethane acrylate oligomer), UA-1100H (hexafunctional urethane acrylate oligomer), U-15HA (pentadecafunctional urethane acrylate oligomer), UA-160TM (difunctional urethane acrylate oligomer), UA-122P (difunctional urethane acrylate oligomer), UA-7100 (trifunctional urethane acrylate oligomer) and UA-W2A (difunctional urethane acrylate oligomer) made by Shin-Nakamura Chemical Co., Ltd., trade name: (hereinafter, omitted) ARONIX (registered trade name) M-208 (bisphenol F, EO-modified (n is approximately equal to or the image of 2) diacrylate), M-211B (bisphenol-A, EO-modified (n is approximately equal to or the image of 2) diacrylate), M-215 (isocyanuric acid EO-modified diacrylate), M-220 (tripropylene glycol (n is approximately equal to or the image of 3) diacrylate), M-240 (polyethyleneglycol (n is approximately equal to or the image of 4) diacrylate), M-309 (trimethylolpropane triacrylate), M-321 (trimethylolpropane PO-modified (n is approximately equal to or the image of 2) triacrylate), M-350 (trimethylolpropane EO-modified (n is approximately equal to or the image of 1) triacrylate), M-315 (isocyanuric acid EO-modified di- and tri-acrylate), M-305 (pentaerythritol tri- and tetra-acrylate), M-450 (pentaerythritol tri- and tetra-acrylate) M-408 (ditrimethylolpropanetetraacrylate), M-400 (dipentaerythritol penta- and hexa-acrylate), M-402 (dipentaerythritol penta- and hexa-acrylate), M-460 (diglycerol EO-modified acrylate), M-1100 (difunctional urethane acrylate oligomer) M-1200 (difunctional urethane acrylate oligomer) made by Toagosei Co., Ltd., trade name: KAYARAD (hereinafter, omitted) R-128H, NPGDA, PEG-400DA, FM-400, R-167, HX-220, HX-620, R-551, R-712, R-604, R-684, GPO-303, TMPTA, THE-330, TPA-330, PET-30, T-1420 (T), RP-1040, DPHA, DPEA-12, FM-700, D-310, DPCA-20, DPCA-30, DPCA-60, DPCA-120, R-115, R-130, R381, EAM-2160, UX-3204, UX-4101, UXT-6100, UX-0937, UXF-4001-M35, UXF-4002, DPHA-40H, UX-5000, UX-5102D-M20, UX-5103D and UX-5005 made by Nippon kayaku co., ltd., trade name: SHIKOH UV-1700B, UV-6300B, UV-7550B, UV-7600B, UV-7605B, UV-7610B, UV-7620EA, UV-7630B, UV-7640B and UV-7650B made by The Nippon Synthetic Chemical Industry Co., Ltd., trade name: Light Acrylate (hereinafter, omitted) HOA-MS (N), HOA-HH (N), HOA-MPL (N), HOA-MPE (N), BA-104, P-1A (N), 3EG-A, 4EG-A, 9EG-A (PEG 400# diacrylate), 14EG-A (PEG 600# diacrylate), PTMGA-250 (polytetramethyleneglycol diacrylate), NP-A (neopentyl glycol diacrylate), MPD-A (3-methyl-1.5 pentanediol diacrylate), 1.6HX-A (1.6-hexanediol diacrylate), 1.9ND-A (simethylol-tricyclodecane diacrylate), DCP-A (dimethylol-tricyclodecane diacrylate), BP-4EAL (diacrylate of ethyleneoxide-modified bisphenol A), BP-4PA (diacrylate of propyleneoxide-modified bisphenol A), HPP-A (hydroxypyvalypivlate diacrylate) TMP-A (trimethylolpropane triacrylate), PE-3A (pentaerythritol triacrylate), PE-4A (pentaerythritol tetraacrylate), DPE-6A (dipentaerythritol hexaacrylate), and trade name: Epoxy ester (hereinafter, omitted) 70PA, 200PA, 80MFA, 3002M (N), 3002A (N), 3000MK and 3000A made by Kyoeisha Chemical Co., Ltd.

Above all, dipentaerythritol hexaacrylate (trade name: KAYARAD DPHA made by Nippon Kayaku Co., Ltd., trade name: A-DPH made by Shin-Nakamura Chemical Co., Ltd., and trade name: Light Acrylate DPE-6A made by Kyoeisha Chemical Co., Ltd.) is preferably used.

A proportion of the acrylic resin is preferably 10 to 95% by mass based on the total amount of solid content in the resin composition. If the proportion of the acrylic resin is within the above range, a balance among low warpage, heat resistance, chemical resistance and adhesion is satisfactory. A further preferred proportion of the acrylic resin is in the range of 20 to 60% by mass. In addition, the solid content of the resin composition means polymers and a filler such as nanosilica. A surface control agent, a photoradical generator, the solvent or the like is excluded from the solid content.

### Silsesquioxane Derivative (B) Represented by Formulas (1), (2) or (3)

A resin composition according to second embodiment of the invention contains at least one kind of silsesquioxane derivatives represented by formula (1), silsesquioxane derivatives represented by formula (2) or silsesquioxane derivatives represented by formula (3), which are described in the first embodiment.

In the total amount of silsesquioxane derivatives (B) represented by formula (1), (2) or (3), a mass ratio of a content of acrylic resin (A) to a content of silsesquioxane derivatives (B) in the resin composition is preferably 10:90 to 95:5, further preferably 40:60 to 80:20, and still further preferably 50:50 to 70:30.

The resin composition exhibits excellent characteristics on low warpage, heat resistance, transparency, yellowing resistance, resistance to heat-induced yellowing, light resistance, surface hardness and adhesion by adjusting the content to the above range.

### Photoradical Polymerization Initiator (C)

The photoradical polymerization initiator is not particularly limited if the photoradical polymerization initiator generates radicals by irradiation with ultraviolet light or visible light.

Examples of the photopolymerization initiator include benzophenone, Michler's ketone, 4,4′-bis(diethylamino)benzophenone, xanthone, thioxanthone, isopropylxanthone, 2,4-diethylthioxanthone, 2-ethylanthraquinone, acetophenone, 2-hydroxy-2-methylpropiophenone, 2-hydroxy-2-methyl-4′-isopropylpropiophenone, 1-hydroxycyclohexylphenyl ketone, isopropylbenzoin ether, isobutylbenzoin ether, 2,2-diethoxyacetophenone, 2,2-dimethoxy-2-phenylacetophenone, camphorquinone, benzanthrone, 2-methyl-1-[4-(methylthio)phenyl]-2-morpholinopropane-1-one, 2-benzyl-2-dimethylamino-1-(4-morpholinophenyl)-butanone-1,4-dimet hylaminoethylbenzoate, 4-dimethylaminoisoamylbenzoate, 4,4′-di(t-butylperoxycarbonyl)benzophenone, 3,4,4′-tri(t-butylperoxycarbonyl)benzophenone, 2,4,6-trimethylbenzoyldiphenylphosphine oxide, 2-(4′-methoxystyryl)-4,6-bis(trichloromethyl)-s-triazine, 2-(3′,4′-dimethoxystyryl)-4,6-bis(trichloromethyl)-s-triazine, 2-(2′,4′-dimethoxystyryl)-4,6-bis(trichloromethyl)-s-triazine, 2-(2′-methoxystyryl)-4,6-bis(trichloromethyl)-s-triazine, 2-(4′-pentyloxystyryl)-4,6-bis(trichloromethyl)-s-triazine, 4-[p-N,N-di(ethoxycarbonylmethyl)]-2,6-di(trichloromethyl)-s-tria zine, 1,3-bis(trichloromethyl)-5-(2′-chlorophenyl)-s-triazine, 1,3-bis(trichloromethyl)-5-(4′-methoxyphenyl)-s-triazine, 2-(p-dimethylaminostyryl)benzoxazole, 2-(p-dimethylaminostyryl)benzthiazole, 2-mercaptobenzothiazole, 3,3′-carbonylbis(7-diethylaminocoumarin), 2-(o-chlorophenyl)-4,4′,5,5′-tetraphenyl-1,2′-biimidazole, 2,2′-bis(2-chlorophenyl)-4,4′,5,5′-tetrakis(4-ethoxycarbonylphenyl)-1,2′-biimidazole, 2,2′-bis(2,4-dichlorophenyl)-4,4′,5,5′-tetraphenyl-1,2′-biimidazol e, 2,2′-bis(2,4-dibromophenyl)-4,4′,5,5′-tetraphenyl-1,2′-biimidazole, 2,2′-bis(2,4,6-trichlorophenyl)-4,4′,5,5′-tetraphenyl-1,2′-biimida zole, 3-(2-methyl-2-dimethylaminopropionyl)carbazole, 3,6-bis(2-methyl-2-morpholinopropionyl)-9-n-dodecylcarbazole, 1-hydroxycyclohexylphenyl ketone and bis(η5-2,4-cyclopentadiene-1-yl)-bis(2,6-difluoro-3-(H-pyrrole-1-yl)-phenyl)titanium.

The above compounds may be used alone, and are effective by using in combination with two or more kinds thereof.

Specific examples of a commercially available photoradical polymerization initiator include 2-hydroxy-2-methyl-1-phenylpropane-1-one (DAROCUR 1173, IRGACURE 1173), 1-hydroxycyclohexylphenyl ketone (IRGACURE 184), 2,2-dimethoxy-1,2-diphenylethane-1-one (IRGACURE 651), IRGACURE 127, IRGACURE 500 (a mixture of IRGACURE 184 and benzophenone), IRGACURE 369, IRGACURE 379, IRGACURE 754, IRGACURE 1300, IRGACURE 819, IRGACURE 1700, IRGACURE 1800, IRGACURE 1850, IRGACURE 1870, DAROCUR 4265, DAROCUR MBF, DAROCUR TPO, IRGACURE 784 and IRGACURE 754. Both of DAROCUR and IRGACURE described above is a name of the products available from BASF Japan Ltd.

Above all, from viewpoints of compatibility with the resin and small heat-induced yellowing, IRGACURE 184 or IRGACURE 1173 is preferred.

An amount of the photoradical polymerization initiators to be used in polymerization is preferably in an addition amount of 0.5% by mass or more, further preferably 1% by mass or more, and still further preferably 3% by mass or more, and preferably 15% by mass or less, further preferably 10% by mass or less, and still further preferably 7% by mass or less, based on the solid content of the resin composition.

### Nanosilica Filler (D)

A resin composition, which is one embodiment according to the invention, can contain a nanosilica filler.

Thermal conductivity and electrical insulation properties can be provided by adding the nanosilica filler. Moreover, addition of the nanosilica filler also contributes to suppression on the reduction of hardness (scratch resistance) and resistance to moist heat.

A mean particle diameter of the nanosilica filler is not limited as long as the diameter thereof is in a nanometer order, and is preferably 1 to 100 nanometers, and from a viewpoint of transparency, further preferably 1 to 40 nanometers, and still further preferably 1 to 20 nanometers. Moreover, a particle size distribution is preferably narrower.

A shape of the nanosilica filler is not particularly limited, and may be any shape such as a spherical shape, an infinite shape and a scaly shape, and from viewpoints of adhesion improvement and transparency, a spherical shape is preferred. In addition, when the shape of the nanosilica filler is other than the spherical shape, the mean particle diameter of the nanosilica filler means a mean maximum diameter of the filler.

Moreover, the nanosilica filler may be subjected to surface treatment with a silane coupling agent or the like.

In the resin composition, a content of the nanosilica filler as component (D) is preferably 5% by mass or more and 35% by mass or less, and further preferably 10% by mass or more and 20% by mass or less, in terms of % by mass based on the total amount of the solid content total amount of the resin composition.

In the present embodiment, the resin composition may be used by adding the nanosilica filler to the acrylic resin, or a commercial item in which the nanosilica filler is dispersed in a resin may be used.

Specific examples of such a commercial item include a nanosilica-dispersed epoxy resin {Nanopox (registered trademark) series (C620, F400, E500, E600, E430)} in which 40% by mass of nanosilica is dispersed in an epoxy resin, and Nanocryl (registered trademark) series (C130, C140, C145, C146, C150, C153, C155, C165, C350) in which 50% by mass of nanosilica is dispersed in an acrylate resin, both made by Evonik industries AG. In addition, when a commercial item in which the nanosilica filler is dispersed in the resin is used, an amount of component (D) is the amount of the nanosilica filler therein.

Moreover, various components such as any other resin, a surfactant and an antioxidant can be added to the resin composition, when necessary.

### Solvent (E)

The resin composition, which is one embodiment according to the invention, may contain the solvent. Examples of the solvent include a hydrocarbon-based solvent (hexane, benzene or toluene), an ether-based solvent (diethyl ether, tetrahydrofuran (THF), 2-methyltetrahydrofuran, diphenyl ether, anisole, dimethoxybenzene, or cyclopentyl methyl ether (CPME)), a halogenated hydrocarbon-based solvent (methylene chloride, chloroform, or chlorobenzene), a ketone-based solvent (acetone, methyl ethyl ketone, or methyl isobutyl ketone), an alcohol-based solvent (methanol, ethanol, propanol, isopropanol, n-butyl alcohol, or t-butyl alcohol), a nitrile-based solvent (acetonitrile, propionitrile, or benzonitrile), an ester-based solvent (ethyl acetate, or butyl acetate), a carbonate-based solvent (ethylene carbonate, or propylene carbonate), an amide-based solvent (N,N-dimethylformamide, N,N-dimethylacetamide or N-methylpyrrolidone), a hydrochlorofluorocarbon-based solvent (HCFC-141b or HCFC-225), a hydrofluorocarbon (HFCs)-based solvent (HFCs having 2 to 4, 5 and 6, or more carbons), a perfluorocarbon-based solvent (perfluoropentane or perfluorohexane), an alicyclic hydrofluorocarbon-based solvent (fluorocyclopentane or fluorocyclobutane), an oxygen-containing fluorine-based solvent (fluoroether, fluoropolyether, fluoroketone or fluoroalcohol), an aromatic-based fluorine solvent (α,α,α-trifluorotoluene or hexafluorobenzene) and water. Above all, methyl ethyl ketone, methyl isobutyl ketone or the like is preferred from viewpoints of varnish preparation or film formation. The above materials may be used alone or in combination with two or more kinds.

For example, from a viewpoint of applicability, an amount of the solvent to be used is at a level at which a total content of acrylic resin (A) and silsesquioxane derivative (B) represented by formula (1), (2) or (3) preferably becomes 20 to 80% by mass, and further preferably becomes 30 to 70% by mass, and still further preferably becomes 40 to 60% by mass, based on the total amount of the acrylic resin composition.

### Surface Control Agent (F)

The resin composition, which is one embodiment according to the invention, may contain the surface control agent.

Examples of the surface control agent can include a silicon-based surface control agent, an acrylic-based surface control agent and a fluorine-based surface control agent, and among them, from a viewpoint of particularly adhesion with a substrate, a (meth)acryloyl group-containing polysiloxane surface control agent is preferred.

Examples of the silicon-based surface control agent include organopolysiloxane such as dimethylpolysiloxane, and a modified silicon in which organopolysiloxane is modified. Specific examples of the modified silicon include alkyl-modified polysiloxane, phenyl-modified polysiloxane and polyether-modified polysiloxane.

Specific examples thereof include dimethylpolysiloxane, methylphenylpolysiloxane, polyether-modified polydimethylsiloxane, polyether-modified dimethylpolysiloxane, polyester-modified dimethylpolysiloxane, polyester-modified polydimethylsiloxane, polymethylalkylsiloxane, polyester-modified polymethylalkylsiloxane and aralkyl-modified polymethylalkylsiloxane. The above materials can be used alone or in combination with two or more kinds thereof.

Specific examples of a polymerizable unsaturated group include a (meth)acryloyl group and a vinyl group. The number of the polymerizable unsaturated group contained therein is not particularly limited, but in view of activated energy ray hardenability under presence of the photopolymerization initiator, the polymerizable unsaturated group may be contained at least in the number of 1 or more, and preferably 2 or more.

Specific examples of an unsaturated group-containing silicon-based surface control agent include (meth)acryloyl group-containing polysiloxane, vinyl group-containing polysiloxane, any other polymerizable unsaturated group-containing polyether-modified polysiloxane and polymerizable unsaturated group-containing polyester-modified polysiloxane.

As the polymerizable unsaturated group-containing silicon-based surface control agent, a commercial item can be used. Specific examples of the (meth)acryloyl group-containing polysiloxane include BYK-UV-3500, BYK-UV-3510, BYK-UV-3570 (trade name, made byBYK-Chemie Japan); Silaplane FM-0711, FM-0721, FM-0725, FM-7711, FM-7721, FM-7725 (trade name, made by JNC Corporation), X-22-2457, X-22-2458, X-22-2459, X-22-1602, X-22-1603 (trade name, made by Shin-Etsu Chemical Co., Ltd.); and TEGO Rad-2100, -2200N, -2250, -2300, -2500, -2600 and -2700 (TEGO Rad series, trade name, made by an Evonik Japan Co., Ltd.). Moreover, examples of the vinyl group-containing polysiloxane include Silaplane FM-2231 (trade name, made by JNC Corporation).

Above all, from a viewpoint of compatibility with resins, Silaplane FM-0711 is preferably used.

An amount of blending the surface control agent is preferably 0.01% by mass or more, and further preferably 0.05% by mass or more, and preferably 3% by mass or less, and further preferably 1.5% by mass or less, as an addition amount based on the solid content of the resin composition.

### Chain Transfer Agent (G)

A chain transfer agent may be added in the composition received. Use of the chain transfer agent can appropriately control molecular weight. Specific examples of the chain transfer agent include mercaptans such as thio-R-naphthol, thiophenol, n-butyl mercaptan, ethyl thioglycolate, mercaptoethanol, mercaptoacetic acid, isopropyl mercaptan, t-butyl mercaptan, dodecanethiol, thiomalic acid, pentaerythritol tetra(3-mercaptopropionate) and pentaerythritol tetra(3-mercapto acetate); disulfides such as diphenyl disulfide, diethyl dithioglycolate and diethyl disulfide; and also include toluene, methyl isobutyrate, carbon tetrachloride, isopropylbenzene, diethyl ketone, chloroform, ethylbenzene, butyl chloride, s-butyl alcohol, methyl ethyl ketone, methyl isobutyl ketone (MIBK), propylene chloride, methyl chloroform, t-butylbenzene, n-butyl alcohol, isobutyl alcohol, acetic acid, ethyl acetate, acetone, dioxane, ethane tetrachloride, chlorobenzene, methylcyclohexane, t-butyl alcohol and benzene.

The chain transfer agent is preferably mercaptans. In particular, mercaptoacetic acid decreases molecular weight of a polymer to be able to uniformize a molecular weight distribution. The chain transfer agent can be used alone or by mixing two or more kinds thereof.

### Any Other Resin (H)

The resin composition, which is one embodiment according to the invention, may contain a resin (any other resin) other than the acrylic resin in the range in which advantageous effects of the invention are not adversely affected. As the resin other than the acrylic resin, a resin containing a crosslinkable functional group is preferred.

For example, from viewpoints of high-speed curing of the acrylic resin, namely prompt curing in air, improvement of curability inside of the resin, suppression of cure shrinkage or the like, an epoxy resin, an oxetane resin, a resin having a vinyl ether group, such as cyclohexanedimethanol divinyl ether can be used.

Specific examples of the commercial item include an oxetane resin {Aron Oxetane (trade name) OXT-221}, {Aron Oxetane (trade name) OXT-101}, {Aron Oxetane (trade name) OXT-212} and {Aron Oxetane (trade name) OXT-121}, made by Toagosei Co., Ltd., vinyl ether {1,4-cyclohexanedimethanol divinyl ether} made by Sigma-Aldrich K.K., and {cyclohexanedimethanol divinyl ether (abbreviation) CHDVE}, {triethyleneglycol divinyl ether (abbreviation) TEGDVE}, {1,4-butanediol divinyl ether (abbreviation) BDVE} and {diethyleneglycol divinyl ether (abbreviation) DEGDVE}, made by Nippon Carbide Industries Co., Inc.

### Curing Agent (I)

When any other resin is added, a cationic polymerization initiator, an acid anhydride-based curing agent, an amine-based curing agent, a phenol-based curing agent or the like may be added.

### Cationic Polymerization Initiator

Examples of the cationic polymerization initiator include an active energy ray polymerization initiator that generates cationic species or Lewis acid by active energy rays such as ultraviolet light, and a thermal polymerization initiator that generates cationic species or Lewis acid by heat. An active energy ray cationic polymerization initiator includes an initiator that generates cationic species by heat, such as part of aromatic onium salt, and such a salt can also be used as a thermal cationic polymerization initiator.

Examples of the active energy ray cationic polymerization initiator include an arylsulfonium complex salt, an aromatic sulfonium or iodonium salt of a halogen-containing complex ion, and an aromatic onium salt of group II, V and VI elements. Several of the above salts can be obtained as a commercial product. Specific examples of the active energy ray cationic polymerization initiator include {CPI-110P (registered trademark)}, {CPI-210K (registered trademark)}, {CPI-210S (registered trademark)}, {CPI-300PG (registered trademark)} and {CPI-410S (registered trademark)}, made by San-Apro Ltd., {Adekaoptomer (registered trademark) SP-130}, {Adekaoptomer (registered trademark) SP-140}, {Adekaoptomer (registered trademark) SP-150}, {Adekaoptomer (registered trademark) SP-170} and {Adekaoptomer (registered trademark) SP-171}, made by ADEKA Corporation, and {IRGACURE (registered trademark) 250}, {IRGACURE (registered trademark) 270} and {IRGACURE (registered trademark) 290}, made by BASF Japan Ltd.

As the thermal cationic polymerization initiator, a cationic or protonic acid catalyst such as a salt of triflic acid and boron trifluoride is used. Examples of a preferred thermal cationic polymerization initiator is a salt of triflic acid, and specific examples thereof include diethylammonium triflate, diisopropylammonium triflate and ethyldiisopropylammonium triflate. On the other hand, aromatic onium salts used also as the active energy ray cationic polymerization initiator include several salts that generate cationic species by heat, and the salts can also be used as the thermal cationic polymerization initiator.

The thermal cationic polymerization initiator can be blended uniformly in the resin composition, and the resin composition can be cured in a catalyst type, and therefore can be cured at low temperature and in a short period of time and has good solvent stability, and such a case is preferred. Moreover, among the above cationic polymerization initiators, an aromatic onium salt is preferred in view of excellence in a balance among handling and a potential and curability, and above all, a diazonium salt, an iodonium salt, a sulfonium salt and a phosphonium salt are preferred in view of excellence in a balance between handling and a potential. The cationic polymerization initiators can be used alone or in combination with two or more kinds thereof.

Specific examples of a commercial item of the thermal cationic polymerization agent include trade names “Adekaopton CP-66” and “CP-77,” made by ADEKA Corporation: trade names “SAN-AID SI-45L,” “SI-60L,” “SI-80L,” “SI-100L,” “SI-110L,” “SI-180L,” “SI-B2A,” “SI-B3” and “SI-B3A,” made by SANSHIN CHEMICAL INDUSTRY CO., LTD. and trade name “FC-520,” made by 3M Japan Limited. The heat cationic polymerization initiators may be used alone in one kind or in combination with two or more kinds thereof.

### Acid Anhydride

Specific examples of the acid anhydride include phthalic anhydride, maleic anhydride, trimellitic anhydride, pyromellitic anhydride, hexahydrophthalic anhydride, 3-methyl-cyclohexanedicarboxylic anhydride, 4-methyl-cyclohexanedicarboxylic anhydride, a mixture of 3-methyl-cyclohexanedicarboxylic anhydride and 4-methyl-cyclohexanedicarboxylic anhydride, tetrahydrophthalic anhydride, nadic anhydride, methylnadic anhydride, norbornane-2,3-dicarboxylic anhydride, methylnorbornane-2,3-dicarboxylic anhydride, cyclohexane-1,3,4-tricarboxylic acid-3,4-anhydride and a derivative thereof. Above all, 4-methyl-cyclohexanedicarboxylic anhydride and a mixture of 3-methyl-cyclohexanedicarboxylic anhydride and 4-methyl-cyclohexanedicarboxylic anhydride are liquid at room temperature, and therefore can be easily handled, and are preferred.

### Amine

Specific examples of an amine to be used as the curing agent include ethylenediamine, diethylenetriamine, triethylenetetramine, tetraethylenepentamine, dimethylaminopropylamine, diethylaminopropylamine, hexamethylenetriamine, biscyanoethylamine, tetramethylguanidine, pyridine, piperidine, methanediamine, isophoronediamine, 1,3-bis-aminomethyl-cyclohexane, bis(4-amino-cyclohexyl)methane, bis(4-amino-3-methyl-cyclohexyl)methane, benzylmethylamine, α-methyl-benzylmethylamine, m-phenylenediamine, m-xylylenediamine, diaminodiphenylmethane, diaminodiphenyl sulfone and diaminodiphenyl ether.

When acid anhydride or amine is used as the curing agent, a preferred use ratio is 0.7 to 1.2 equivalent of acid anhydride or amine, and further preferably 0.9 to 1.1 equivalents thereof relative to 1 equivalent of the epoxy contained in the compound in the composition. When a blending amount of the curing agent is within the range described above, a curing reaction rapidly progresses and no coloring is caused in the cured film obtained, and such a case is preferred.

### Curing Accelerator (J)

In the case where compound (B) has an epoxy group, and in the case where an epoxy resin is blended as other resins, a curing accelerator may also be contained therein. An epoxy resin curing accelerator can be used for promoting a reaction between the epoxy resin and the epoxy curing agent and for improving heat resistance, chemical resistance and hardness of the cured film. The curing accelerator is used by being ordinarily added in an amount of 0.01 to 5% by mass based on 100% by mass of the solid content in the resin composition (the remaining component upon removing the solvent from the resin composition). The curing accelerators may be used alone, or in combination with two or more kinds thereof.

Any of the curing accelerator can be used as long as the curing accelerator has a function of promoting the reaction between the epoxy resin and the epoxy curing agent, and examples thereof include an imidazole-based curing accelerator, a phosphine-based curing accelerator and an ammonium-based curing accelerator. Specific examples thereof include trimethylolpropane triacrylate, ethylene oxide-modified trimethylolpropane tri(meth)acrylate, trimethylolpropane PO-modified triacrylate, trimethylolpropane EO-modified triacrylate, glycerol tri(meth)acrylate, ethoxylated glycerin tri(meth)acrylate, epichlorohydrin-modified glycerol tri(meth)acrylate, diglycerin EO-modified acrylate, alkyl-modified dipentaerythritol penta(meth)acrylate, alkyl-modified dipentaerythritol tetra(meth)acrylate, alkyl-modified dipentaerythritol tri(meth)acrylate, ethoxylated isocyanuric ring tri(meth)acrylate, ε-caprolactone-modified tris-(2-acryloxyethyl)isocyanurate, propylene oxide-modified trimethylolpropane tri(meth)acrylate, epichlorohydrin-modified trimethylolpropane tri(meth)acrylate, ditrimethylolpropane tetra(meth)acrylate, isocyanuric acid EO-modified di/triacrylate, pentaerythritol tri/tetraacrylate (ARONIX M305, M450; Toagosei Co., Ltd.), dipentaerythritol penta/hexaacrylate (ARONIX M402; Toagosei Co., Ltd.), diglycerin EO-modified acrylate, ethoxylated isocyanuric acid triacrylate, tris[(meth)acryloxyethyl]isocyanurate, ethoxylated glycerin triacrylate, ethoxylated pentaerythritol tetraacrylate, 2-undecylimidazole, 2-heptadecylimidazole, 2-phenylimidazole, 2-phenyl-4-methylimidazole and 2,3-dihydro-1H-pyrrolo[1,2-a]benzimidazole.

### Surfactant (K)

The surfactant can also be used for improving wettability, leveling or applicability for the base material, and is ordinarily used by being added in an amount of 0.01 to 1% by mass, and preferably 0.1 to 0.3% by mass, based on 100% by mass of the solid content of the resin composition. The surfactant may be used in one kind of the compound or in combination with two or more kinds of the compounds.

Specific examples of the surfactant include Polyflow No. 45, Polyflow KL-245, Polyflow No. 75, Polyflow No. 90 and Polyflow No. 95 (Kyoeisha Chemical Co., Ltd.), Disperbyk-161, Disperbyk-162, Disperbyk-163, Disperbyk-164, Disperbyk-166, Disperbyk-170, Disperbyk-180, Disperbyk-181, Disperbyk-182, BYK-300, BYK-306, BYK-310, BYK-320, BYK-330, BYK-342, BYK-346, BYK-UV3500 and BYK-UV3570 (BYK-Chemie Japan K. K.), KP-341, KP-358, KP-368, KF-96-50CS and KF-50-100CS (Shin-Etsu Chemical Co., Ltd.), Surflon SC-101 and Surflon KH-40 (AGC Seimi Chemical Co., Ltd.), Ftergent 222F, Ftergent 251 and FTX-218 (Neos Company Limited), EFTOP EF-351, EFTOP EF-352, EFTOP EF-601, EFTOP EF-801 and EFTOP EF-802 (Mitsubishi Materials Corp.), MEGAFACE (registered trademark) F-410, MEGAFACE (registered trademark) F-430, MEGAFACE (registered trademark) F-444, MEGAFACE (registered trademark) F-472SF, MEGAFACE (registered trademark) F-475, MEGAFACE (registered trademark) F-477, MEGAFACE (registered trademark) F-552, MEGAFACE (registered trademark) F-553, MEGAFACE F-554, MEGAFACE F-555, MEGAFACE (registered trademark) F-556, MEGAFACE (registered trademark) F-558, MEGAFACE (registered trademark) F-563, MEGAFACE (registered trademark) R-94, MEGAFACE (registered trademark) RS-75 and MEGAFACE (registered trademark) RS-72-K (DIC Corporation), TEGORad 2200N and TEGO Rad 2250N (Evonik Japan Co., Ltd.) and Silaplane (registered trademark) FM-0511 (JNC Corporation).

### Antioxidant (L)

The resin composition according to one embodiment of the invention may contain the antioxidant. Improvement of heat resistance and weather resistance can be expected by containing the antioxidant. Moreover, oxidative degradation during heating can be prevented and coloring can be suppressed by containing the antioxidant. As a blending proportion of the antioxidant in the epoxy resin composition, the antioxidant is preferably used by being added in an amount of 0.1% by mass to 2.0% by mass based on the total amount of the solid content in the resin composition.

Examples of the antioxidant include a phenol-based antioxidant and a phosphorus-based antioxidant, and specific examples thereof include monophenols, bisphenols, polymer-type phenols, phosphites and oxaphosphaphenanthrene oxides.

Specific examples of the monophenols include 2,6-di-t-butyl-p-cresol, butylated hydroxyanisole, 2,6-di-t-butyl-p-ethylphenol and stearyl-β-(3,5-di-t-butyl-4-hydroxyphenyl)propionate.

Specific example of the bisphenols include 2,2′-methylenebis(4-methyl-6-t-butylphenol), 2,2′-methylenebis(4-ethyl-6-t-butylphenol), 4,4′-thiobis(3-methyl-6-t-butylphenol), 4,4′-butylidenebis(3-methyl-6-t-butylphenol) and 3,9-bis[1,1-dimethyl-2-{β-(3-t-butyl-4-hydroxy-5-methylphenyl)prop ionyloxy}ethyl]2,4,8,10-tetraoxaspiro[5,5]undecane.

Specific examples of the polymer-type phenols include 1,1,3-tris(2-methyl-4-hydroxy-5-t-butylphenyl)butane, 1,3,5-trimethyl-2,4,6-tris(3,5-di-t-butyl-4-hydroxybenzyl)benzene, tetrakis-[methylene-3-(3′,5′-di-t-butyl-4′-hydroxyphenyl)propionat e]methane, bis[3,3′-bis-(4′-hydroxy-3′-t-butylphenyl)butyric acid]glycol ester, 1,3,5-tris(3′,5′-di-t-butyl-4′-hydroxybenzyl)-S-triazine-2,4,6-(1H,3H,5H)trione and tocophenol.

Specific examples of the phosphites include triphenyl phosphite, diphenyl isodecyl phosphite, phenyl di-isodecyl phosphite, tris(nonylphenyl) phosphite, diisodecylpentaerythritol phosphite, tris(2,4-di-t-butylphenyl)phosphite, cyclic neopentane tetraylbis(octadecyl)phosphite, cyclic neopentane tetraylbi(2,4-di-t-butylphenyl)phosphite, cyclic neopentane tetraylbi(2,4-di-t-butyl-4-methylphenyl)phosphite and bis[2-t-butyl-6-methyl-4-{2-(octadecyloxycarbonyl)ethyl}phenyl]hyd rogen phosphite.

Specific examples of the oxaphosphaphenanthrene oxides include 9,10-dihydro-9-oxa-10-phosphaphenanthrene-10-oxide, 10-(3,5-di-t-butyl-4-hydroxybenzyl)-9,10-dihydro-9-oxa-10-phosphap henanthrene-10-oxide and 10-decyloxy-9,10-dihydro-9-oxa-10-phosphaphenanthrene-10-oxide.

Specific examples of a commercially available antioxidant include Irgafos 168, Irgafos XP40, Irgafos XP60, Irganox 1010, Irganox 1035, Irganox 1076, Irganox 1135, Irganox 1520L (BASF Japan Ltd.) and ADK STAB (registered trademark) AO-20, AO-30, AO-40, AO-50, AO-60, AO-75, AO-80 and AO-330 (ADEKA Corporation). The antioxidants may be used alone, or in combination with two or more kinds thereof.

### Photosensitizer (M)

A photosensitizer can also be used as an additive.

Specific examples of the photosensitizer include an aromatic nitro compound, coumarins (7-diethylamino-4-methylcoumarin, 7-hydroxy-4-methylcoumarin, ketocoumarin, carbonylbiscoumarin), aromatic 2-hydroxyketone and amino-substituted aromatic 2-hydroxyketones (2-hydroxybenzophenone, mono- or di-p-(dimethylamino)-2-hydroxybenzophenone), acetophenone, anthraquinone, xanthone, thioxanthone, 2-chlorothioxanthone, 2-methylthioxanthone, 2,4-diethylthioxanthone, 2-isopropylthioxanthone, and benzanthrone, thiazolines (2-benzoylmethylene-3-methyl-β-naphthothiazoline, 2-(β-naphthoylmethylene)-3-methylbenzothiazoline, 2-(α-naphthoylmethylene)-3-methylbenzothiazoline, 2-(4-biphenoylmethylene)-3-methylbenzothiazoline, 2-(β-naphthoylmethylene)-3-methyl-β-naphthothiazoline, 2-(4-biphenoylmethylene)-3-methyl-β-naphthothiazoline and 2-(p-fluorobenzoylmethylene)-3-methyl-β-naphthothiazoline), oxazoline (2-benzoylmethylene-3-methyl-β-naphthoxazoline, 2-(β-naphthoylmethylene)-3-methylbenzoxazoline, 2-(α-naphthoylmethylene)-3-methylbenzoxazoline, 2-(4-biphenoylmethylene)-3-methylbenzoxazoline, 2-(β-naphthoylmethylene)-3-methyl-β-naphthoxazoline, 2-(4-biphenoylmethylene)-3-methyl-β-naphthoxazoline, 2-(p-fluorobenzoylmethylene)-3-methyl-β-naphthoxazoline), benzothiazole, nitroaniline (m- or p-nitroaniline, 2,4,6-trinitroaniline) or nitroacenaphthene (5-nitroacenaphthene), (2-[(m-hydroxy-p-methoxy)styryl]benzothiazole, benzoinalkyl ether, N-alkylated phthalone, acetophenoneketal(2,2-dimethoxyphenylethanone), naphthalene, 2-naphthalenemethanol, 2-naphthalenecarboxylic acid, anthracene, 9-anthracenemethanol, 9-anthracenecarboxylic acid, 9,10-diphenylanthracene, 9,10-bis(phenylethynyl)anthracene, 2-methoxyanthracene, 1,5-dimethoxyanthracene, 1,8-dimethoxyanthracene, 9,10-diethoxyanthracene, 6-chloroanthracene, 1,5-dichloroanthracene, 5,12-bis(phenylethynyl)naphthacene, chrysene, pyrene, benzopyran, azoindolizine, furocoumarin, phenothiazine, benzo[c]phenothiazine, 7-H-benzo[c]phenothiazine, triphenylene, 1,3-dicyanobenzene and phenyl-3-cyanobenzoate.

Preferred examples include 9,10-diphenylanthracene, 9,10-diethoxyanthracene and 9,10-dibutoxyanthracene.

Examples of a commercial item thereof include a photosensitizer {9,10-diphenylanthracene (trade name)} made by Kanto Chemical Co., Inc., a photocationic sensitizer {ANTHRACURE (registered trademark) UVS-1101} and {ANTHRACURE (registered trademark) UVS-1331} made by Kawasaki Kasei Chemicals Ltd., and a photoradical sensitizer {ANTHRACURE (registered trademark) UVS-581} made by Kawasaki Kasei Chemicals Ltd.

### Coupling Agent (N)

A coupling agent can also be used for improving adhesion between the cured film formed of the resin composition and the base material, and can be ordinarily used by being added in an amount of 0.01 to 10% by mass based on the total solid content in the resin composition.

As the coupling agent, a silane-based compound, an aluminum-based compound and a titanate-based compound can be used. Specific examples thereof include a silane-based compound such as vinyltrichlorosilane, vinyltrimethoxysilane, vinyltriethoxysilane, 2-(3,4-epoxycyclohexyl)ethyltrimethoxysilane, 3-glycidoxypropyldimethylethoxysilane, 3-glycidoxypropylmethyldiethoxysilane, 3-glycidoxypropyltriethoxysilane, 3-glycidoxypropyltrimethoxysilane, 3-aminopropyltrimethoxysilane, 3-aminopropyltriethoxysilane, 3-methacryloxypropyltrimethoxysilane and 3-methacryloxypropyltriethoxysilane; an aluminum-based compound such as acetoalkoxyaluminum diisopropylate; and a titanate-based compound such as tetraisopropylbis(dioctylphosphite)titanate. Above all, 3-glycidoxypropyltrimethoxysilane is preferred because an effect of improving adhesion is large. Examples of a commercially available coupling agent include Sila-Ace S510 (JNC Corporation) and Sila-Ace S530 (JNC Corporation).

### Method of Adjusting Varnish

The resin composition according to one embodiment of the invention may or need not contain the solvent. A varnish can be obtained by dissolving acrylic resin (A) and at least one kind of silsesquioxane derivative (B) represented by formula (1), (2) or (3) in solvent (E). When a concentration of component (B) is high, the varnish is preferably prepared by using the solvent from a viewpoint of the applicability.

Specifically, for example, the varnish can be prepared by mixing a component other than the curing agent, components (A), (B) and (D) to (F), and heating the resulting mixture at 70° C. or lower and stirring and dissolving the resulting mixture, and then adding photoradical polymerization initiator (C) thereto, and dissolving the initiator therein.

The varnish can be applied thereonto by applying a general-purpose application method such as spin coating or various printing methods, and the cured film can be produced inexpensively and simply by using the varnish as a coating agent. A coating method and a curing method for the varnish will be described in the following section: 3. Cured film.

### 3. Cured Film

A third embodiment according to the invention relates to a cured film formed of curing a resin composition containing acrylic resin (A) and at least one kind selected from silsesquioxane derivatives (B) represented by formula (1), (2) or (3) (hereinafter, referred to as “compound represented by formulas (1) to (3)” in several cases). Acrylic resin (A) and compound (B) represented by formulas (1) to (3) both contained in the resin composition are similar to the acrylic resin described in the second embodiment and the compound represented by formulas (1) to (3) described in the first embodiment. Moreover, the description on the resin composition of the second embodiment of the invention described above can be applied to each component or the like of the resin composition.

A method of curing a resin composition containing acrylic resin (A) and at least one kind selected from compounds (B) represented by formulas (1) to (3) will be described below.

### Application

First, a resin composition is applied on a base material or the like. For example, when a cured film obtained is used as a coating, the resin composition may be directly applied on an object to be coated.

A method of applying the resin composition on the base material is not particularly limited, and examples thereof include a method in which a varnish of an epoxy resin composition is added dropwise onto a base material and then the resulting material is applied thereonto by using a wire bar, and a method in which a varnish is applied thereonto by using a gravure coater, a lip coater, a slit die or an inkjet method. In view of capability of evenly applying a predetermined amount of the varnish, a method in which a varnish is added dropwise onto a base material and then the resulting material is applied thereonto by using a wire bar, and a method of applying a varnish thereonto by using a gravure coater or a slit die are further preferred.

An amount of application of the resin composition may be appropriately set according to an intended purpose.

From viewpoints of handling and cost, application of the varnish is preferably performed at an ordinary temperature. Therefore, rotational viscosity of the varnish is preferably 1 to 3,000 mPa·sec, and further preferably 1 to 500 mPa·sec, at 25° C.

### Curing Step

The resin composition containing epoxy resin (A) and at least one kind selected from compounds (B) represented by formulas (1) to (3) can be cured by at least one of heating and irradiation with active light, and is preferably cured by ultraviolet light.

When the composition is cured by the active light, a conventionally known method can be used, and as the active light, ultraviolet light can be used. Examples of a light source for irradiating the composition with ultraviolet light include a metal halide type, a high pressure mercury lamp and a UV-LED lamp.

A commercially available apparatus can be used in the curing step.

Examples thereof include an ultraviolet exposure apparatus {LH10-10Q (trade name), H bulb (trade name) made by Heraeus K.K.} and an LED ultraviolet exposure apparatus {ASM1503NM-UV-LED (trade name) made by ASUMI GIKEN, Limited}. Then apparatus may be designed so that the coating step and the curing step can be continuously performed.

When the composition is cured by the active light, conditions in the curing step only need to be appropriately set according to a thickness of the resin composition or the like.

Specifically, for example, the resin composition layer formed by application at a thickness of 4 to 5 micrometers on the base material is irradiated with ultraviolet light having a wavelength of 254 nanometers or 365 nanometers with an integrated exposure of 0.5 to 1.5 J/cm² by using the ultraviolet exposure apparatus {LH10-10Q (trade name), H bulb (trade name)} made by Heraeus K.K.

In addition, irradiation is ordinarily performed from a side of applied surface, but irradiation with ultraviolet light can also be performed from a rear surface side of the applied surface by using a base material through which ultraviolet light can be permeated.

In the case of thermal curing, a heating method is not particularly limited, and for example, a heating means adopting a conventionally known method according to which the composition can be heated at a predetermined temperature, such as a heat circulation system, a hot air heating system, and an induction heating system can be used. As a further preferred method to be used, a curing furnace by hot air circulation or a curing furnace by infrared light can be adopted. Alternatively, heating may be simultaneously performed by simultaneously using a hot air circulation curing furnace and an infrared light curing furnace, or by assembling an infrared heater in the hot air circulation curing furnace. Moreover, a photocuring furnace and a thermal curing furnace may be simultaneously used, or heating and irradiation with the active light may be simultaneously performed.

Curing conditions under which the composition is thermally cured may be appropriately set according to the thickness of the resin composition or the like.

### 4. Laminate

A fourth embodiment of the invention relates to a laminate including a base material, and a cured film formed by curing a resin composition containing at least acrylic resin (A) and at least one kind selected from silsesquioxane derivatives (B) represented by formula (1), (2) or (3) on the base material.

Acrylic resin (A) and silsesquioxane derivative (B) represented by formulas (1) to (3) both contained in the resin composition are similar to the acrylic resin described in the second embodiment and the silsesquioxane derivative represented by (1) to (3) described in the first embodiment. Here, the description on the resin composition of the second embodiment of the invention described above can be applied to each component or the like of the resin composition. Further, from viewpoints of suppression of cure shrinkage and resistance to moist heat, a mass ratio of a content of component (A) to a content of component (B) in the resin composition is preferably 10:90 to 95:5, further preferably 40:60 to 80:20, and still further preferably 50:50 to 70:30.

### Base Material

The base material is not particularly limited, and only needs to be selected according to an application of the laminate. For example, such a material can be used as a quartz substrate, a glass substrate including barium borosilicate glass and aluminoborosilicate glass, a calcium fluoride substrate, metal oxide including indium tin oxide (ITO), a ceramic substrate, a plastic film including a polycarbonate (PC) film, a silicone-based film, a polyethylene terephthalate (PET) film, a polyethylene naphthalate (PEN) film, a cycloolefin polymer (COP) film, a polypropylene film, a polyethylene film, an acryl polymer film, a polyvinyl alcohol film, a triacetylcellulose film, a polyimide (PI) film and a liquid crystal polymer film, a carbon fiber film, a semiconductor substrate including a silicon wafer, and a metal substrate including a SUS substrate and a copper substrate.

From a viewpoint of adhesion, a material in which an easy-adhesive bonding layer is provided on the base material as exemplified above is preferably used.

A method of producing the laminate according to the fourth embodiment of the invention has a coating step of coating a resin composition on a base material, and a curing step of curing a resin composition layer formed on the base material. The description in the section of “Coating” and “Curing step” described in the third embodiment can be applied to methods of coating and curing the resin composition.

### 5. Characteristics of Cured Film

The cured film of the resin composition according to one embodiment of the invention or the laminate according to one embodiment of the invention is suppressed in cure shrinkage during being cured, and suppression on the reduction of low warpage and hardness (scratch resistance) is realized. Further, the cured film can have high resistance to moist heat. Moreover, the cured film can have high transparency by selecting resins.

The cured film of the resin composition according to one embodiment of the invention preferably has low warpage of 0 millimeter or more and 4 millimeters or less in a height of warpage of the base material with the cured film in evaluation method 1 on the resin composition containing at least acrylic resin (A) and at least one kind selected from silsesquioxane derivatives (B) represented by formulas (1) to (3).

Moreover, the cured film preferably has high resistance to moist heat of 4B or more for all in the adhesion after 120 hours in adhesion evaluation by evaluation method 2 on the above resin composition.

Further, the cured film preferably has no large scratches in scratch resistance evaluation by evaluation method 3 on the above resin composition.

Moreover, the laminate according to any other embodiment of the invention includes a base material, and a cured film formed by curing a resin composition containing at least acrylic resin (A) and at least one kind selected from silsesquioxane derivatives (B) represented by formulas (1) to (3) on the base material, and preferably has low warpage of 0 millimeter or more and 4 millimeters or less in a height of warpage of the base material with the cured film in evaluation method 1, low warpage of 4B or more for all in the adhesion after 120 hours in adhesion evaluation by evaluation method 2, and high resistance to moist heat of 4B or more for all in the adhesion after 120 hours in adhesion evaluation by evaluation method 2 on the resin composition. Further, the laminate preferably has no large scratches in the scratch resistance evaluation by evaluation method 3 on the above resin composition.

### Evaluation Method 1

A cured film having a thickness of 2.5 to 6 micrometers and composed of the resin composition containing at least acrylic resin (A) and at least one kind selected from silsesquioxane derivatives (B) represented by formula (1), (2) or (3) is formed on a 50 micrometer-thick polyethylene terephthalate (PET) film base material on which an easy-adhesive bonding layer may be formed.

The resulting PET with the cured film is cut into a lattice of 15 cm×15 cm, and the resulting square is allowed to stand with the cured film upward under an atmosphere of 25° C. and 50% RH for 24 hours or more, and then each height of the cured film lifted on four corners on a horizontal table is measured, and a mean value of a total of the heights is taken as a measured value (unit: mm).

A case of curling downward (U shape) is taken as a positive value, and a case of curling upward (inverted U shape) is taken as a negative value.

### Evaluation Method 2

A cured film having a thickness of 2.5 to 6 micrometers and composed of the resin composition containing at least acrylic resin (A) and at least one kind selected from silsesquioxane derivatives (B) represented by formula (1), (2) or (3) is formed on a 50 micrometer-thick polyethylene terephthalate (PET) film base material on which an easy-adhesive bonding layer may be formed.

On the PET with the cured film, and in accordance with ASTM D3359 (Method B),

an adhesion test is performed by using a crosscut adhesion method with 25 lattice patterns at a spacing of 1 millimeter. Then, the PET with the cured film after completion of the adhesion test is put into a constant temperature and humidity chamber at 85° C. and 85% RH for 120 hours, and the resulting material is took out therefrom, and in accordance with ASTM D3359 (Method B),
an adhesion test is performed on the resulting material by using a crosscut adhesion method with 25 lattice patterns at a spacing of 1 millimeter. Evaluation criteria are as described below:

5B: 0% in percent area removed;

4B: less than 5% in percent area removed;

3B: 5% or more and less than 15% in percent area removed;

2B: 15% or more and less than 35% in percent area removed;

1B: 35% or more and less than 65% in percent area removed; and

0B: 65% or more in percent area removed;

### Evaluation Method 3

A cured film having a thickness of 2.5 to 6 micrometers and composed of the resin composition containing at least acrylic resin (A) and at least one kind selected from silsesquioxane derivatives (B) represented by formula (1), (2) or (3) is formed on a 50 micrometer-thick polyethylene terephthalate (PET) film base material on which an easy-adhesive bonding layer may be formed.

A glass surface with the cured film is scratched with steel wool (#0000) applied with a load of 500 g/cm² by 10 reciprocating motions, and the cured films before and after testing are visually evaluated by the following criteria:

### Evaluation Criteria:

No scratches were observed: Excellent

Several fine scratches were observed: Good

Large scratches were observed: Poor

### 6. Application

The cured film of the resin composition according to one embodiment of the invention or the laminate according to one embodiment of the invention is preferably used for various electronic components owing to excellent low warpage. The above materials satisfies both low warpage, and hardness (scratch resistance), and therefore are also preferably used as a hard coat layer on an outermost surface of various electronic components, in particular. Moreover, the above materials are also preferably used as an insulating material used on a wiring portion of a printed wiring board having an electronic circuit.

### EXAMPLES

Hereinafter, the invention will be further specifically described by Examples, but the invention is not limited to the Examples unless the invention is beyond the spirit.

### Synthesis Example

Devices used in Synthesis Examples are as described below.

### Use Device

Gel permeation chromatography (GPC): made by Japan Analytical Industry Co., Ltd.
Column: Shodex KF804L, Shodex KF805L, made by Showa Denko K. K., both are connected in series.

Mobile phase: THF

Rate of flow: 1.0 mL/min

Temperature: 40° C.

Detector: Refractive Index Detector (RI)

Molecular weight standard sample: Polymethyl methacrylate resin having known molecular weight (made by Showa Denko K. K.) Nuclear magnetic resonance (NMR): made by VARIAN

Device name: VARIAN NMR SYSTEM (500 MHz)

Matrix Assisted Laser Desorption/Ionization (MALDI-TOF MS): made by BRUKER DALTONICS

Device name: Bruker Daltonics Autoflex III

Matrix: 2,5-dihydroxybenzoic acid (2,5-DHB)

Ionizing agent: sodium trifluoroacetate (NaTFA) Formulation (mole ratio): 2,5-DHB/NaTFA/Sample=100/10/1

Measurement: Linear Positive mode (measurement range: m/z=1,000 to 3,000)

### Synthesis Example I: Synthesis of Compound (3)

A compound (hereinafter, referred to as compound (β)) represented by formula (β) was produced by the following method.

Under nitrogen sealing, 300 g of a compound represented by formula (α) (hereinafter, referred to as compound (α)) prepared by the method disclosed in WO 2004/024741 A and 420 g of dehydrated toluene (made by Kanto Chemical Co., Inc.) were charged into a reaction vessel, and the resulting mixture was heated to 90° C. and stirred. Thereto, 0.3 mL of PT-VTSC-3.0X (made by Umicore Japan) was added, and 69.6 of aryl alcohol (made by Tokyo Chemical Industry Co., Ltd.) was added dropwise. Then, the resulting reaction solution was refluxed for 5 hours, and after a peak at 2,140 cm⁻¹ was confirmed to be lost by a Fourier transform infrared spectrophotometer (FT-IR), heating was stopped and the resulting solution was cooled to room temperature. Then, 15 g of activated carbon (made by FUJIFILM Wako Pure Chemical Corporation) was added thereto, and the resulting mixture was stirred overnight, and the activated carbon was filtered off by using Celite and removed. A filtrate was concentrated with an evaporator until a solid content concentration reached about 80%, and 750 g of heptane (made by FUJIFILM Wako Pure Chemical Corporation) was added thereto while stirring the solution to obtain a white precipitate. The precipitate obtained was subjected to filtration, further washed with heptane, and dried under reduced pressure to obtain 310 g of compound (β) (white solid). GPC purity: 97%

¹H-NMR: (400 MHz, (CD₃)₂CO) δ=7.27-7.57 (40H, Ph), 3.20-3.24 (12H, —OCH₂, OH), 1.36 (8H, —CH₂), 0.58 (8H, —SiCH₂), 0.08 (24H, —Si(CH₃)₂) MALDI-TOFMS: m/z C₆₈H₉₂NaO₁₈Si₁₂ [M+Na]⁺, 1555.38.

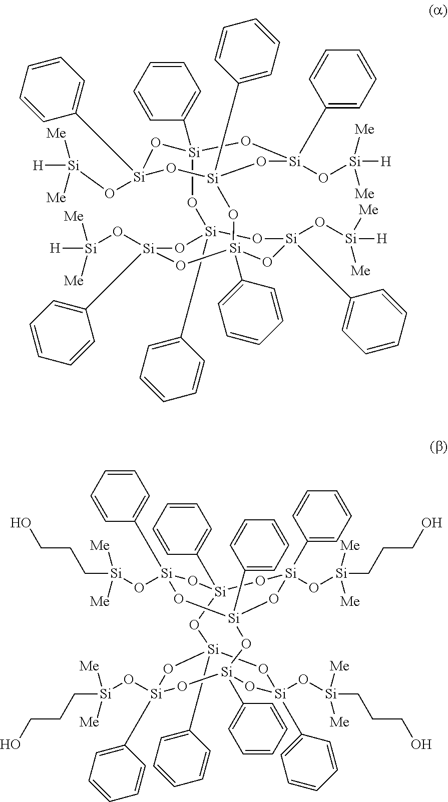 [SMILES: C[SiH](C)O[Si]1(c2ccccc2)O[Si]2(c3ccccc3)O[Si](O[SiH](C)C)(c3ccccc3)O[Si](c3ccccc3)(O1)O[Si]1(c3ccccc3)O[Si](O[SiH](C)C)(c3ccccc3)O[Si](c3ccccc3)(O[Si](O[SiH](C)C)(c3ccccc3)O1)O2 ; C[Si](C)(CCCO)O[Si]1(c2ccccc2)O[Si]2(c3ccccc3)O[Si](O[Si](C)(C)CCCO)(c3ccccc3)O[Si](c3ccccc3)(O1)O[Si]1(c3ccccc3)O[Si](O[Si](C)(C)CCCO)(c3ccccc3)O[Si](c3ccccc3)(O[Si](O[Si](C)(C)CCCO)(c3ccccc3)O1)O2]

### Synthesis Example II: DD-4C₃UAc (1)-(a-1)

A compound (DD-4C₃UAc) represented by the following formula was produced by the following method.

Under nitrogen sealing, 150 g of compound (β), 300 g of dehydrated toluene (made by Kanto Chemical Co., Inc.), 4.4 g of 2,6-di-tert-butyl-p-cresol (made by Tokyo Chemical Industry Co., Ltd.) and 0.47 mL of dibutyltin dilaurate (made by Tokyo Chemical Industry Co., Ltd.) were charged into a reaction vessel, and the resulting mixture was heated to 80° C. and stirred while bubbling air. Thereto, 56.3 g of 2-acryloyloxyethyl isocyanate (AOI) (made by Showa Denko K. K.) was added dropwise. Then, the resulting reaction solution was stirred for 2 hours, and after a peak at 2,250 cm-1 was confirmed to be lost or to be reduced to cause no change by an FT-IR, heating was stopped and the resulting solution was cooled to room temperature. Then, the resulting reaction solution was concentrated with an evaporator, and 750 g of heptane (made by FUJIFILM Wako Pure Chemical Corporation) was added thereto while stirring the solution. A supernatant was removed by decantation, and the obtained viscous liquid was further washed by heptane several times, and supernatant was removed. To the obtained viscous liquid, 0.1 g of 2,6-di-tert-butyl-p-cresol was added, and the resulting mixture was dried under reduced pressure to obtain 204 g of (DD-4C₃UAc) (transparent viscous liquid) GPC purity: 97%

¹H-NMR: (400 MHz, (CD₃)₂CO) δ=7.56-7.20 (40H, Ph), 6.35 (4H, COCH═CH₂, cis), 6.19 (4H, NH), 6.12 (4H, COCH═CH₂, gem) 5.86 (4H, COCH═CH₂, trans), 4.18 (8H, CH₂OCOCH═CH₂), 3.65 (8H, CH₂OCONH), 3.39 (8H, OCONHCH₂), 1.41 (8H, SiCH₂CH₂), 0.54 (8H, SiCH₂), 0.09 (24H, —Si(CH₃)₂) MALDI-TOFMS: m/z C₉₂H₁₂₀N₄NaO₃₀Si₁₂[M+Na]⁺, 2119.631.

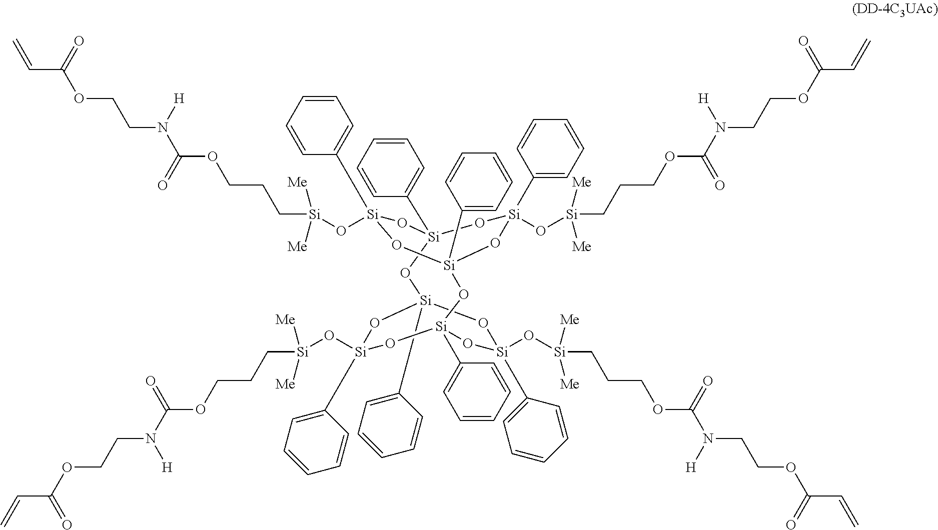 [SMILES: C=CC(=O)OCCNC(=O)OCCC[Si](C)(C)O[Si]1(c2ccccc2)O[Si]2(c3ccccc3)O[Si](O[Si](C)(C)CCCOC(=O)NCCOC(=O)C=C)(c3ccccc3)O[Si](c3ccccc3)(O1)O[Si]1(c3ccccc3)O[Si](O[Si](C)(C)CCCOC(=O)NCCOC(=O)C=C)(c3ccccc3)O[Si](c3ccccc3)(O[Si](O[Si](C)(C)CCCOC(=O)NCCOC(=O)C=C)(c3ccccc3)O1)O2]

### Synthesis Example III: Synthesis of (DD-4C₃UAc₂) (1)-(a-3)

A silsesquioxane derivative (DD-4C₃UAc₂) represented by the following formula was produced by the following method.

Under nitrogen sealing, 100 g of compound (β), 140 g of dehydrated toluene (made by Kanto Chemical Co., Inc.), 3.0 g of 2,6-di-tert-butyl-p-cresol (made by Tokyo Chemical Industry Co., Ltd.) and 0.32 mL of dibutyltin dilaurate (made by Tokyo Chemical Industry Co., Ltd.) were charged into a reaction vessel, and the resulting mixture was heated to 90° C. and stirred while bubbling air. Thereto, 64.2 g of 1,1-(bis-acryloyloxymethyl)ethylisocyanate (BEI) (made by Showa Denko K. K.) was added dropwise. Then, the resulting reaction solution was stirred for 3 hours, and after a peak at 2,250 cm⁻¹ was confirmed to be lost or to be reduced to cause no change by an FT-IR, heating was stopped and the resulting solution was cooled to room temperature. Then, the resulting reaction solution was concentrated with an evaporator, and 450 g of heptane (made by FUJIFILM Wako Pure Chemical Corporation) was added thereto while stirring the solution. A supernatant was removed by decantation, the obtained viscous liquid was further washed with heptane several times, and the resulting supernatant was removed. To the obtained viscous liquid, 0.1 g of 2,6-di-tert-butyl-p-cresol was added, and the resulting mixture was dried under reduced pressure to obtain 153 g of (DD-4C₃UAc₂) (transparent viscous liquid).

GPC purity: 98%

¹H-NMR: (400 MHz, (CD₃)₂CO) δ=7.55-7.20 (40H, Ph), 6.36 (8H, COCH═CH₂, cis), 6.15 (8H, COCH═CH₂, gem), 6.09 (4H, NH), 5.88 (8H, COCH═CH₂, trans), 4.36 (16H, CH₂═CHCOOCH₂), 3.58 (8H, CH₂OCONH), 1.39 (12H, CCH3), 1.38 (8H, SiCH₂CH₂), 0.51 (8H, SiCH₂), 0.08 (24H, —Si(CH3)₂).

MALDI-TOFMS: m/z C₁₁₂H₁₁₄N₄NaO₃₈Si₁₂ [M+Na]⁺, 2511.805.

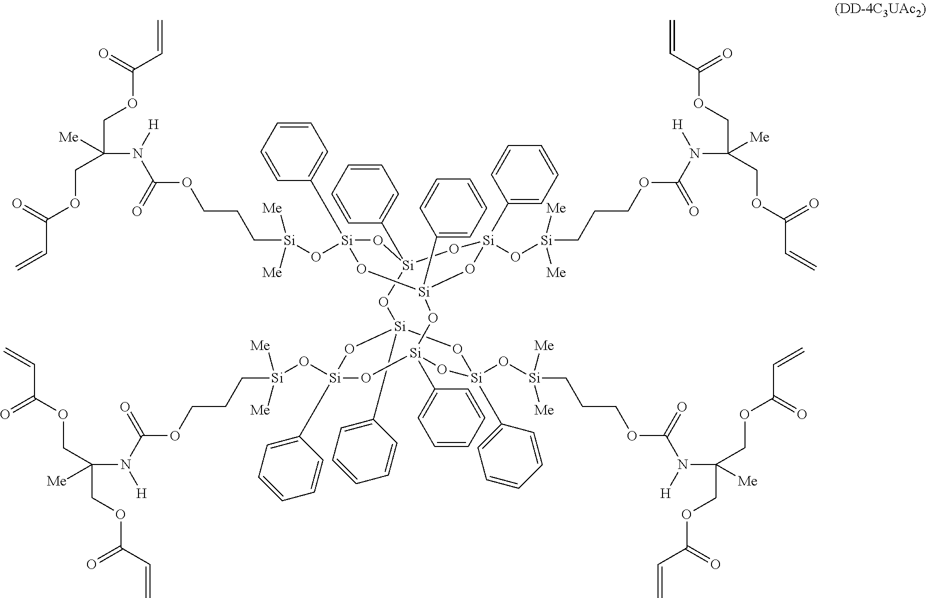 [SMILES: C=CC(=O)OCC(C)(COC(=O)C=C)NC(=O)OCCC[Si](C)(C)O[Si]1(c2ccccc2)O[Si]2(c3ccccc3)O[Si](O[Si](C)(C)CCCOC(=O)NC(C)(COC(=O)C=C)COC(=O)C=C)(c3ccccc3)O[Si](c3ccccc3)(O1)O[Si]1(c3ccccc3)O[Si](O[Si](C)(C)CCCOC(=O)NC(C)(COC(=O)C=C)COC(=O)C=C)(c3ccccc3)O[Si](c3ccccc3)(O[Si](O[Si](C)(C)CCCOC(=O)NC(C)(COC(=O)C=C)COC(=O)C=C)(c3ccccc3)O1)O2]

### Synthesis Example IV: Synthesis of (DD-4C₃OC₂UAc) (1)-(b-1)

A silsesquioxane derivative (DD-4C₃OC₂UAc) represented by the following formula was produced by the following method.

Under nitrogen sealing, 100 g of a compound represented by formula (γ) (hereinafter, referred to as compound (γ)) prepared by the method disclosed in WO 2004/024741 A, 140 g of dehydrated toluene (made by Kanto Chemical Co., Inc.), 2.6 g of 2,6-di-tert-butyl-p-cresol (made by Tokyo Chemical Industry Co., Ltd.) and 0.28 mL of dibutyltin dilaurate (made by Tokyo Chemical Industry Co., Ltd.) were charged into a reaction vessel, and the resulting mixture was heated to 80° C. and stirred while bubbling air. Thereto, 33.7 g of AOI (made by Showa Denko K. K.) was added dropwise. Then, the resulting reaction solution was stirred for 2 hours, and after a peak at 2,250 cm⁻¹ was confirmed to be lost or to be reduced to cause no change by an FT-IR, heating was stopped and the resulting solution was cooled to room temperature. Then, the resulting reaction solution was concentrated with an evaporator, and 450 g of heptane (made by FUJIFILM Wako Pure Chemical Corporation) was added thereto while stirring the solution. A supernatant was removed by decantation, the obtained viscous liquid was further washed with heptane several times, and the resulting supernatant was removed. To the obtained viscous liquid, 0.1 g of 2,6-di-tert-butyl-p-cresol was added, and the resulting mixture was dried under reduced pressure to obtain 132 g of (DD-4C3OC₂UAc) (transparent viscous liquid).

GPC purity: 98%

¹H-NMR: (400 MHz, (CD₃)₂CO) δ=7.55-7.20 (40H, Ph), 6.41 (4H, NH), 6.36 (4H, COCH═CH₂, cis), 6.13 (4H, COCH═CH₂, gem), 5.86 (4H, COCH═CH₂, trans), 4.20 (8H, CH₂═CHCOOCH₂), 4.02 (8H, CH₂OCONH), 3.42 (8H, SiC3H₆OCH₂), 3.37 (8H, SiC₂H₄CH₂) 3.02 (8H, OCONHCH₂), 1.37 (8H, SiCH₂CH₂), 0.55 (8H, SiCH₂), 0.09 (24H, —Si(CH₃)2).

MALDI-TOFMS: m/z C₁₀₀H₁₃₆N₄NaO₃₄Si₁₂ [M+Na]⁺, 2295.681.

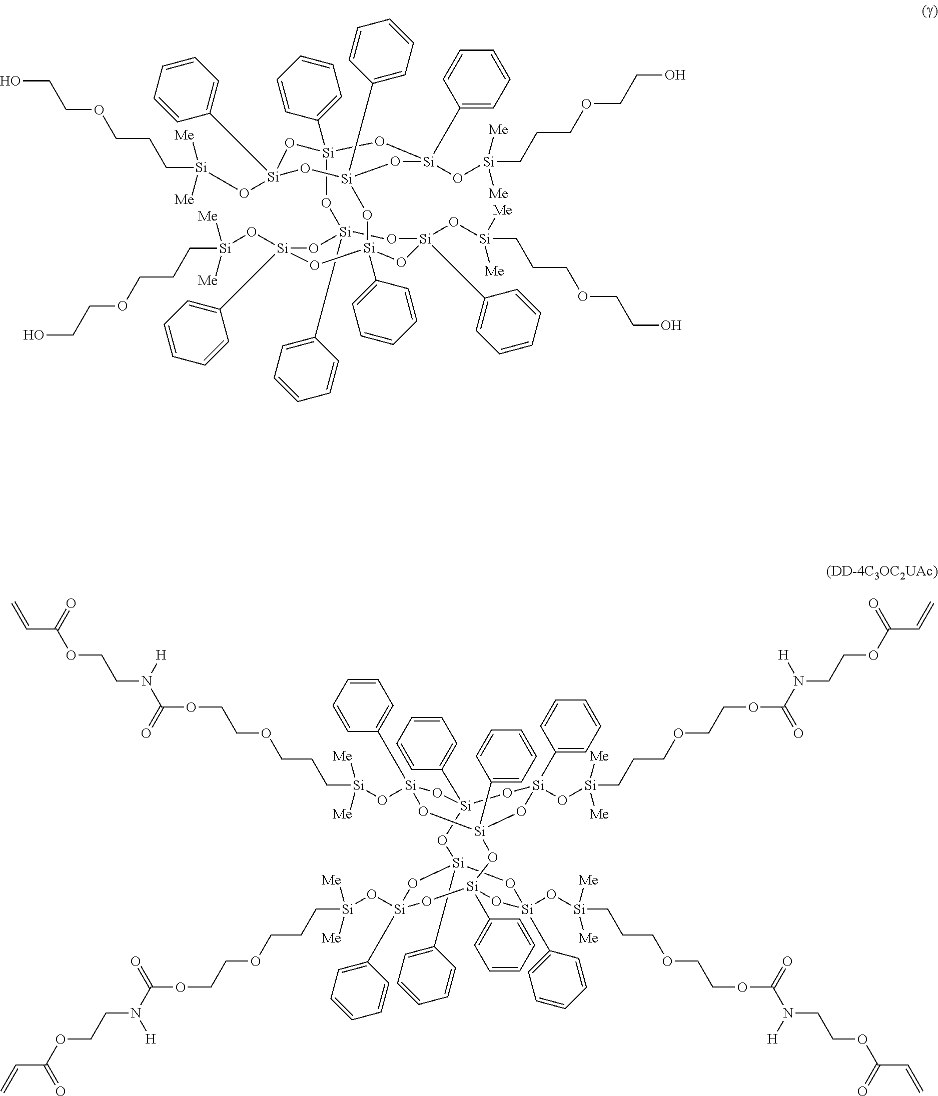 [SMILES: C[Si](C)(CCCOCCO)O[Si]1(c2ccccc2)O[Si]2(c3ccccc3)O[Si](O[Si](C)(C)CCCOCCO)(c3ccccc3)O[Si](c3ccccc3)(O1)O[Si]1(c3ccccc3)O[Si](O[Si](C)(C)CCCOCCO)(c3ccccc3)O[Si](c3ccccc3)(O[Si](O[Si](C)(C)CCCOCCO)(c3ccccc3)O1)O2 ; C=CC(=O)OCCNC(=O)OCCOCCC[Si](C)(C)O[Si]1(c2ccccc2)O[Si]2(c3ccccc3)O[Si](O[Si](C)(C)CCCOCCOC(=O)NCCOC(=O)C=C)(c3ccccc3)O[Si](c3ccccc3)(O1)O[Si]1(c3ccccc3)O[Si](O[Si](C)(C)CCCOCCOC(=O)NCCOC(=O)C=C)(c3ccccc3)O[Si](c3ccccc3)(O[Si](O[Si](C)(C)CCCOCCOC(=O)NCCOC(=O)C=C)(c3ccccc3)O1)O2]

### Synthesis Example V: Synthesis of (DD-4C₃OC₂UAc₂) (1)-(b-3)

A silsesquioxane derivative (DD-4C3OC₂UAc₂) represented by the following formula was produced by the following method.

Under nitrogen sealing, 100 g of compound (γ), 140 g of dehydrated toluene (made by Kanto Chemical Co., Inc.), 3.0 g of 2,6-di-tert-butyl-p-cresol (made by Tokyo Chemical Industry Co., Ltd.) and 0.32 mL of dibutyltin dilaurate (made by Tokyo Chemical Industry Co., Ltd.) were charged into a reaction vessel, and the resulting mixture was heated to 90° C. and stirred while bubbling air. Thereto, 64.2 g of BEI (made by Showa Denko K. K.) was added dropwise. Then, the resulting reaction solution was stirred for 3 hours, and after a peak at 2,250 cm⁻¹ was confirmed to be lost or to be reduced to cause no change by an FT-IR, heating was stopped and the resulting solution was cooled to room temperature. Then, the resulting reaction solution was concentrated with an evaporator, and 450 g of heptane (made by FUJIFILM Wako Pure Chemical Corporation) was added thereto while stirring the solution. A supernatant was removed by decantation, the obtained viscous liquid was further washed with heptane several times, and the resulting supernatant was removed. To the obtained viscous liquid, 0.1 g of 2,6-di-tert-butyl-p-cresol was added, and the resulting mixture was dried under reduced pressure to obtain 153 g of (DD-4C3OC₂UAc₂) (transparent viscous liquid)

GPC purity: 99%

¹H-NMR: (400 MHz, (CD3) 2CO) δ=7.56-7.20 (40H, Ph), 6.39 (8H, COCH═CH₂, cis), 6.33 (4H, NH), 6.16 (8H, COCH═CH₂, gem), 5.89 (8H, COCH═CH₂, trans), 4.38 (16H, CH₂═CHCOOCH₂), 3.99 (8H, CH₂OCONH), 3.35 (8H, SiC₃H₆OCH₂), 3.02 (8H, SiC₂H₄CH₂), 1.42 (12H, CCH₃), 1.36 (8H, SiCH₂CH₂), 0.55 (8H, SiCH₂), 0.09 (24H, —Si(CH₃)₂).

MALDI-TOFMS: m/z C₁₂₀H₁₆₀N₄NaO₄₂Si₁₂ [M+Na]⁺, 2688.056.

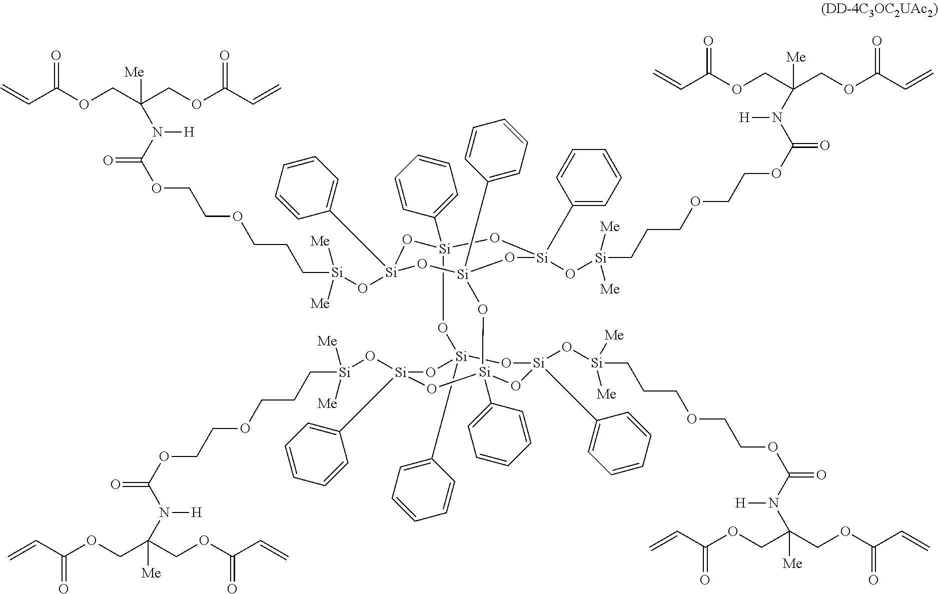 [SMILES: C=CC(=O)OCC(C)(COC(=O)C=C)NC(=O)OCCOCCC[Si](C)(C)O[Si]1(c2ccccc2)O[Si]2(c3ccccc3)O[Si](O[Si](C)(C)CCCOCCOC(=O)NC(C)(COC(=O)C=C)COC(=O)C=C)(c3ccccc3)O[Si](c3ccccc3)(O1)O[Si]1(c3ccccc3)O[Si](O[Si](C)(C)CCCOCCOC(=O)NC(C)(COC(=O)C=C)COC(=O)C=C)(c3ccccc3)O[Si](c3ccccc3)(O[Si](O[Si](C)(C)CCCOCCOC(=O)NC(C)(COC(=O)C=C)COC(=O)C=C)(c3ccccc3)O1)O2]

### Synthesis Example VI: Synthesis of (DD-4EPAc) (1)-(c-1)

A silsesquioxane derivative (DD-4EPAc) represented by the following formula was produced by the following method.

Under nitrogen sealing, 10 g of a compound represented by formula (δ) (hereinafter, referred to as compound (δ)) prepared by the method disclosed in WO 2004/024741 A, 14 g of dehydrated toluene (made by Kanto Chemical Co., Inc.), 0.38 g of tetrabutylphosphonium bromide (made by Tokyo Chemical Industry Co., Ltd.) and 0.04 g of 2,6-di-tert-butyl-p-cresol (made by Tokyo Chemical Industry Co., Ltd.) were charged into a reaction vessel, and the resulting mixture was heated to 110° C. and stirred while bubbling air. Thereto, 2.4 g of acrylic acid (made by FUJIFILM Wako Pure Chemical Corporation) was added dropwise. Then, the resulting reaction solution was refluxed for 7 hours while following the reaction by HPLC, and after a change on an HPLC chart was confirmed to be stopped by HPLC, heating was stopped and the resulting solution was cooled to room temperature. Then, the resulting reaction solution was diluted with toluene, and the resulting solution was washed with a saturated aqueous sodium carbonate solution, and an organic phase was washed with a saturated aqueous sodium chloride solution until an aqueous layer became neutral. The resulting organic phase was dried with sodium sulfate, and sodium sulfate was filtrated off, and then the solvent was distilled off by an evaporator. To the obtained viscous liquid, 0.01 g of 2,6-di-tert-butyl-p-cresol was added, and the resulting mixture was dried under reduced pressure to obtain 11 g of a colorless transparent viscous liquid (DD-4EPAc). From the results of MALDI-TOFMS, the obtained material was assumed to be a mixture in which n is 0 to 3.

MALDI-TOFMS:

m/z C₉₂H₁₂₄NaO₃₀Si₁₂[M+Na]⁺, 2067.608;
C₉₅H₁₂₈NaO₃₂Si₁₂ [M+Na]⁺, 2139.637;
C₉₈H₁₃₂NaO₃₄Si₁₂ [M+Na]⁺, 2211.679;
C₁₀₁H₁₃₆NaO₃₆Si₁₂ [M+Na]⁺, 2283.713.

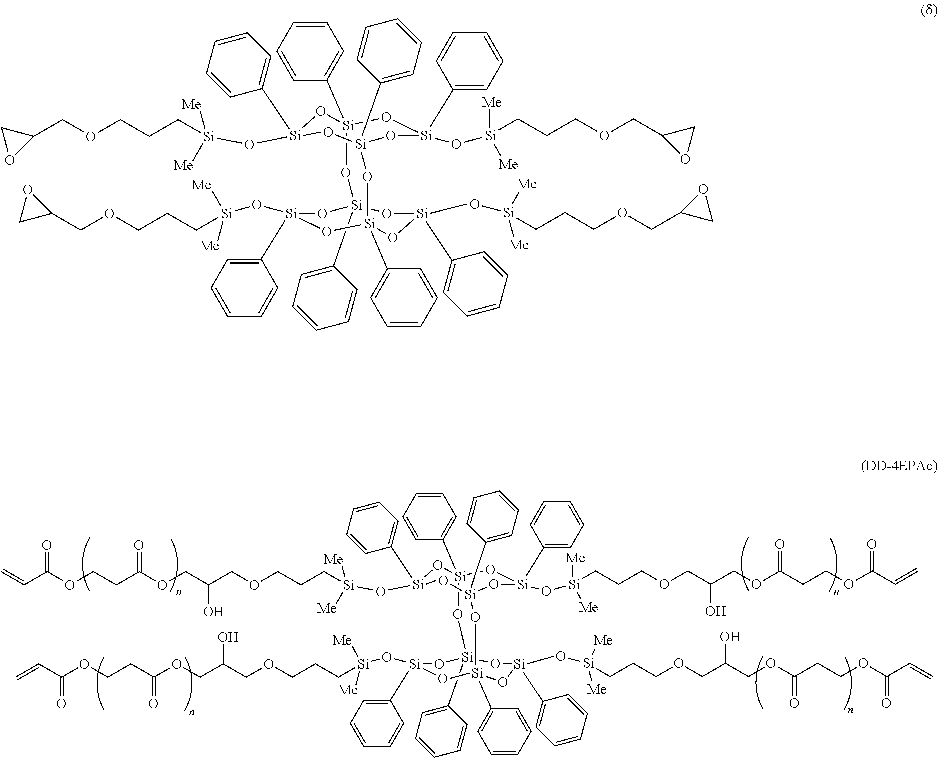

### Synthesis Example VII: Synthesis of (DD-4cEPAc) (1)-(d-1)

A silsesquioxane derivative (DD-4cEPAc) represented by the following formula was produced by the following method.

Under nitrogen sealing, 50 g of a compound represented by formula (ε) (hereinafter, referred to as compound (ε)) prepared by the method disclosed in JP 5013127 B, 70 g of dehydrated toluene (made by Kanto Chemical Co., Inc.), 7.5 g of tetrabutylphosphonium bromide (made by Tokyo Chemical Industry Co., Ltd.) and 1.8 g of 2,6-di-tert-butyl-p-cresol (made by Tokyo Chemical Industry Co., Ltd.) were charged into a reaction vessel, and the resulting mixture was heated to 110° C. and stirred while bubbling air. Thereto, 12 g of acrylic acid (made by FUJIFILM Wako Pure Chemical Corporation) was added dropwise. Then, the resulting reaction solution was refluxed for 7 hours while following the reaction by HPLC, and after a change on an HPLC chart was confirmed to be stopped by HPLC, heating was stopped and the resulting solution was cooled to room temperature. Then, the resulting reaction solution was diluted with toluene, and the resulting solution was washed with a saturated aqueous sodium carbonate solution, and an organic phase was washed with a saturated aqueous sodium chloride solution until an aqueous layer became neutral. The resulting organic phase was dried with sodium sulfate, and sodium sulfate was filtrated off, and then the solvent was distilled off by an evaporator. To the obtained viscous liquid, 0.05 g of 2,6-di-tert-butyl-p-cresol was added, and the resulting mixture was dried under reduced pressure to obtain 57 g of a white solid (DD-4cEPAc). From the results of MALDI-TOFMS, the obtained material was assumed to be: n=0 to 3.

MALDI-TOFMS:

m/z C₁₀₀H₁₃₂NaO₂₆Si₁₂ [M+Na]⁺, 2107.7;
C₁₀₃H₁₃₆NaO₂₈Si₁₂ [M+Na]⁺, 2179.9;
C₁₀₆H₁₄₀NaO₃₀Si₁₂ [M+Na]⁺, 2252.0;
C₁₀₉H₁₄₄NaO₃₂Si₁₂ [M+Na]⁺, 2324.2.

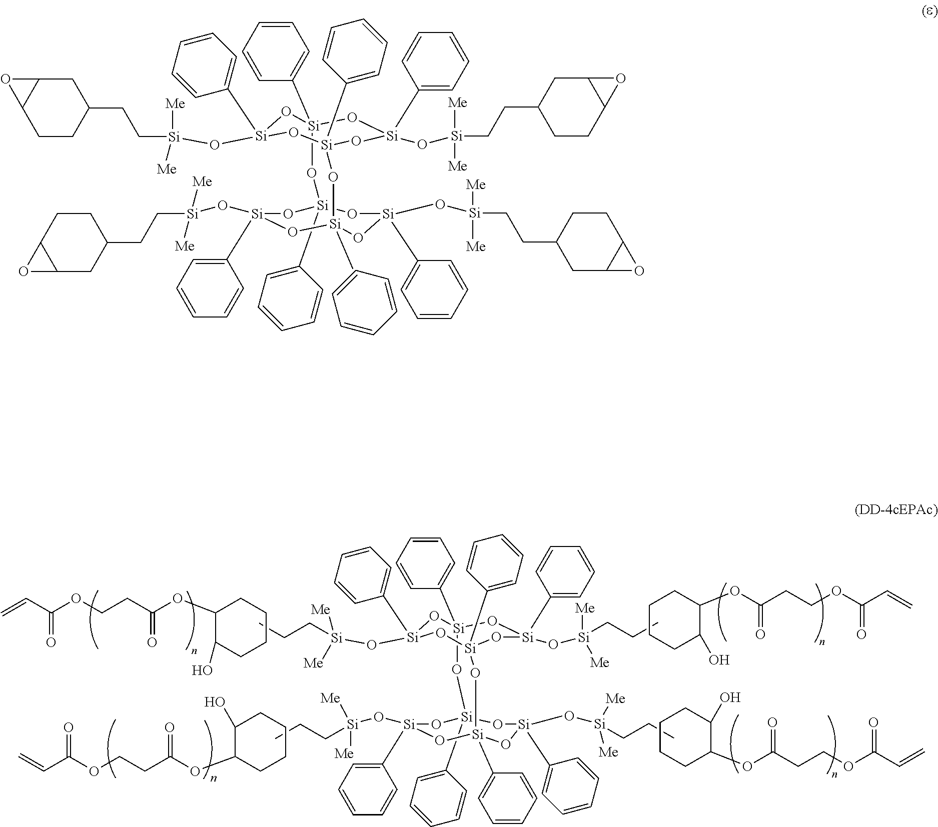

### Synthesis Example VIII: Synthesis of Solgel Material Ac-Solgel of 3-acryloxyprophyltrimethoxysilane

A mixture of 50 g of 3-acryloxyprophyltrimethoxysilane (made by Tokyo Chemical Industry Co., Ltd.), 250 g of dehydrated toluene (made by Kanto Chemical Co., Inc.) and 0.2 g of 2,6-di-tert-butyl-p-cresol (made by Tokyo Chemical Industry Co., Ltd.) was stirred at 80° C., and an aqueous solution (water 12 g) of 0.2 g of methanesulfonic acid (made by Tokyo Chemical Industry Co., Ltd.) was slowly added dropwise thereto. Further, the resulting mixture was stirred at 80° C. for 5 hours. The resulting solution was washed with water until an aqueous layer became neutral, and toluene was distilled off by an evaporator to obtain 49 g of a transparent liquid. A number average molecular weight by GPC was about 2,000.

### Preparation of Varnish

A varnish in each Examples and Comparative Examples was prepared to be in the composition shown in Table 1.

Components (A), (B) and (D) and components (E) and (F) were put in a brown screw tube, and the resulting material was heated, stirred and dissolved while being held at about 70° C., and then component (C) (photoradical polymerization initiator) was added thereto as a curing agent and dissolved therein, and the resulting material was taken as a varnish.

In the Table, components (A), (B) and (D) each are expressed in terms of a value in % by mass when a total of components (A), (B) and (D) is taken as 100% by mass, and a value of components (C), (E) and (F) each is expressed in terms of a value in % by mass when the total of components (A), (B) and (D) (solid content) is taken as 100% by mass.

In addition, with regard to Comparative Example 3, component (D) shows a mixing amount of Nanocryl C165, in which a nanosilica filler occupies 50% parts by mass is and the remaining 50% parts by mass thereof is an acrylic resin. With regard to Comparative Example 4, component (D) shows a mixing amount of Nano silica, in which a nanosilica filler occupies 40% parts by mass and the remaining 60% parts by mass is MEK.

Each component in the varnish is as described below.

### Component (A)

### DPHA:

Trade name: A-DPH made by Shin-Nakamura Chemical Co., Ltd.

(dipentaerythritol hexaacrylate)

### UV-7650B:

Trade name: SHIKOH UV-7650B made by The Nippon Synthetic Chemical Industry Co., Ltd.

(tetrafunctional to pentafunctional urethane acrylate oligomer)

### Component (C)

### Irgacure 184:

IRGACURE (registered trademark) 184 made by BASF Japan Ltd.
(1-hydroxycyclohexylphenyl ketone)

### Component (H)

### Ac-Solgel:

A solgel material of 3-(acryloxy)propyltrimethoxysilane obtained by Synthesis Example VIII

### Component (D)

Nanocryl C165 (content of SiO₂: 50 wt %):

Trade name: NANOCRYL (registered trade name) C165 made by EVONIK INDUSTRIES

(50% parts by mass silica nano particle-mixed pentaerythritol propoxy tetraacrylate solution)

*50% parts by mass thereof is an acrylic resin.

Nano silica (content of SiO₂: 40 wt % in MEK dispersion liquid):

Trade name: MEK-ST-40 made by Nissan Chemical Industries, Ltd.

(40% parts by mass silica-nanoparticle-dispersed MEK solution)

*60 parts by mass is MEK.

### Component (E)

### MIBK:

Trade name: 4-methyl-2-pentanone made by Tokyo Chemical Industry Co., Ltd.

(methyl isobutyl ketone)

### Component (F)

### FM-0711:

Trade name: Silaplane (registered trademark) made by JNC Corporation

(single end methacryloxy group-modified dimethyl silicone (average molecular weight Mn: 1,000))

### Preparation of Cured Film

A varnish thus prepared was coated on each of a 50 μm-thick polyethylene terephthalate film on which double-sided easy-adhesion treatment was performed by a wire bar coater to be 2.5 to 6 μm in a cured film thickness. When the varnish contains a solvent, the resulting material was dried in an oven at 80° C. for 1 minute, and then the resulting material was irradiated with ultraviolet light to be an integrated exposure of ultraviolet light into 0.5 J/cm² by using an ultraviolet exposure apparatus {LH10-10Q (trade name), H bulb (trade name made by Heraeus K.K.)} to obtain a cured film. (Hereinafter, described as PET with the cured film). A thickness of the obtained cured film is shown in Table 1.

### Curling Test: Cure Shrinkage Evaluation (Evaluation Method 1)

The thus obtained PET with the cured film was cut into a lattice of 15 cm×15 cm, and the resulting lattice was allowed to stand with the cured film upward under an atmosphere of 25° C. and 50% RH for 24 hours or more, and then each height of the cured film lifted on four corners on a horizontal table was measured, and a total of the mean value of the heights was taken as a measured value (unit: mm). At that time, curling of the base materials was 0 mm for all the base materials. The results of evaluation are shown in Table 1.

### Moist Heat Resistant Test: Adhesion Evaluation (Evaluation Method 2)

An adhesion test of the PET with the cured film was performed, and then the resulting PET with the cured film was put into a constant temperature and humidity chamber at 85° C. and 85% RH for 120 hours, and then the resulting material was took out therefrom, and an adhesion test was performed thereon. The adhesion test was performed thereon by using a crosscut adhesion method with 25 lattice patterns at a spacing of 1 millimeter in accordance with ASTM D3359 (Method B), and adhesion was evaluated on the basis of the following criteria. The results of evaluation are shown in Table 1.

5B: 0% in percent area removed;

4B: less than 5% in percent area removed;

3B: 5% or more and less than 15% in percent area removed;

2B: 15% or more and less than 35% in percent area removed;

1B: 35% or more and less than 65% in percent area removed; and

0B: 65% or more in percent area removed.

### Scratch Resistance Test

A glass surface with the cured film was scratched with steel wool (#0000) applied with a load of 500 g/cm² by 10 reciprocating motions, and the cured films before and after testing were visually evaluated. Before testing, all samples have no scratches. The results of evaluation after testing are shown in Table 1.

### Evaluation Criteria

No scratches were observed: Excellent

Several fine scratches were observed: Good

Significant scratches were observed: Poor

TABLE 1
Table 1

| | | | Compound, | Examples | | | | | Comparative Examples | | | | |
|---|---|---|---|---|---|---|---|---|---|---|---|---|---|
| | Component | | conditions | 1 | 2 | 3 | 4 | 5 | 1 | 2 | 3 | 4 | 5 |
| Varnish | A | Radically | DPHA | 50 | 50 | 50 | 50 | 50 | 100 | 50 | | 50 | 50 |
| | | polymerizable | | | | | | | | | | | |
| | | resin (base | | | | | | | | | | | |
| | | resin) | | | | | | | | | | | |
| | | Radically | UV-7650B | | | | | | | | | | 50 |
| | | polymerizable | | | | | | | | | | | |
| | | resin | | | | | | | | | | | |
| | B | Silsesquioxane | DD-4cEPAc | 50 | | | | | | | | | |
| | | derivative | DD-4C₃UAc | | 50 | | | | | | | | |
| | | | DD-4C₃UAc₂ | | | 50 | | | | | | | |
| | | | DD-4C₃OC₂UAc | | | | 50 | | | | | | |
| | | | DD-4C₃OC₂UAc₂ | | | | | 50 | | | | | |
| | H | Silsesquioxane | Ac-Solgel | | | | | | | 50 | | | |
| | | derivative | | | | | | | | | | | |
| | D | Nano silica filler | Nanocryl C165 | | | | | | | | 100 | | |
| | | | (content of SiO_{2:} | | | | | | | | | | |
| | | | 50 wt %) | | | | | | | | | | |
| | | | Nano silica | | | | | | | | | 125 | |
| | | | (content of SiO_{2:} | | | | | | | | | | |
| | | | 40 wt % in MEK | | | | | | | | | | |
| | | | dispersion liquid) | | | | | | | | | | |
| | F | Surface control | FM-0711 | 0.1 | 0.1 | 0.1 | 0.1 | 0.1 | 0.1 | 0.1 | 0.1 | 0.1 | 0.1 |
| | | agent | | | | | | | | | | | |
| | C | Photoradical | Irgacure 184 | 5 | 5 | 5 | 5 | 5 | 5 | 5 | 5 | 5 | 5 |
| | | generator | | | | | | | | | | | |
| | E | Solvent | MIBK | 40 | 40 | 40 | 40 | 40 | 40 | 40 | 40 | 0 | 40 |

| | | | | | | | | | | | | |
|---|---|---|---|---|---|---|---|---|---|---|---|---|
| Curing step | UV integrated | Heraeus H bulb | 0.5 | 0.5 | 0.5 | 0.5 | 0.5 | 0.5 | 0.5 | 0.5 | 0.5 | 0.5 |
| | exposure | | | | | | | | | | | |
| | (J/cm²) | | | | | | | | | | | |
| Cured film | Film thickness | | 3.0 | 3.1 | 3.1 | 3 | 6 | 3.3 | 2.5 | 2.8 | 3.3 | 3.4 |
| | (μm) | | | | | | | | | | | |
| Results | Curling (mean | 15 × 15 cm 50 μm- | 3 | 0 | 4 | 0 | 2 | Cylindrical | 0 | 3 | 10 | 10 |
| | value on 4 | thick PET with | | | | | | shape | | | | |
| | corners) (mm) | easily adhesive | | | | | | | | | | |
| | | layer | | | | | | | | | | |
| | Adhesion after | 0 hour | 5B | 5B | 5B | 5B | 5B | 5B | 5B | 5B | 5B | 5B |
| | humidity and | after 120 hours | 5B | 5B | 4B | 5B | 4B | 1B | 0B | 0B | 4B | 0B |
| | heat resistant | | | | | | | | | | | |
| | test | | | | | | | | | | | |
| | 50 μm-thick | | | | | | | | | | | |
| | PET with easily | | | | | | | | | | | |
| | adhesive layer | | | | | | | | | | | |
| | Scratch | #0000 10 | Good | Good | Excel- | Excel- | Excel- | Excel- | Poor | Excel- | Excel- | Excel- |
| | resistance | reciprocating | | | lent | lent | lent | lent | | lent | lent | lent |
| | Δhaze | motions (load: | | | | | | | | | | |
| | | 500 g) | | | | | | | | | | |

Examples 1 to 5 show that addition of a new silsesquioxane derivative to the acrylic resin can suppress curling of the cured film while maintaining the scratch resistance, and the cured film that has excellent adhesion to the PET with a easily adhesive layer after moist heat resistant test, and has high resistance to moist heat can be obtained.

Comparative Example 1 shows that no reduction of the scratch resistance was caused, but a curl was heavily formed into a cylindrical shape, and further adhesion after the moist heat resistant test was deteriorated when only the acrylic resin (DPHA) to which the new silsesquioxane derivative of the invention was not added was cured.

Comparative Example 2 shows that cure shrinkage was suppressed, but scratch resistance was significantly reduced, and adhesion after moist heat resistant test was significantly reduced, when the amorphous acrylic group-containing silsesquioxane prepared by the solgel method was added to the acrylic resin.

Comparative Example 3 shows that reduction of scratch resistance was suppressed, but adhesion after the moist heat resistant test was significantly reduced by curing the resin composition in which nanosilica was incorporated into the acrylic resin (pentaerythritol propoxy tetraacrylate) in which the new silsesquioxane derivative according to the invention was not added.

Comparative Example 4 shows that no reduction of scratch resistance was observed, but cure shrinkage was significantly caused and the cured film was significantly curled when nanosilica was added to the acrylic resin (DPHA) to which the new silsesquioxane derivative of the invention was not added, and the resulting material was cured.

Comparative Example 5 shows that no reduction of scratch resistance was observed, but cure shrinkage was significantly large, the cured film was curled, and further adhesion after the moist heat resistant test was significantly reduced when urethane acrylate comparable to, in equivalent of a functional group, the new silsesquioxane derivative of the invention was added to the acrylic resin (DPHA) to which the new silsesquioxane derivative of the invention was not added.

### INDUSTRIAL APPLICABILITY

A new silsesquioxane derivative is provided from one embodiment of the invention. The invention provides a resin composition from which a cured film having scratch resistance low warpage and high resistance to moist heat can be obtained by combining a new silsesquioxane derivative according to the invention with an acrylic resin. The cured film of the resin composition according to one embodiment of the invention or a laminate according to one embodiment of the invention is preferably used as a coating of various electronic components from excellent low warpage. Moreover, the above materials are also preferably used as an insulating material used on a wiring unit of a printed wiring board having an electronic circuit.

1. A silsesquioxane derivative having a radically polymerizable functional group, represented by formula (1), (2) or (3):
wherein, in the formulas (1) to (3),
R¹ is a group independently selected from alkyl having 1 to 45 carbons, cycloalkyl having 4 to 8 carbons, aryl having 6 to 14 carbons and arylalkyl having 7 to 24 carbons; in the alkyl having 1 to 45 carbons, at least one hydrogen may be replaced by fluorine, and at least one non-adjacent —CH₂— may be replaced by —O— or —CH═CH—; in a benzene ring in the aryl and the arylalkyl, at least one hydrogen may be replaced by halogen or alkyl having 1 to 10 carbons, and in the alkyl having 1 to 10 carbons, at least one hydrogen may be replaced by fluorine, and at least one non-adjacent —CH₂— may be replaced by —O— or —CH═CH—; the number of carbons of alkylene in the arylalkyl is 1 to 10, and at least one non-adjacent —CH₂— may be replaced by —O—;
R² and R³ are a group independently selected from alkyl having 1 to 10 carbons, cyclopentyl, cyclohexyl and phenyl,
X is independently hydrogen or a monovalent organic group, in which at least one of X is a radically polymerizable functional group represented by formula (4); and
in formula (4), 1 is an integer from 0 to 10, m is an integer from 0 to 10, n is 0 or 1, p is an integer from 0 to 10, q is 0 or 1, r is 0 or 1, s is an integer from 0 to 10, R⁴ is a hydroxyl group, R⁵ is hydrogen or methyl, R⁶ is an organic group having 4 to 6 carbons, and having an acryloyl group or a methacryloyl group, and R⁷ is hydrogen or methyl; and arbitrary —CH₂— may be replaced by —O—; in which a case where two oxygens are bonded with each other (—O—O—) is excluded; in X of the silsesquioxane derivative represented by formula (1), when all of m, n, p, q and r are 0, and R⁷ is methyl, a sum: 1+s is an integer from 4 or more; and in X of the silsesquioxane derivative represented by formula (2), when all of m, n, p, q and r are 0, a sum: 1+s is an integer from 4 or more:

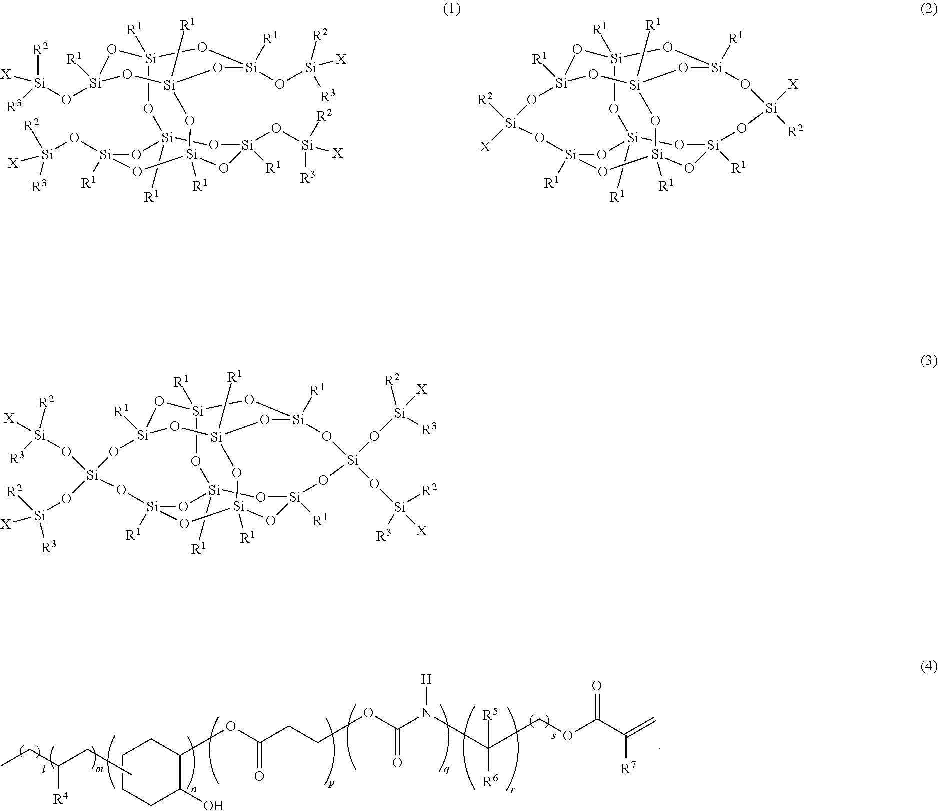

2. The silsesquioxane derivative having the radically polymerizable functional group according to claim 1, wherein, in the formula (1), (2) or (3), all of R² and R³ are alkyl having 1 to 6 carbons.

3. The silsesquioxane derivative having the radically polymerizable functional group according to claim 2, wherein, in the formula (1), (2) or (3), all of R² and R³ are a methyl group or an ethyl group.

4. The silsesquioxane derivative having the radically polymerizable functional group according to claim 1, wherein, in the formula (1), (2) or (3), all of X contain a polymerizable functional group.

5. The silsesquioxane derivative having the radically polymerizable functional group according to claim 1, wherein, in the formula (1), (2) or (3), at least one of X is (meth)acrylate, urethane (meth)acrylate or epoxy (meth)acrylate.

6. The silsesquioxane derivative having the radically polymerizable functional group according to claim 1, wherein, in the formula (1), X is one kind selected from the group of polymerizable functional groups represented by (a-1) to (a-4), (b-1) to (b-5), (c-1), (c-2), (d-1) and (d-2),
in the formula (2), X is one kind selected from the group of polymerizable functional groups represented by (a-1) to (a-3), (b-1) to (b-5), (c-1), (c-2), (d-1) and (d-2), and
in the formula (3), X is one kind selected from the group of polymerizable functional groups represented by (a-1) to (a-5), (b-1) to (b-5), (c-1), (c-2), (d-1) and (d-2): 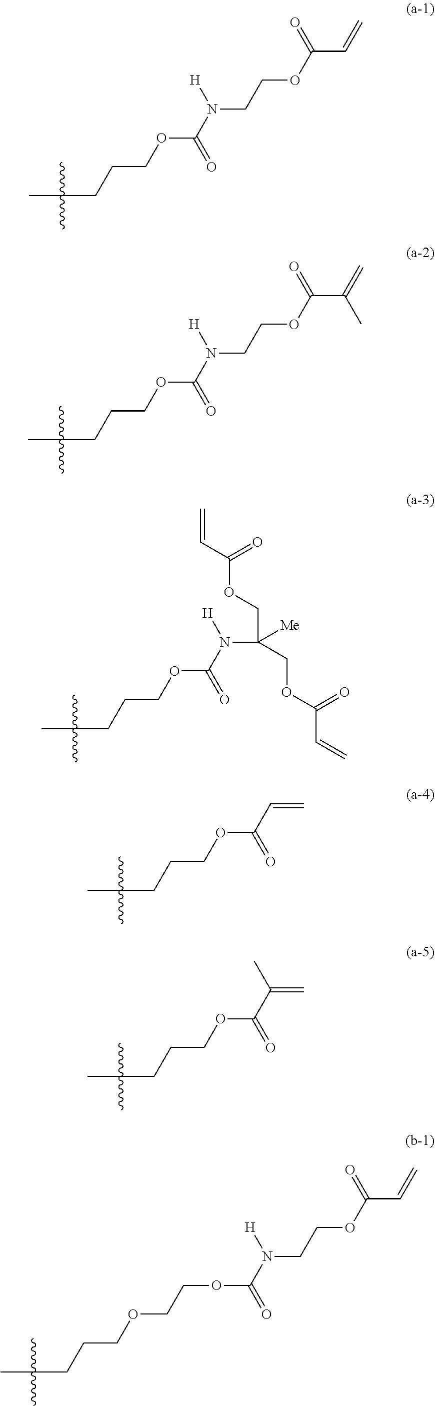 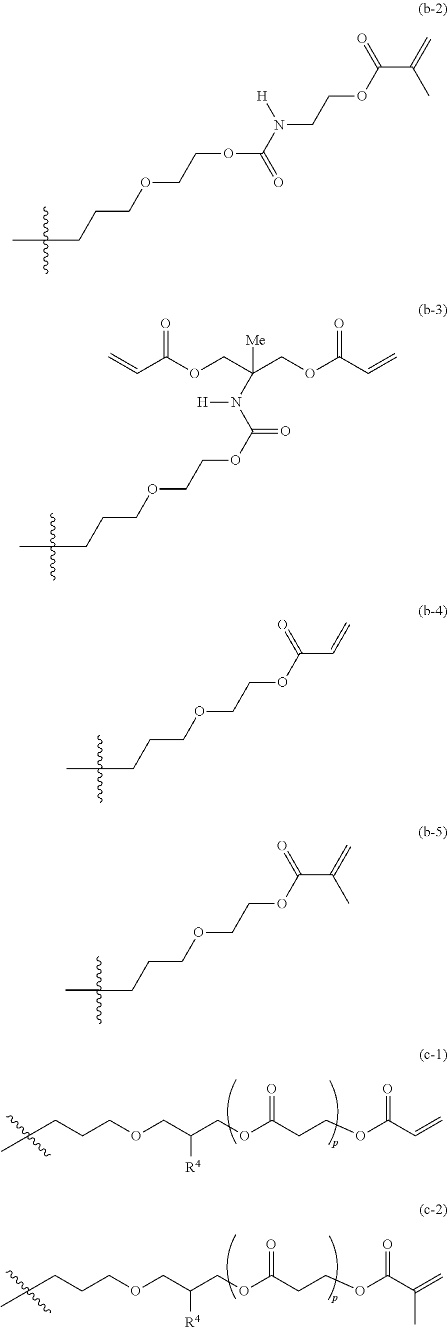 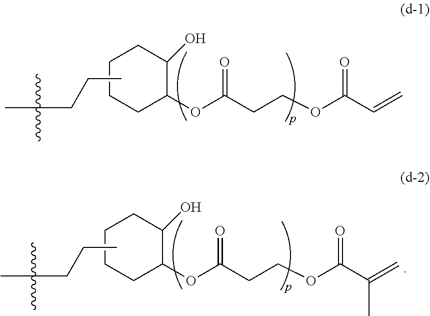
wherein, R⁴ is a hydroxyl group, and p is an integer from 0 to 10.

7. A resin composition, containing acrylic resin (A) and at least one kind selected from silsesquioxane derivatives (B) represented by formula (1), (2) or (3),
wherein, in the silsesquioxane derivative represented by formula (1), (2) or (3),
R¹ is a group independently selected from alkyl having 1 to 45 carbons, cycloalkyl having 4 to 8 carbons, aryl having 6 to 14 carbons and arylalkyl having 7 to 24 carbons; and in the alkyl having 1 to 45 carbons, at least one hydrogen may be replaced by fluorine, and at least one non-adjacent-CH₂— may be replaced by —O— or —CH═CH—; in a benzene ring in the aryl and the arylalkyl, at least one hydrogen may be replaced by halogen or alkyl having 1 to 10 carbons, and in the alkyl having 1 to 10 carbons, at least one hydrogen may be replaced by fluorine, and at least one non-adjacent —CH₂— may be replaced by —O— or —CH═CH—; the number of carbons of alkylene in the arylalkyl is 1 to 10, and at least one non-adjacent-CH₂— may be replaced by —O—,
R² and R³ are a group independently selected from alkyl having 1 to 10 carbons, cyclopentyl, cyclohexyl and phenyl,
X is independently hydrogen or a monovalent organic group, in which at least one of X is a radically polymerizable functional group represented by formula (4); and
in formula (4), 1 is an integer from 0 to 10, m is an integer from 0 to 10, n is 0 or 1, p is an integer from 0 to 10, q is 0 or 1, r is 0 or 1, s is an integer from 0 to 10, R⁴ is a hydroxyl group, R⁵ is hydrogen or methyl, R⁶ is an organic group having 4 to 6 carbons, and having an acryloyl group or a methacryloyl group, R⁷ is hydrogen or methyl; and arbitrary —CH₂— may be replaced by —O—; in which a case where two oxygens are bonded with each other (—O—O—) is excluded, in X of the silsesquioxane derivative represented by formula (1), when all of m, n, p, q and r are 0, and R⁷ is methyl, a sum: 1+s is an integer from 4 or more, and in X of the silsesquioxane derivative represented by formula (2), when all of m, n, p, q and r are 0, a sum: 1+s is an integer from 4 or more:

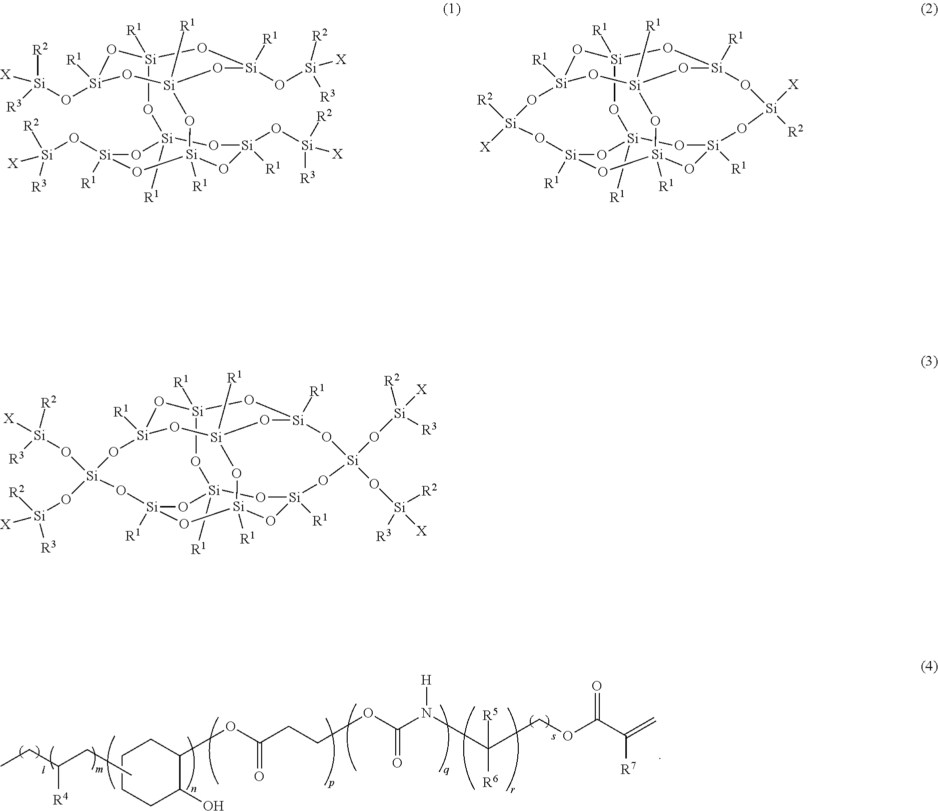

8. The resin composition according to claim 7, containing at least one kind of a silsesquioxane derivative, wherein, in the silsesquioxane derivative (B) represented by formula (1), (2) or (3), all of R¹ are phenyl, all of R² and R³ are a methyl group, and X is selected from the group represented by (a-1) to (a-5), (b-1) to (b-5), (c-1), (c-2), (d-1) and (d-2): 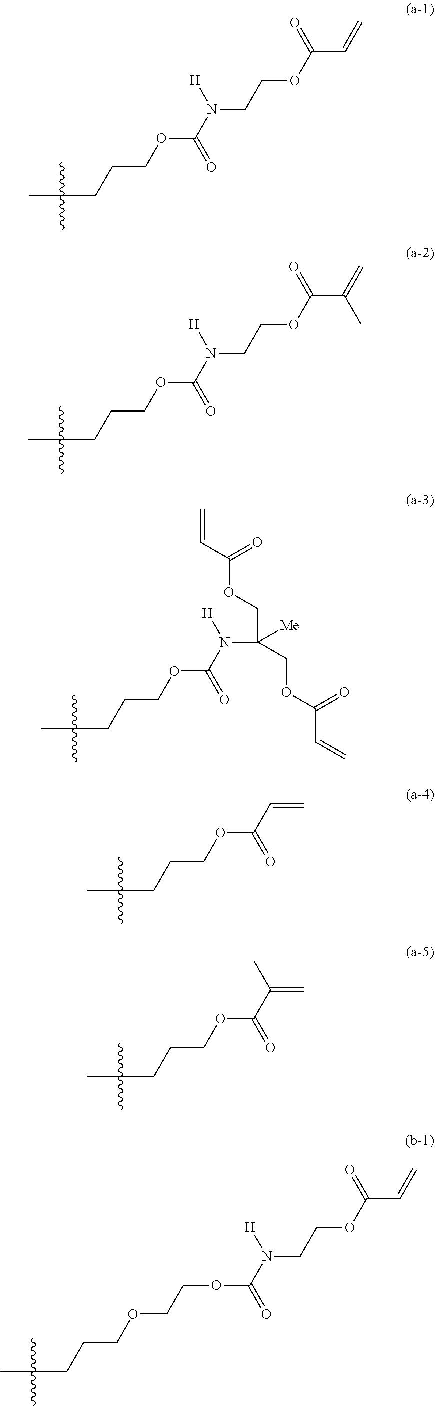 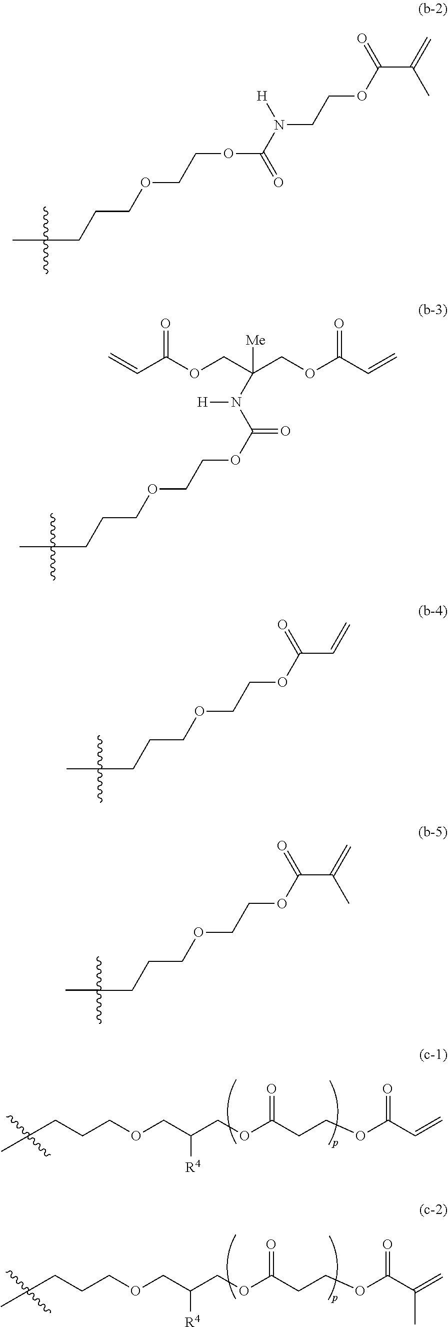 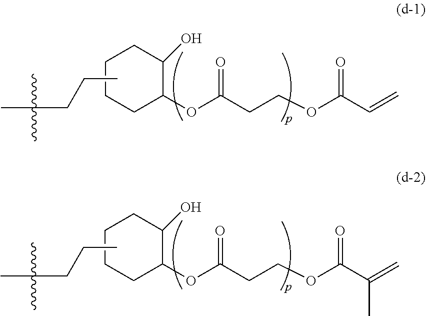
wherein, R⁴ is a hydroxyl group and p is an integer from 0 to 10.

9. The resin composition according to claim 7, wherein the acrylic resin (A) is a polyfunctional monomer type (meth)acrylic resin.

10. The resin composition according to claim 7, containing acrylic resin(A) by 10% by mass or more and 95% by mass or less in a solid content of the resin composition.

11. The resin composition according to claim 7, wherein a mass ratio of a content of the acrylic resin (A) to a total content of the silsesquioxane derivatives (B) represented by formula (1), (2) or (3) is 10:90 to 95:5.

12. A cured film, formed by curing the resin composition according to claim 7.

13. A laminate, including:
a base material; and
a cured film formed by curing the resin composition containing at least acrylic resin (A) and at least one kind selected from silsesquioxane derivatives (B) represented by formula (1), (2) or (3) on the base material, and the laminate,
in which a warpage height of the base material with the cured film, on the resin composition, is 0 millimeter or more and 4 millimeters or less by evaluation method 1, and adhesion after 120 hours is rated to be 4B or more for all in an adhesion evaluation by evaluation method 2: and in the formulas (1) to (3), R¹ is a group independently selected from alkyl having 1 to 45 carbons, cycloalkyl having 4 to 8 carbons, aryl having 6 to 14 carbons and arylalkyl having 7 to 24 carbons; and in the alkyl having 1 to 45 carbons, at least one hydrogen may be replaced by fluorine, and at least one non-adjacent —CH₂— may be replaced by —O— or —CH═CH—; in a benzene ring in the aryl and the arylalkyl, at least one hydrogen may be replaced by halogen or alkyl having 1 to 10 carbons, and in the alkyl having 1 to 10 carbons, at least one hydrogen may be replaced by fluorine, and at least one non-adjacent —CH₂— may be replaced by —O— or —CH═CH—; and the number of carbons of alkylene in the arylalkyl is 1 to 10, and at least one non-adjacent-CH₂— may be replaced by —O—,
R² and R³ are a group independently selected from alkyl having 1 to 10 carbons, cyclopentyl, cyclohexyl and phenyl,
X is independently hydrogen or a monovalent organic group, in which at least one of X is a radically polymerizable functional group represented by formula (4); and
in the formula (4), 1 is an integer from 0 to 10, m is an integer from 0 to 10, n is 0 or 1, p is an integer from 0 to 10, q is 0 or 1, r is 0 or 1, s is an integer from 0 to 10, R⁴ is a hydroxyl group, R⁵ is hydrogen or methyl, R⁶ is an organic group having 4 to 6 carbons, and having an acryloyl group or a methacryloyl group, and R⁷ is hydrogen or methyl; and arbitrary —CH₂— may be replaced by —O—; in which a case where two oxygens are bonded with each other (—O—O—) is excluded; in X of the silsesquioxane derivative represented by formula (1), when all of m, n, p, q and r are 0 and R⁷ is methyl, a sum: 1+s is an integer from 4 or more; and in X of the silsesquioxane derivative represented by formula (2), when all of m, n, p, q and r are 0, a sum: 1+s is an integer from 4 or more: and 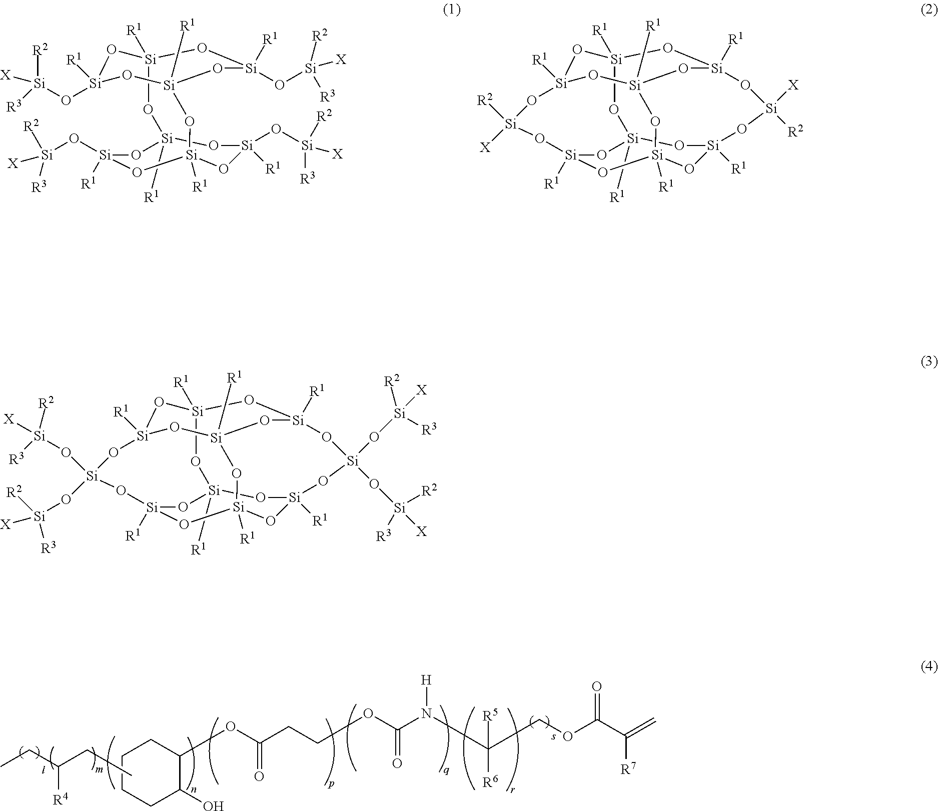
evaluation method 1
a cured film each having a thickness of 2.5 to 6 micrometers and composed of the resin composition is formed on a 50 micrometer-thick polyethylene terephthalate (PET) film base material on which an easy-adhesive layer may be formed;
the resulting PET with the cured film is cut into a lattice of 15 cm×15 cm, and the resulting square is allowed to stand with the cured film upward under an atmosphere of 25° C. and 50% RH for 24 hours or more, and then each height of the cured film lifted on four corners on a horizontal table is measured, and a mean value of the total of heights is taken as a measured value (unit: mm); and
a case of curling downward (U shape) is taken as a positive value, and a case of curling upward (inverted U shape) is taken as a negative value:
evaluation method 2
a cured film each having a thickness of 2.5 to 6 micrometers and composed of the resin composition is formed on a 50 micrometer-thick polyethylene terephthalate (PET) film base material on which an easy-adhesive layer may be formed;
on the resulting PET with the cured film, in accordance with ASTM D3359 (Method B),
an adhesion test is performed by using a crosscut adhesion method with 25 lattice patterns at a spacing of 1 millimeter; and then the PET with the cured film after performing the adhesion test is put into a constant temperature and humidity chamber at 85° C. and 85% RH for 120 hours, and then the resulting material is took out therefrom, and in accordance with ASTM D3359 (Method B),
an adhesion test is performed by using a crosscut adhesion method with 25 lattice patterns at a spacing of 1 millimeter; and evaluation criteria are as described below:
5B: 0% in percent area removed;
4B: less than 5% in percent area removed;
3B: 5% or more and less than 15% in percent area removed;
2B: 15% or more and less than 35% in percent area removed;
1B: 35% or more and less than 65% in percent area removed; and
0B: 65% or more in percent area removed.

14. An electronic component, including the cured film according to claim 12.
